(19) United States
(12) Patent Application Publication
(10) Pub. No.: US 2026/0080917 A1
(43) Pub. Date: Mar. 19, 2026

(54) MEMORY DEVICE

(71) Applicant: Kioxia Corporation, Tokyo (JP)

(72) Inventors: Shinya ARAI, Yokkaichi (JP); Yoshikazu HOSOMURA, Kamakura (JP)

(73) Assignee: Kioxia Corporation, Tokyo (JP)

(21) Appl. No.: 19/074,950

(22) Filed: Mar. 10, 2025

(30) Foreign Application Priority Data
Sep. 19, 2024 (JP) 2024-162402

(51) Int. Cl. G11C 5/06; G11C 16/04; H10B 43/10; H10B 43/27; H10B 43/35; H10B 43/40; H10D 64/66

(52) U.S. Cl. CPC G11C 5/063; G11C 16/0483; H10B 43/10; H10B 43/27; H10B 43/35; H10B 43/40; H10D 64/666

(57) ABSTRACT

A memory device according to an embodiment includes a substrate and first and second circuit layers. The first circuit layer includes a CMOS circuit. The second circuit layer includes a memory cell array including a layer stack and pillars. The layer stack includes insulating layers and first conductive layers alternately stacked. The pillars penetrate the layer stack and is connected to a source line. The second circuit layer includes a contact electrically connected to the CMOS circuit. The source line includes a second conductive layer. The second conductive layer has a portion provided to cover an upper portion of the first pillars and has a portion provided to cover an upper portion of the contact. The second conductive layer electrically connects the pillars and the contact. A surface of the second conductive layer is provided in a non-planar shape above at least one of the pillars and the contact.

### CROSS-REFERENCE TO RELATED APPLICATION

This application is based upon and claims the benefit of priority from Japanese Patent Application No. 2024-162402, filed Sep. 19, 2024, the entire contents of which are incorporated herein by reference.

### FIELD

Embodiments described herein relate generally to a memory device.

### BACKGROUND

A NAND flash memory capable of storing data in a nonvolatile manner is known.

### BRIEF DESCRIPTION OF DRAWINGS

FIG. 1 is a block diagram showing an example of an overall configuration of a memory system including a memory device according to a first embodiment.

FIG. 2 is a circuit diagram showing an example of a circuit configuration of a memory cell array included in the memory device according to the first embodiment.

FIG. 3 is a perspective view showing an example of an external appearance of the memory device according to the first embodiment.

FIG. 4 is a plan view showing an example of a planar layout of the memory device according to the first embodiment.

FIG. 5 is a plan view showing an example of a planar layout in a core area of the memory cell array included in the memory device according to the first embodiment.

FIG. 6 is a cross-sectional view taken along line VI-VI of FIG. 5, showing an example of a cross-sectional structure in a storage area of the memory cell array included in the memory device according to the first embodiment.

FIG. 7 is a cross-sectional view taken along line VII-VII of FIG. 6, showing an example of a cross-sectional structure of a memory pillar included in the memory device according to the first embodiment.

FIGS. 8 and 9 are cross-sectional views showing examples of cross-sectional structures of the memory device according to the first embodiment.

FIG. 10 is a plan view showing an example of arrangement of bonding pads in the memory device according to the first embodiment.

FIG. 11 is a cross-sectional view showing an example of a detailed cross-sectional structure of the vicinity of two bonding pads arranged to face each other in the memory device according to the first embodiment.

FIG. 12 is a plan view showing an example of a planar layout of semiconductor layers in the memory device according to the first embodiment.

FIG. 13 is a plan view showing an example of a planar layout of conductive layers in the memory device according to the first embodiment.

FIG. 14 is a plan view showing an example of a planar layout of the vicinity of a pad unit in the memory device according to the first embodiment.

FIG. 15 is a cross-sectional view taken along line XV-XV of FIG. 14, showing an example of a cross-sectional structure of the vicinity of the pad unit in the memory device according to the first embodiment.

FIG. 16 is a cross-sectional view showing an example of a cross-sectional structure in the manufacturing process of the memory cell array included in the memory device according to the first embodiment.

FIG. 17 is a flowchart showing an example of a method of manufacturing the memory device according to the first embodiment.

FIGS. 18, 19, 20, 21, 22, 23, 24, 25, and 26 are cross-sectional views showing examples of cross-sectional structures in the manufacturing process of the memory device according to the first embodiment.

FIG. 27 is a plan view showing an example of a planar layout of a memory device according to a comparative example to the first embodiment.

FIG. 28 is a cross-sectional view showing an example of a cross-sectional structure of the memory device according to the comparative example to the first embodiment.

FIG. 29 is a plan view showing an example of a planar layout of the memory device according to the first embodiment.

FIG. 30 is a plan view showing an example of a planar layout of conductive layers in a memory device according to a second embodiment.

FIG. 31 is a cross-sectional view showing an example of a cross-sectional structure of the memory device according to the second embodiment.

FIG. 32 is a plan view showing an example of a planar layout of the vicinity of a pad unit in a memory device according to a third embodiment.

FIG. 33 is a cross-sectional view taken along line XXXIII-XXXIII of FIG. 32, showing an example of a cross-sectional structure of the vicinity of the pad unit in the memory device according to the third embodiment.

FIGS. 34 and 35 are cross-sectional views showing examples of cross-sectional structures of a memory device according to a fourth embodiment.

FIG. 36 is a flowchart showing an example of a method of manufacturing the memory device according to the fourth embodiment.

FIGS. 37, 38, 39, 40, 41, 42, and 43 are cross-sectional views showing examples of cross-sectional structures in the manufacturing process of the memory device according to the fourth embodiment.

FIG. 44 is a cross-sectional view showing an example of a cross-sectional structure of a memory device according to a fifth embodiment.

FIG. 45 is a plan view showing an example of a planar layout of conductive layers in the memory device according to the fifth embodiment.

FIGS. 46, 47, 48, 49, 50, and 51 are cross-sectional views showing examples of cross-sectional structures in the manufacturing process of the memory device according to the fifth embodiment.

FIG. 52 is a cross-sectional view showing an example of a cross-sectional structure of a memory device according to a comparative example to the fifth embodiment.

FIG. 53 is a plan view showing an example of a planar layout in a core area of a memory cell array included in a memory device according to a sixth embodiment.

FIGS. 54 and 55 are cross-sectional views showing examples of cross-sectional structures of the memory device according to the sixth embodiment.

FIG. 56 is a flowchart showing an example of a method of manufacturing the memory device according to the sixth embodiment.

FIGS. 57, 58, 59, 60, 61, 62, 63, 64, 65, 66, 67, and 68 are cross-sectional views showing examples of cross-sectional structures in the manufacturing process of the memory device according to the sixth embodiment.

FIG. 69 is a plan view showing an example of a planar layout of a memory cell array included in a memory device according to a seventh embodiment.

FIGS. 70 and 71 are cross-sectional views showing examples of cross-sectional structures of the memory device according to the seventh embodiment.

FIG. 72 is a flowchart showing an example of a method of manufacturing the memory device according to the seventh embodiment.

FIGS. 73, 74, 75, 76, 77, 78, 79, 80, 81, 82, 83, and 84 are cross-sectional views showing examples of cross-sectional structures in the manufacturing process of the memory device according to the seventh embodiment.

FIG. 85 is a plan view showing an example of a planar layout of a memory cell array included in a memory device according to a modification example of the seventh embodiment.

### DETAILED DESCRIPTION

In general, according to one embodiment, a memory device has a bonding surface. The memory device includes a substrate, a first circuit layer, and a second circuit layer. The substrate has a first area and a second area arranged in a first direction. The first circuit layer is provided between the substrate and the bonding surface and includes a CMOS circuit. The second circuit layer is provided above the bonding surface. The second circuit layer includes, in the first area, a memory cell array including a layer stack and a plurality of first pillars. The layer stack includes a plurality of first insulating layers and a plurality of first conductive layers alternately stacked in a second direction crossing the first direction. The first pillars penetrate the layer stack in the second direction and are electrically connected to a source line above the layer stack. The second circuit layer includes, in the second area, at least one first contact having a portion provided at a same height as the layer stack and being electrically connected to the CMOS circuit. The source line includes a second conductive layer. The second conductive layer has, in the first area, a portion provided to cover an upper portion of each of the first pillars included in the memory cell array and has, in the second area, a portion provided to cover an upper portion of the at least one first contact. The second conductive layer electrically connects the first pillars and the at least one first contact. A surface of the second conductive layer is provided in a non-planar shape above at least one of a set of the first pillars and a set of the at least one first contact.

Hereinbelow, embodiments are described with reference to the drawings. Each embodiment gives examples of a device and a method for embodying the technical idea of the invention. The drawings are schematic or conceptual ones. The dimensions, ratios, etc. of drawings are not necessarily the same as the actual ones. The illustration of the configuration is omitted as appropriate. The hatching added to the plan view is not necessarily related to the material or characteristics of the component. In the present specification, components having substantially the same function and configuration are marked with the same reference signs. The numerals, characters, etc. added to reference signs are referred to by the same reference signs, and are used to distinguish between similar elements.

### <1> First Embodiment

A memory device according to a first embodiment has a bonding structure, and has a configuration in which a metal material used as part of a source line and a contact used for connection between the source line and a CMOS circuit are directly connected to each other. A memory device 1 according to the first embodiment will now be described.

### <1-1> Configuration

First, a configuration of the memory device 1 according to the first embodiment is described.

### <1-1-1> Overall Configuration of the Memory Device 1

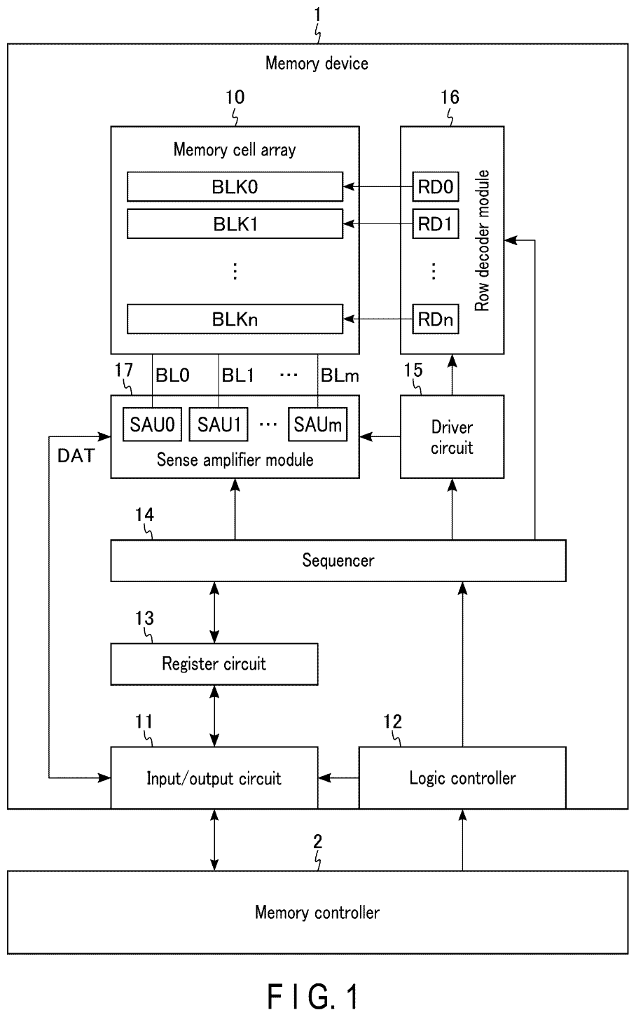

FIG. 1 is a block diagram showing an example of an overall configuration of a memory system including the memory device 1 according to the first embodiment. As shown in FIG. 1, the memory device 1 is controlled by a memory controller 2 in the outside. The memory device 1 is, for example, a NAND flash memory capable of storing data in a nonvolatile manner. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer of 1 or more). The block BLK is a set of a plurality of memory cells. The block BLK corresponds to, for example, a unit of data erasure. The block BLK includes a plurality of pages. The page corresponds to a unit in which reading and writing of data are executed. Although illustration is omitted, the memory cell array 10 is provided with a plurality of bit lines BL0 to BLm (“m” is an integer of 1 or more) and a plurality of word lines WL. Each memory cell is associated with, for example, one bit line BL and one word line WL.

The input/output circuit 11 is an interface circuit that takes charge of transmission and reception of input/output signals with the memory controller 2. The input/output signal includes, for example, data DAT, status information, address information, a command, etc. The input/output circuit 11 can input and output data DAT between the sense amplifier module 17 and the memory controller 2. The input/output circuit 11 can output, to the memory controller 2, status information transferred from the register circuit 13. The input/output circuit 11 can output, to the register circuit 13, each of address information and a command transferred from the memory controller 2.

The logic controller 12 controls each of the input/output circuit 11 and the sequencer 14 based on a control signal inputted from the memory controller 2. For example, the logic controller 12 controls the sequencer 14 to enable the memory device 1. The logic controller 12 notifies the input/output circuit 11 that the input/output signal received by the input/output circuit 11 is a command, address information, or the like. The logic controller 12 orders the input/output circuit 11 to input or output an input/output signal.

The register circuit 13 temporarily stores status information, address information, and a command. The status information is updated based on the control of the sequencer 14, and is transferred to the input/output circuit 11. The address information includes a block address, a page address, a column address, and the like. The command includes orders regarding various operations of the memory device 1.

The sequencer 14 controls the entire operation of the memory device 1. The sequencer 14 executes a read operation, a write operation, an erase operation, or the like based on a command and address information stored in the register circuit 13.

The driver circuit 15 generates voltage used in a read operation, a write operation, an erase operation, or the like. Then, the driver circuit 15 supplies the generated voltage to the row decoder module 16, the sense amplifier module 17, or the like.

The row decoder module 16 is a circuit used to select a block BLK to be operated and transfer voltage to a wiring line such as a word line WL. The row decoder module 16 includes a plurality of row decoders RD0 to RDn. The row decoders RD0 to RDn are associated with the blocks BLK0 to BLKn, respectively, and are used to select the block BLK. Each row decoder RD transfers voltage generated by the driver circuit 15 to various wiring lines provided in the memory cell array 10.

The sense amplifier module 17 is a circuit used to transfer voltage to each bit line BL and read data. The sense amplifier module 17 includes a plurality of sense amplifier units SAU0 to SAUm. The sense amplifier units SAU0 to SAUm are associated with the bit lines BL0 to BLm, respectively. Each sense amplifier unit SAU includes a sense amplifier capable of determining data based on the voltage of the associated bit line BL, a latch circuit that temporarily holds data, etc.

A combination of the memory device 1 and the memory controller 2 may constitute one semiconductor device. Examples of such a semiconductor device include a memory card such as an SD™ card, an SSD (solid-state drive), and the like. The memory device 1 may include a plurality of memory cell arrays 10. The memory device 1 may include a row decoder module 16 and a sense amplifier module 17 for each memory cell array 10. A set of the memory cell array 10, the row decoder module 16, and the sense amplifier module 17 is referred to as, for example, a “plane”. That is, the memory device 1 may include a plurality of planes.

### <1-1-2> Circuit Configuration of the Memory Cell Array 10

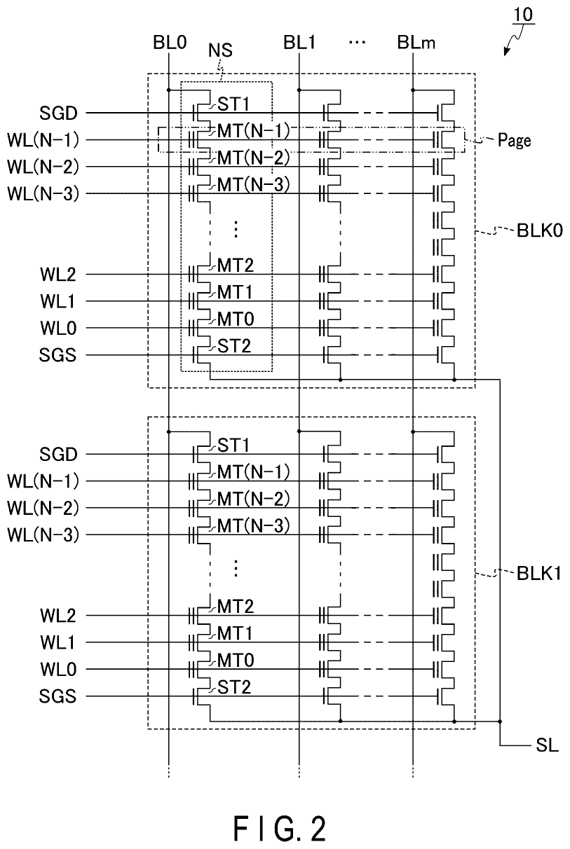

FIG. 2 is a circuit diagram showing an example of a circuit configuration of the memory cell array 10 included in the memory device 1 according to the first embodiment. FIG. 2 shows two blocks BLK0 and BLK1 among the blocks BLK included in the memory cell array 10. As shown in FIG. 2, in the memory cell array 10, select gate lines SGD and SGS and word lines WL0 to WL(N−1) (N is an integer of 2 or more) are provided for each block BLK. Bit lines BL0 to BLm and a source line SL are shared by, for example, a plurality of blocks BLK.

Each block BLK includes a plurality of NAND strings NS. The NAND strings NS are individually associated with the bit lines BL0 to BLm. In other words, each bit line BL is shared by NAND strings NS to which the same column address is allocated among a plurality of blocks BLK. Each NAND string NS is connected between the associated bit line BL and the source line SL. Each NAND string NS includes, for example, N memory cell transistors MT0 to MT(N−1) and select transistors ST1 and ST2. Each memory cell transistor MT is a memory cell including a control gate and a charge storage layer, and holds (stores) data in a nonvolatile manner. Each of the select transistors ST1 and ST2 is used to select the block BLK.

In each NAND string NS, the select transistor ST1, the memory cell transistors MT(N−1) to MT0, and the select transistor ST2 are connected in series in this order. Specifically, the drain end and the source end of the select transistor ST1 are connected to the associated bit line BL and the drain end of the memory cell transistor MT(N−1), respectively. The drain end and the source end of the select transistor ST2 are connected to the source end of the memory cell transistor MT0 and the source line SL, respectively. The memory cell transistors MT0 to MT(N−1) are connected in series between the select transistors ST1 and ST2.

Each select gate line SGD is connected to the gate end of each of the select transistors ST1 included in the associated block BLK. The select gate line SGS is connected to the gate end of each of the select transistors ST2 included in the associated block BLK. The word lines WL0 to WL(N−1) are connected to the control gate ends of the memory cell transistors MT0 to MT(N−1) included in the associated block BLK, respectively. The “page” corresponds to a set of memory cell transistors MT connected to a common word line WL in the same block BLK. The set of memory cell transistors MT connected to a common word line WL in the same block BLK can have a storage capacity of two-page data or more according to the number of bits stored in the memory cell transistors MT.

The circuit configuration of the memory cell array 10 may be another circuit configuration. For example, a plurality of independently controllable select gate lines SGD may be provided in each block BLK. In this case, each block BLK is configured such that selection can be performed in units of a plurality of units individually associated with the select gate lines SGD.

In the following, for the memory device 1 according to the first embodiment, a case where each NAND string NS includes eight memory cell transistors MT0 to MT7 connected to word lines WL0 to WL7, respectively, (that is, a case where N=8) is described as an example.

### <1-1-3> Structure of the Memory Device 1

A structure of the memory device 1 according to the first embodiment will now be described.

In the drawings referred to below, a three-dimensional orthogonal coordinate system is used. The X direction corresponds to the extending direction of the word line WL. The X direction may be referred to as a word line (WL) direction. The Y direction corresponds to the extending direction of the bit line BL. The Y direction may be referred to as a bit line (BL) direction. The Z direction corresponds to the vertical direction with respect to a surface of a semiconductor substrate taken as a reference. The “up and down” is defined based on a direction along the Z direction. The positive direction (upward) corresponds to a direction away from a semiconductor substrate taken as a reference. The XY plane (cross section) corresponds to a plane (cross section) parallel to each of the X direction and the Y direction. The YZ cross section corresponds to a cross section parallel to each of the Y direction and the Z direction. The XZ cross section corresponds to a cross section parallel to each of the X direction and the Z direction.

### (1: External Appearance of the Memory Device 1)

First, an external appearance of the memory device 1 according to the first embodiment is described. The memory device 1 according to the first embodiment is formed by a method in which two semiconductor circuit substrates each with a semiconductor circuit formed thereon are bonded together and the bonded semiconductor circuit substrates are separated on a chip basis. That is, the memory device 1 according to the first embodiment has a bonding surface formed by bonding semiconductor substrates W1 and W2. Each of the semiconductor substrates W1 and W2 is a silicon substrate. In the following, a case where the semiconductor substrate W2 is removed in the manufacturing process of the memory device 1 is described. Depending on the structure of the memory cell array 10, part of the semiconductor substrate W2 may remain after the semiconductor substrates W1 and W2 are bonded together.

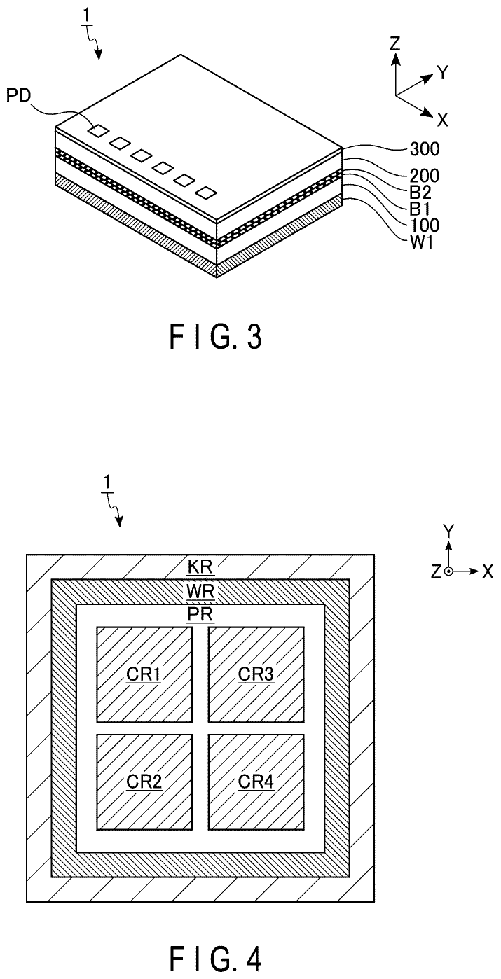

FIG. 3 is a perspective view showing an example of an external appearance of the memory device 1 according to the first embodiment. As shown in FIG. 3, the memory device 1 includes, for example, a semiconductor substrate W1, a CMOS layer 100, a bonding layer B1, a bonding layer B2, a memory layer 200, and a wiring layer 300.

The CMOS layer 100 is placed on the semiconductor substrate W1. The CMOS layer 100 includes a CMOS circuit (control circuit) formed using the semiconductor substrate W1. The semiconductor substrate W1 has an impurity diffusion region, etc. according to the design of the CMOS circuit. The CMOS layer 100 includes, for example, the input/output circuit 11, the logic controller 12, the register circuit 13, the sequencer 14, the driver circuit 15, the row decoder module 16, and the sense amplifier module 17. The CMOS layer 100 may be referred to as a circuit layer.

The bonding layer B1 is placed on the CMOS layer 100. The bonding layer B1 is formed using the semiconductor substrate W1. The bonding layer B1 includes a plurality of bonding pads electrically connected to the CMOS circuit provided in the CMOS layer 100 and forming parts of the semiconductor circuit.

The bonding layer B2 is placed on the bonding layer B1. The bonding layer B2 is formed using a semiconductor substrate W2 (not illustrated). The bonding layer B2 includes a plurality of bonding pads electrically connected to the memory cell array 10 provided in the memory layer 200 and forming parts of the semiconductor circuit. The bonding pads included in the bonding layer B2 are individually connected to the bonding pads included in the bonding layer B1. A portion between the bonding layers B1 and B2 corresponds to a boundary portion between a layer formed using the semiconductor substrate W1 and a layer formed using the semiconductor substrate W2, that is, a bonding surface.

The memory layer 200 is placed on the bonding layer B2. The memory layer 200 includes a memory cell array 10 formed using the semiconductor substrate W2, etc. The memory layer 200 may be referred to as a circuit layer.

The wiring layer 300 is placed on the memory layer 200. The wiring layer 300 is formed after the semiconductor substrates W1 and W2 are bonded together. The wiring layer 300 includes wiring lines connected to the semiconductor circuit provided in the memory layer 200 and a plurality of pad units PD. Each of the pad units PD includes a conductive portion (pad) exposed on the surface of the memory device 1. The pad units PD are used for connection between the memory device 1 and the memory controller 2 or the like, supply of power, etc.

### (2: Planar Layout of the Memory Device 1)

FIG. 4 is a plan view showing an example of a planar layout of the memory device 1 according to the first embodiment. As shown in FIG. 4, the memory device 1 includes, for example, at least one core area CR, a peripheral area PR, a wall area WR, and a kerf area KR.

The core area CR is, for example, a rectangular area provided in the vicinity of the center of the semiconductor substrate W1. In the core area CR, for example, the memory cell array 10, the register circuit 13, the sequencer 14, the driver circuit 15, the row decoder module 16, the sense amplifier module 17, etc. are arranged. In the present example, the memory device 1 includes four core areas CR1 to CR4 arranged in a lattice configuration. The memory device 1 includes, for example, four memory cell arrays 10 arranged corresponding to the four core areas CR1 to CR4.

The wall area WR is, for example, an area in a quadrangular ring shape provided to surround the outer periphery of the four core areas CR1 to CR4. In the wall area WR, at least one sealing unit (not illustrated) provided to surround the outer periphery of the peripheral area PR is placed. The sealing unit is a structure capable of releasing positive charges and negative charges generated inside and outside the wall area WR to the semiconductor substrate W1. The sealing unit can suppress permeation of moisture or the like into the core area CR from the outside of the wall area WR. The sealing unit can suppress stress generated in an interlayer insulating film (for example, tetraethoxysilane (TEOS)) of the memory device 1. The sealing unit can be used also as a crack stopper.

The peripheral area PR is an area located on the inside of the wall area WR and not overlapping with any core area CR. The peripheral area PR has a portion in a quadrangular ring shape provided to surround the outer periphery of the core areas CR1 to CR4 and a portion sandwiched between two adjacent core areas CR. In the peripheral area PR, for example, the input/output circuit 11, the logic controller 12, etc. are arranged. Further, in the peripheral area PR, for example, contacts, etc. for connecting wiring lines provided in the wiring layer 300 and a circuit provided in the CMOS layer 100 or the memory layer 200 are arranged.

The kerf area KR is an area in a quadrangular ring shape provided to surround the outer periphery of the wall area WR. The kerf area KR is in contact with the outermost periphery of the memory device 1. In the kerf area KR, for example, an alignment mark, etc. used at the time of manufacturing the memory device 1 are arranged. The structure of the kerf area KR may be removed in a dicing step of cutting the semiconductor circuit substrate on a chip (memory device 1) basis.

### (3: Planar Layout of the Memory Cell Array 10)

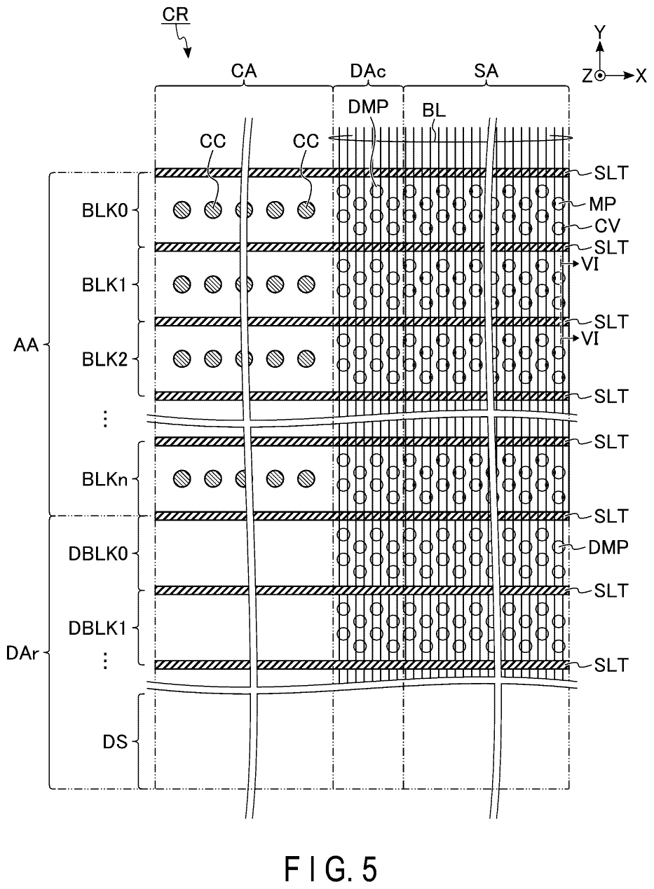

FIG. 5 is a plan view showing an example of a planar layout in the core area CR of the memory cell array 10 included in the memory device 1 according to the first embodiment. As shown in FIG. 5, the memory cell array 10 includes a plurality of slits SLT, a plurality of memory pillars MP, and pluralities of contacts CV and CC. Further, the memory cell array 10 includes, for example, a storage area SA, a dummy area DAc, and a contact area CA arranged in the X direction.

Each slit SLT is a plate-like member provided to extend along the X direction. Each slit SLT has a portion provided to extend along the X direction, and crosses the storage area SA, the dummy area DAc, and the contact area CA along the X direction. The slits SLT are arranged in the Y direction. Each slit SLT divides wiring lines adjacent via the slit SLT (for example, the word lines WL0 to WL7 and the select gate lines SGD and SGS). In each slit SLT, a conductor provided with a spacer of an insulator on its side wall may be placed to be insulated from these wiring lines, or an insulator may be embedded. In the memory cell array 10, each of the areas partitioned along the Y direction by the slits SLT corresponds to one block BLK.

The storage area SA includes a plurality of memory pillars MP. Each memory pillar MP is, for example, a pillar-like member functioning as one NAND string NS. A plurality of memory pillars MP are arranged in a lattice configuration for each block BLK. At least one bit line BL is placed to overlap with each memory pillar MP. The bit lines BL each have a portion provided to extend in the Y direction, and are arranged in the X direction. In the present example, two bit lines BL are arranged to overlap with one memory pillar MP. The memory pillar MP and the bit line BL associated with each other are electrically connected to each other via a contact CV.

The dummy area DAc is placed at an end in the X direction of the storage area SA. In the core area CR, two dummy areas DAc can be arranged to sandwich the storage area SA in the X direction. The dummy area DAc includes a plurality of dummy pillars DMP. The dummy pillars DMP are a pattern for compensating for the configuration of memory pillars MP, and each have a similar structure to the memory pillar MP. For each dummy pillar DMP, a bit line BL may be placed to overlap therewith. The bit lines BL arranged in the dummy area DAc are a pattern for compensating for the configuration of bit lines BL arranged in the storage area SA. The dummy pillar DMP is not connected to a contact CV, nor to a bit line BL. Thus, the dummy pillar DMP is not used to store data.

The contact area CA is used for connection between stacked wiring lines (for example, the word lines WL and the select gate lines SGD and SGS) included in the memory cell array 10 and the row decoder module 16. In the contact area CA, a plurality of contacts CC are arranged for each block BLK. For each block BLK, each of the contacts CC is electrically connected to one associated wiring line of the stacked wiring lines. In each block BLK, at least one contact CC is electrically connected to the select gate line SGS, the word lines WL0 to WL7, and the select gate line SGD.

In the contact area CA, the contacts CC in each block BLK are not limited to an arrangement in a line in the X direction like that shown in FIG. 5, and may be arranged in a lattice configuration for each block BLK. In the core area CR, two contact areas CA may be arranged to sandwich the storage area SA in the X direction. Further, the contact area CA may be placed to divide the storage area SA in the X direction. In the present example, a case where, in the core area CR, two contact areas CA are arranged to sandwich a storage area SA in the X direction will be described.

The core area CR includes an active area AA and a dummy area DAr arranged in the Y direction. Each of the active area AA and the dummy area DAr overlaps with each of the storage area SA, the dummy area DAc, and the contact area CA. A plurality of memory pillars MP used to store data are arranged in an area where the storage area SA and the active area AA overlap. A plurality of contacts CC used to control active blocks BLK are arranged in an area where the contact area CA and the active area AA overlap.

The dummy area DAr is placed in an end portion in the Y direction of the core area CR. In the core area CR, two dummy areas DAr can be arranged to sandwich the active area AA in the Y direction. A dummy block DBLK corresponds to an area partitioned in the Y direction by slits SLT in the dummy area DAr. The dummy area DAr includes at least one dummy block DBLK. In FIG. 5, two dummy blocks DBLK0 and DBLK1 arranged in the Y direction are shown. A plurality of dummy pillars DMP can be arranged in an area of the dummy block DBLK overlapping with the storage area SA and the dummy area DAc.

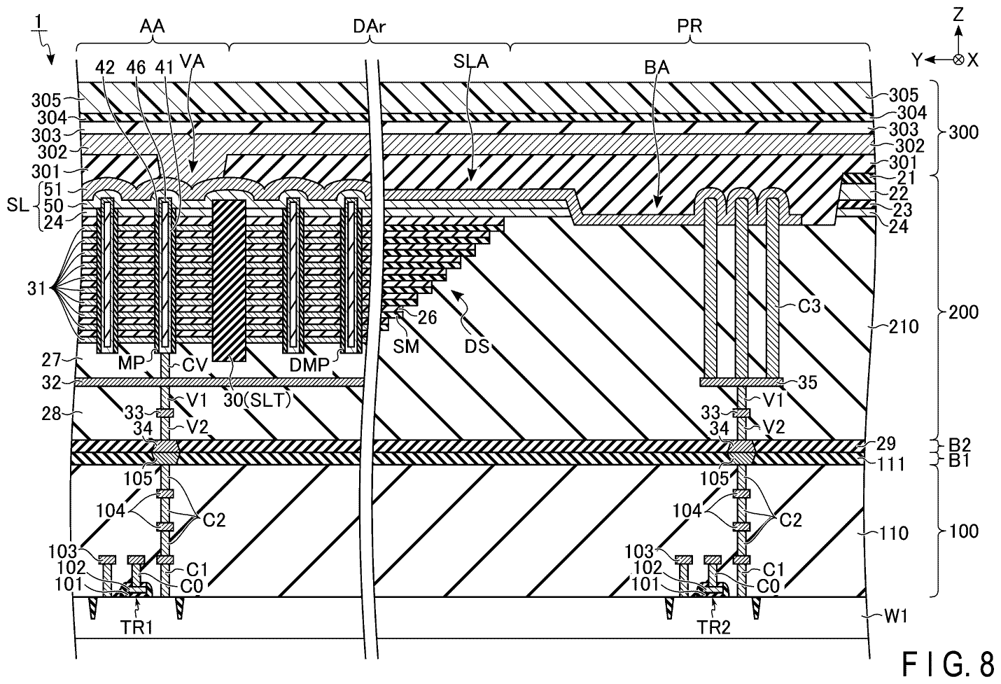

The dummy area DAr further includes a dummy staircase portion DS in a portion corresponding to the outer edge of the core area CR. The dummy staircase portion DS includes end portions of stacked wiring lines provided in a staircase shape. In the dummy staircase portion DS, sacrificial members SM remain in portions corresponding to the stacked wiring lines. The sacrificial member SM is a member used in replacement processing of forming the stacked wiring lines. In the replacement processing, out of alternately stacked sacrificial members SM and insulating layers, the sacrificial members SM are replaced with a conductor; thereby, stacked wiring lines are formed. More specifically, in the replacement processing, the sacrificial members SM are removed via the slit SLT, and a conductor is embedded in the space where the sacrificial members SM have been removed. Thus, sacrificial members SM provided in portions away from the slit SLT can remain without being replaced with the conductor in the replacement processing. Thereby, end portions of the stacked sacrificial members SM are provided in a staircase shape. An example of the structure of the dummy staircase portion DS is shown in FIG. 8 described later.

### (4: Cross-Sectional Structure in the Storage Area SA of the Memory Cell Array 10)

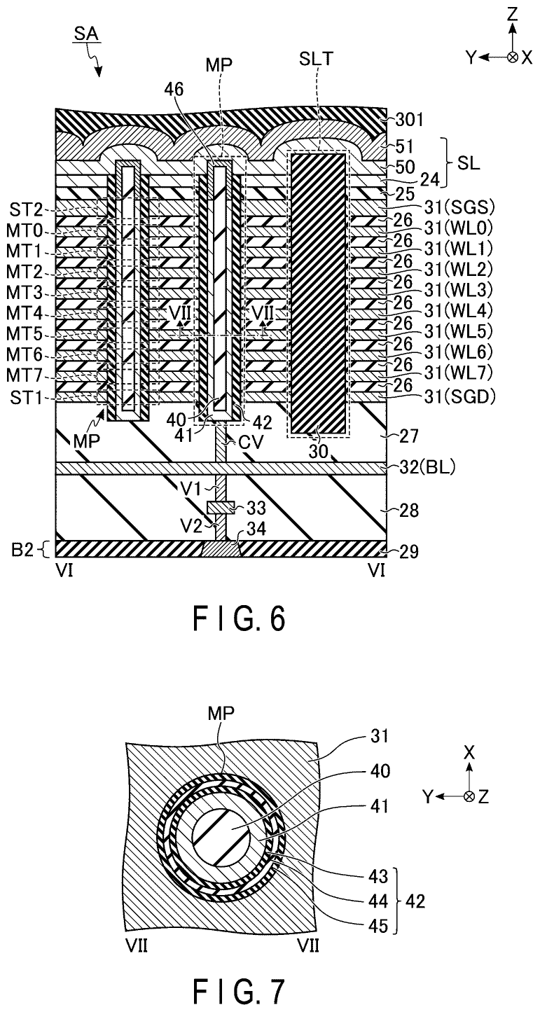

FIG. 6 is a cross-sectional view taken along line VI-VI of FIG. 5, showing an example of a cross-sectional structure in the storage area SA of the memory cell array 10 included in the memory device 1 according to the first embodiment. FIG. 6 shows an example of a structure of a circuit layer including the memory cell array 10 and the bonding layer B2 below the structure, and shows coordinate axes with the semiconductor substrate W1 (not illustrated) as a reference. As shown in FIG. 6, in the storage area SA, the circuit layer including the memory cell array 10 and the bonding layer B2 include, for example, an insulating member 301, a conductive layer 51, a semiconductor layer 50, a semiconductor layer 24, insulating layers 25 to 29, an insulating member 30, conductive layers 31 to 34, and contacts CV, V1, and V2.

A conductive layer 51, a semiconductor layer 50, and a semiconductor layer 24 are provided in this order under an insulating member 301. A set of the conductive layer 51, the semiconductor layer 50, and the semiconductor layer 24 is used as the source line SL. The conductive layer 51 contains a metal material, for example, contains tungsten (W) or aluminum (Al). The conductive layer 51 may contain a barrier metal. Each of the semiconductor layers 50 and 24 is, for example, polysilicon. Each of the semiconductor layers 50 and 24 is doped with an impurity. Thus, each of the semiconductor layers 50 and 24 can function as a conductor.

An insulating layer 25 is provided under the semiconductor layer 24. Under the insulating layer 25, a conductive layer 31 and an insulating layer 26 are alternately provided in the Z direction. That is, a plurality of conductive layers 31 are arranged in the Z direction. Thus, the layer stack corresponding to the memory cell array 10 includes conductive layers 31 and insulating layers 26 alternately provided in the Z direction. The number of conductive layers 31 corresponds to, for example, the number of stacked wiring lines (the select gate line SGS, the word line WL, and the select gate line SGD). In the present example, the ten conductive layers 31 arranged in the Z direction are used as the select gate line SGS, the word lines WL0 to WL7, and the select gate line SGD in this order from the source line SL side. The conductive layer 31 is, for example, formed in a plate shape spreading along the XY plane. The conductive layer 31 contains, for example, tungsten (W).

Under the lowermost conductive layer 31, an insulating layer 27, a conductive layer 32, and an insulating layer 28 are provided in this order. The conductive layer 32 has, for example, a portion formed in a line shape extending in the Y direction. In the present example, the conductive layer 32 is used as the bit line BL. The conductive layer 32 contains, for example, copper (Cu).

A conductive layer 33 is provided below the conductive layer 32. The conductive layer 33 is a wiring line that relays connection between the bit line BL and the sense amplifier module 17. The conductive layer 32 and the conductive layer 33 are connected to each other via a contact V1. A conductive layer 34 is provided below the conductive layer 33. The conductive layer 34 corresponds to a bonding pad. The conductive layer 33 and the conductive layer 34 are connected to each other via a contact V2. The side surfaces of the conductive layer 33 and the contacts V1 and V2 are covered with an insulating layer 28. The insulating layer 28 can include a plurality of insulating films. The side surface of the conductive layer 34 is covered with an insulating layer 29. The insulating layer 29 and the conductive layer 34 are included in the bonding layer B2. The circuit layer including the memory cell array 10 can include a plurality of conductive layers 33. The bonding layer B2 can include a plurality of conductive layers 34. The conductive layer 34 contains, for example, copper (Cu).

The insulating member 30 has a portion formed in a plate shape spreading along the XZ plane. The insulating member 30 divides the semiconductor layer 24, the insulating layer 25, and the alternately provided conductive layers 31 and insulating layers 26. An upper portion of the insulating member 30 is covered with the semiconductor layer 50. In the present example, the insulating member 30 is embedded in the slit SLT. In the slit SLT, a conductor provided with a spacer of an insulator on its side wall may be placed to be insulated from the conductive layers 31.

Each memory pillar MP is provided to extend along the Z direction, and penetrates the semiconductor layer 24, the insulating layer 25, and the alternately provided conductive layers 31 and insulating layers 26. An upper portion of each memory pillar MP is covered with the semiconductor layer 50. The surface of the semiconductor layer 50 is provided in a non-planar shape above the memory pillars MP. Similarly, the surface of the conductive layer 51 is provided in a non-planar shape above the memory pillars MP.

Each memory pillar MP includes, for example, a core member 40, a semiconductor layer 41, a stacked film 42, and a semiconductor layer 46. The core member 40 is an insulator provided to extend along the Z direction. A set of the semiconductor layers 41 and 46 covers the core member 40. The semiconductor layer 41 faces each of the conductive layers 31 arranged in the Z direction in a planar direction (for example, the Y direction). The semiconductor layer 46 is provided in an upper portion of the memory pillar MP. The semiconductor layer 46 corresponds to the semiconductor layer 41 doped with an impurity. The impurity concentration of the semiconductor layer 46 is higher than the impurity concentration of a portion of the semiconductor layer 41 facing the conductive layer 31 in the Y direction. An upper portion of the semiconductor layer 46 is in contact with the semiconductor layer 50. The stacked film 42 covers the side surface of the semiconductor layer 41 and part of the side surface of the semiconductor layer 46. The upper end of the stacked film 42 faces the semiconductor layer 50 in the Z direction. The semiconductor layer 41 (the memory pillar MP) and the conductive layer 32 (the bit line BL) associated with each other are connected to each other via a contact CV.

A portion where the conductive layer 31 used as the select gate line SGS and the memory pillar MP cross each other functions as a select transistor ST2. A portion where the conductive layer 31 used as the word line WL and the memory pillar MP cross each other functions as a memory cell transistor MT. A portion where the conductive layer 31 used as the select gate line SGD and the memory pillar MP cross each other functions as a select transistor ST1. In each memory pillar MP, the semiconductor layer 41 is used as channels (current paths) of the memory cell transistors MT0 to MT7 and the select transistors ST1 and ST2 included in a NAND string NS.

### (5: Cross-Sectional Structure of the Memory Pillar MP)

FIG. 7 is a cross-sectional view taken along line VII-VII of FIG. 6, showing an example of a cross-sectional structure of the memory pillar MP included in the memory device 1 according to the first embodiment. FIG. 7 shows a cross section including the memory pillar MP and the conductive layer 31 and parallel to the surface of the semiconductor substrate W1. As shown in FIG. 7, the stacked film 42 includes, for example, a tunnel insulating film 43, an insulating film 44, and a block insulating film 45. The tunnel insulating film 43 surrounds the side surface of the semiconductor layer 41. The insulating film 44 surrounds the side surface of the tunnel insulating film 43. The block insulating film 45 surrounds the side surface of the insulating film 44. The conductive layer 31 surrounds the side surface of the block insulating film 45. Each of the tunnel insulating film 43 and the block insulating film 45 contains, for example, silicon oxide (SiO₂). The insulating film 44 is used as a charge storage layer of the memory cell transistor MT. The insulating film 44 contains, for example, silicon nitride (SiN).

### (6: Cross-Sectional Structure of the Memory Device 1 in the BL Direction)

FIG. 8 is a cross-sectional view showing an example of a cross-sectional structure of the memory device 1 according to the first embodiment, and shows a cross section along the BL direction (the Y direction). FIG. 8 shows parts of the active area AA, the dummy area DAr, and the peripheral area PR, and shows coordinate axes with the semiconductor substrate W1 as a reference. As shown in FIG. 8, the CMOS layer 100 includes an insulating layer 110. The bonding layer B1 includes an insulating layer 111. The memory layer 200 includes an insulating layer 210. The wiring layer 300 includes an insulating member 301, a conductive layer 302, and insulating layers 303, 304, and 305.

The insulating layer 110 is provided on the semiconductor substrate W1. The insulating layer 110 covers at least parts of wiring lines, contacts, elements, etc. provided in the CMOS layer 100. The insulating layer 110 may include a plurality of kinds of insulating films. The insulating layer 111 is provided on the insulating layer 110. The insulating layer 111 covers the side surfaces of bonding pads provided in the bonding layer B1. The insulating layer 29 of the bonding layer B2 is provided on the insulating layer 111.

The insulating layer 210 is provided on the insulating layer 29. The insulating layer 210 covers at least parts of wiring lines, contacts, elements, etc. provided in the memory layer 200. The insulating layer 210 may include a plurality of kinds of insulating films, and can include insulating layers 27 and 28. A semiconductor layer 24 is provided on the insulating layer 210. In part of the peripheral area PR, a member 23, a semiconductor layer 22, and an insulating layer 21 are stacked in this order on the semiconductor layer 24. Details of the member 23, the semiconductor layer 22, and the insulating layer 21 will be described later.

In the active area AA, the dummy area DAr, and the peripheral area PR, the semiconductor layer 50 is provided on the layer stack corresponding to the memory cell array 10. The semiconductor layer 50 covers the semiconductor layer 46 in an upper portion of each memory pillar MP, the semiconductor layer 46 in an upper portion of each dummy pillar DMP, and an upper portion of the insulating member 30 (the slit SLT). Then, the semiconductor layer 50 is electrically connected to the semiconductor layers 41 and 46 of each memory pillar MP. Hereinafter, in a planar view, an area where the semiconductor layer 50 is provided on the semiconductor layer 24 is referred to as a “source line area SLA”. In a planar view, an area of the peripheral area PR that does not include the insulating layer 21, the semiconductor layer 22, the member 23, or the semiconductor layer 24 is referred to as an “insulating area BA”.

In the active area AA, the dummy area DAr, and the peripheral area PR, the conductive layer 51 is provided on the semiconductor layer 50 or the insulating layer 210. The conductive layer 51 covers, via the semiconductor layer 50, the semiconductor layer 46 in an upper portion of each memory pillar MP, the semiconductor layer 46 in an upper portion of each dummy pillar DMP, and an upper portion of the insulating member 30 (the slit SLT). That is, each of the semiconductor layer 50 and the conductive layer 51 has a portion provided to cover an upper portion of each of the memory pillar MP, the dummy pillar DMP, and the slit SLT. Further, in a boundary portion between the source line area SLA and the insulating area BA, the conductive layer 51 has a portion provided along the side surfaces of the semiconductor layers 24 and 50. Further, in the insulating area BA, the conductive layer 51 has a portion provided to cover an upper portion of at least one contact C3. In the insulating area BA, the conductive layer 51 is in contact with an upper portion of at least one contact C3. Thereby, the conductive layer 51 electrically connects a plurality of memory pillars MP and at least one contact C3. The surface of the conductive layer 51 is provided in a non-planar shape above at least one of the set of memory pillars MP and the set of at least one contact C3.

The insulating member 301 is, for example, provided on the conductive layer 51, the insulating layer 210, or the insulating layer 21. The insulating member 301 is provided to be embedded in level differences formed in the source line area SLA and the insulating area BA. The upper surface of the insulating member 301 is planarized. The insulating member 301 includes at least one via VA in the active area AA. The via VA penetrates the insulating member 301. The bottom of the via VA reaches the conductive layer 51.

The conductive layer 302 is provided on the insulating member 301. The conductive layer 302 in the active area AA can have a portion provided along the via VA and connected to the conductive layer 51 via the via VA. Further, in the peripheral area PR and the wall area WR, the conductive layer 302 can have a portion provided on the insulating member 301. The conductive layer 302 is divided (insulated) at least between the peripheral area PR and the wall area WR. The conductive layer 302 can have a portion continuously provided between the active area AA and the peripheral area PR.

The insulating layer 303, the insulating layer 304, and the insulating layer 305 are provided in this order on the insulating member 301 or the conductive layer 302. Each of the insulating member 301 and the insulating layer 303 contains, for example, silicon oxide (SiO₂). The insulating layer 304 contains, for example, silicon nitride (SiN). The insulating layer 305 contains, for example, a polyimide.

In the active area AA, the CMOS layer 100 includes a gate insulating film 101, a gate electrode 102, conductive layers 103 and 104, and contacts C0 to C2, and the bonding layer B1 includes a conductive layer 105. The gate insulating film 101 is provided on the semiconductor substrate W1. The gate electrode 102 of the active area AA is provided on the gate insulating film 101, and is used as a gate electrode of a transistor TR1. The transistor TR1 is included in, for example, the sense amplifier module 17. The conductive layers 103 are wiring lines above the gate electrode 102. The contact C0 connects the gate electrode 102 and a conductive layer 103. The contact C1 connects an impurity diffusion region of the transistor TR1 provided on the semiconductor substrate W1 and a conductive layer 103. The conductive layers 104 are wiring lines provided at heights between the conductive layer 103 and the bonding layer B1. The contacts C2 are provided at heights between the conductive layer 103 and the bonding layer B1. The at least one conductive layer 103 is connected to the conductive layer 105 via at least one contact C2 and at least one conductive layer 104. The conductive layer 105 corresponds to a bonding pad placed in the bonding layer B1. The conductive layer 105 is in contact with the conductive layer 34 placed to face the conductive layer 105 in the bonding layer B2. Thereby, the semiconductor layer 41 in the active area AA is electrically connected to the transistor TR1 via the contact CV, the conductive layers 32 to 34 and 103 to 105, and the contacts CV, V1, V2, C1, and C2.

In the peripheral area PR, like in the active area AA, the CMOS layer 100 includes a gate insulating film 101, a gate electrode 102, conductive layers 103 and 104, and contacts C0 to C2, and the bonding layer B1 includes a conductive layer 105. The gate electrode 102 of the peripheral area PR is used as a gate electrode of a transistor TR2. The transistor TR2 is included in, for example, the driver circuit 15. In the peripheral area PR, the bonding layer B2 includes a conductive layer 34, and the memory layer 200 includes conductive layers 33 and 35 and contacts V1, V2, and C3. The conductive layer 35 is a wiring line provided in the same layer as the conductive layer 32. At least one contact C3 is provided on the conductive layer 35. An upper portion of each contact C3 reaches at least the height of the semiconductor layer 22. The upper portion of each contact C3 is covered with the conductive layer 51, and is electrically connected to the conductive layer 51.

Thereby, the conductive layer 51 in the peripheral area PR is electrically connected to the transistor TR2 via at least one contact C3, the conductive layers 33 to 35 and 103 to 105, and the contacts V1, V2, C1, and C2. Therefore, the semiconductor layer 46 of each memory pillar MP is electrically connected to the transistor TR2 via the semiconductor layer 50, the conductive layer 51, at least one contact C3, the conductive layers 33 to 35 and 103 to 105, and the contacts V1, V2, C1, and C2.

In the memory device 1, the layer stack corresponding to the memory cell array 10 includes, in the dummy area DAr, the insulating layer 26 and the conductive layer 31 alternately stacked in the Z direction, or the insulating layer 26 and a sacrificial member SM alternately stacked in the Z direction. That is, a plurality of sacrificial members SM are arranged in the Z direction. The sacrificial member SM is different in material from each of the insulating layer 26 and the conductive layer 31. The dummy staircase portion DS includes, for example, an insulating layer 26 and a sacrificial member SM alternately stacked in the Z direction. In other words, the layer stack corresponding to the memory cell array 10 has, in the dummy area DAr, a layer stack portion in which insulating layers 26 and sacrificial members SM are alternately stacked in the Z direction. In the layer stack portion, end portions of the stacked sacrificial members SM are provided in a staircase shape. The plurality of dummy pillars DMP penetrate the layer stack corresponding to the memory cell array 10 in the dummy area DAr in the Z direction.

### (7: Cross-Sectional Structure of the Memory Device 1 in the WL Direction)

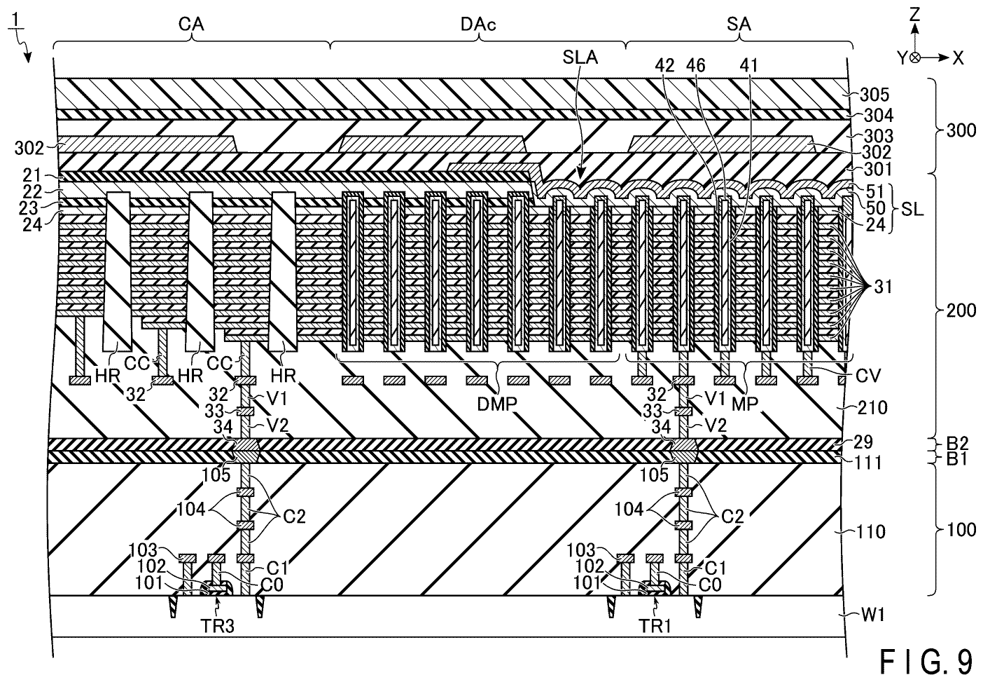

FIG. 9 is a cross-sectional view showing an example of a cross-sectional structure of the memory device 1 according to the first embodiment, and shows a cross section along the WL direction (the X direction). FIG. 9 shows parts of the contact area CA, the dummy area DAc, and the storage area SA, and shows coordinate axes with the semiconductor substrate W1 as a reference. As shown in FIG. 9, part of the source line area SLA overlaps with the dummy area DAc. The dummy area DAc includes an end portion of the conductive layer 51. In the contact area CA and part of the dummy area DAc, a member 23, a semiconductor layer 22, and an insulating layer 21 are stacked in this order on the semiconductor layer 24. In the dummy area DAc, the end portion of the conductive layer 51 has a portion provided to cover part of the insulating layer 21. In the portion provided to cover part of the insulating layer 21, the conductive layer 51 is apart from the dummy pillar DMP.

The contact area CA includes a plurality of columnar members HR. The columnar member HR is configured to maintain the stacked structure in the contact area CA during replacement processing. Specifically, each columnar member HR is provided to extend along the Z direction, and penetrates, for example, the member 23, the semiconductor layer 24, the insulating layer 25, and the alternately provided conductive layers 31 and insulating layers 26. An upper portion of each columnar member HR reaches the semiconductor layer 22. In a case where conductive layers 31 are provided in a staircase shape in the contact area CA, the number of conductive layers 31 penetrated by the columnar member HR may vary according to the position of the columnar member HR. The columnar member HR contains, for example, silicon oxide (SiO₂).

In the contact area CA, like in the active area AA, the CMOS layer 100 includes a gate insulating film 101, a gate electrode 102, conductive layers 103 and 104, and contacts C0 to C2, and the bonding layer B1 includes a conductive layer 105. The gate electrode 102 of the contact area CA is used as a gate electrode of a transistor TR3. The transistor TR3 is included in, for example, the row decoder module 16. In the contact area CA, the bonding layer B2 includes a conductive layer 34, and the memory layer 200 includes conductive layers 32 and 33 and contacts V1, V2, and CC. Each conductive layer 31 is electrically connected to the transistor TR3 via the contact CC, the conductive layers 32 to 34 and 103 to 105, and the contacts V1, V2, C1, and C2.

In the present example, in the wiring layer 300, the conductive layer 302 is provided to extend in the Y direction. A plurality of conductive layers 302 are arranged in the X direction. The space between adjacent conductive layers 302 is filled with the insulating layer 303. In a cross section along the X direction, the semiconductor layer 50 may be provided to cover at least the source line area SLA. The configuration is not limited thereto, and in the memory device 1 according to the first embodiment, the semiconductor layer 50 may be provided between the insulating layer 21 and the conductive layer 51 in the dummy area DAc.

### (8: Planar Layout of Bonding Pads)

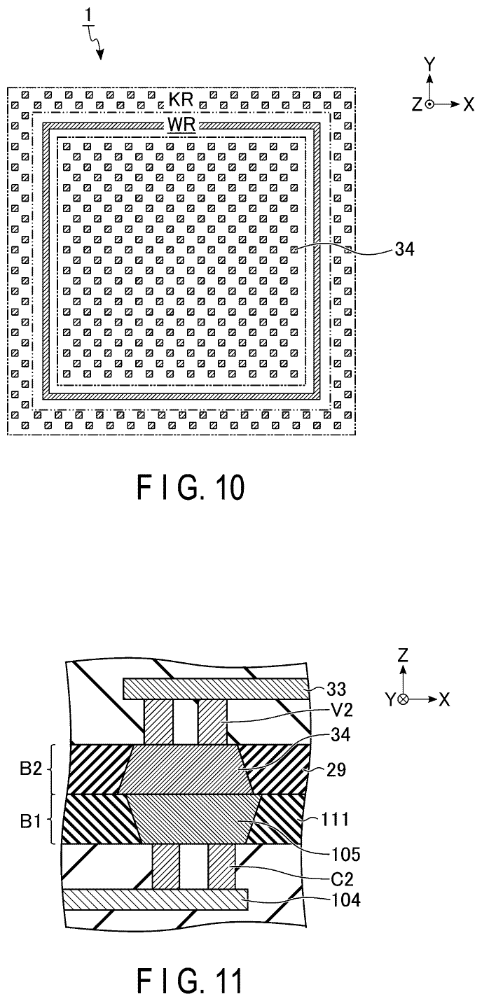

FIG. 10 is a plan view showing an example of arrangement of bonding pads in the memory device 1 according to the first embodiment. FIG. 10 shows, as an example of arrangement of bonding pads, an arrangement of conductive layers 34 provided corresponding to the semiconductor substrate W2. As shown in FIG. 10, on the inside of the wall area WR, a plurality of conductive layers 34 are, for example, arranged in a staggered configuration. The conductive layers 34 may be arranged in a lattice configuration. Some of the conductive layers 34 correspond to a dummy pattern not used for the operation of the memory device 1. Each conductive layer 105 provided corresponding to the semiconductor substrate W1 is placed to face the associated conductive layer 34. The wall area WR may include conductive layers 34 and 105 provided in a ring shape corresponding to the sealing unit. Further, a plurality of conductive layers 34 may be arranged in the kerf area KR.

### (9: Detailed Cross-Sectional Structure of Bonding Pads)

FIG. 11 is a cross-sectional view showing an example of a detailed cross-sectional structure of the vicinity of two bonding pads arranged to face each other in the memory device 1 according to the first embodiment. FIG. 11 shows a conductive layer 105 (a bonding pad) formed using a semiconductor substrate W1 (not illustrated), a conductive layer 34 (a bonding pad) formed using a semiconductor substrate W2 (not illustrated), and some contacts C2 and V2 and conductive layers 104 and 33 connected to them.

As shown in FIG. 11, the two bonding pads arranged to face each other can have different tapered shapes based on the etching direction during formation. Specifically, the conductive layer 105 formed using the semiconductor substrate W1 has, for example, an inverse tapered shape. The conductive layer 34 formed using the semiconductor substrate W2 has, for example, a normal tapered shape. Thus, in the shape of a cross section along the Z direction in a portion where the conductive layer 105 and the conductive layer 34 are joined, the side wall of the portion may not have a straight-lined shape but the portion may forms a non-rectangular shape in the cross section. Further, a set of two bonding pads arranged to face each other can be joined in a shifted manner according to alignment at the time of bonding processing. Therefore, a level difference can be formed between the side surface of the conductive layer 105 and the side surface of the conductive layer 34.

A set of two bonding pads arranged to face each other may have a boundary, or may be integrated. A bonding pad and a contact C2 or V2 connected to the bonding pad may be integrally formed. To a bonding pad, a corresponding plurality of contacts C2 or V2 may be connected. For example, the conductive layer 105 may be connected to the conductive layer 104 via a plurality of contacts C2. Similarly, the conductive layer 34 may be connected to the conductive layer 33 via a plurality of contacts V2. In a case where a set of two bonding pads arranged to face each other is a dummy pattern, the connection of the contact C2 to the conductive layer 105 and the connection of the contact V2 to the conductive layer 34 can be omitted.

### (10: Planar Layout of Semiconductor Layers 22)

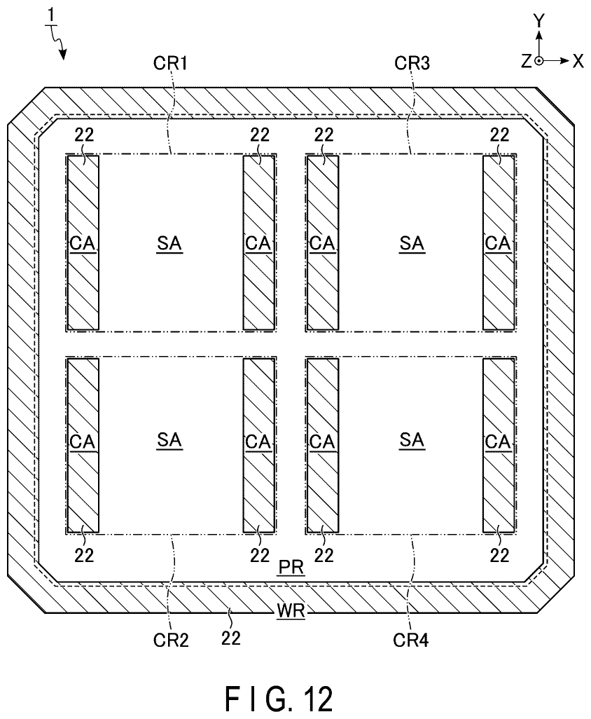

FIG. 12 is a plan view showing an example of a planar layout of semiconductor layers 22 in the memory device 1 according to the first embodiment. As shown in FIG. 12, the semiconductor layer 22 is, for example, placed in the contact area CA of each core area CR, and not included in the storage area SA. Further, the semiconductor layer 22 is not included in most of the peripheral area PR including a portion along the outer periphery of each core area CR, and a semiconductor layer 22 provided in one of two adjacent core areas CR and a semiconductor layer 22 provided in the other core area CR are apart from each other. The wall area WR may include a semiconductor layer 22 provided in a ring shape corresponding to the sealing unit.

### (11: Planar Layout of Conductive Layers 302)

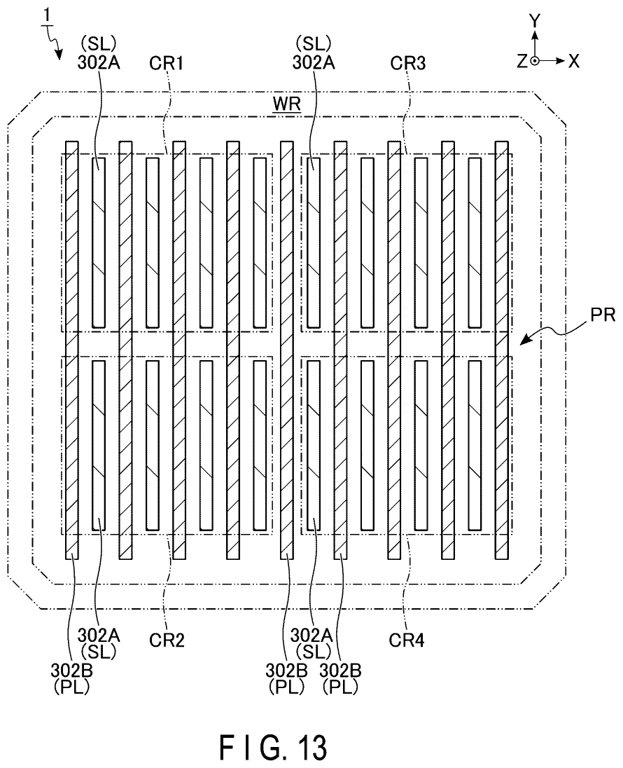

FIG. 13 is a plan view showing an example of a planar layout of conductive layers 302 in the memory device 1 according to the first embodiment. As shown in FIG. 13, a plurality of conductive layers 302 are arranged on the inside of the wall area WR. Each of the conductive layers 302 has, for example, a portion provided to extend in the Y direction. The conductive layers 302 include, for example, conductive layers 302A used as shunt wiring lines of the source line SL and conductive layers 302B used as parts of a power supply line PL.

The conductive layer 302A corresponds to, for example, the conductive layer 302 having a portion connected to the conductive layer 51 via the via VA in the core area CR shown in FIG. 8. In the present example, conductive layers 302A are provided for each core area CR. In the present example, conductive layers 302B are provided to extend from end portions of the core areas CR1 and CR3 on the outer peripheral side of the memory device 1 to end portions of the core areas CR2 and CR4 on the outer peripheral side of the memory device 1. In each core area CR, the conductive layers 302A and 302B are, for example, alternately arranged in the X direction. The conductive layer 302A is, for example, not included in the peripheral area PR. The arrangement of conductive layers 302A and 302B can be changed according to the layout of pad units PD (not illustrated) and the CMOS circuit, as appropriate.

### (12: Detailed Planar Layout of the Vicinity of the Pad Unit PD)

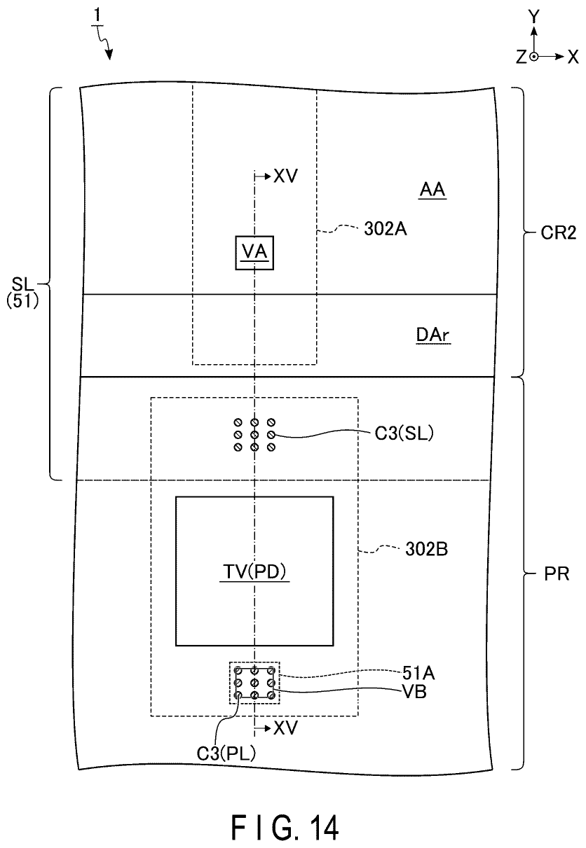

FIG. 14 is a plan view showing an example of a planar layout of the vicinity of the pad unit PD in the memory device 1 according to the first embodiment. FIG. 14 shows a pad unit PD used for connection to the input/output circuit 11, the logic controller 12, or the like in the memory device 1, and part of each of the core area CR2 and the peripheral area PR in the vicinity thereof. As shown in FIG. 14, the peripheral area PR includes a via TV used as the pad unit PD and a via VB.

The via TV is placed not to overlap with, in the Z direction, an area where the conductive layer 51 used as the source line SL is provided. At the bottom of the via TV, for example, the conductive layer 302B used as the power supply line PL is exposed. A portion of the conductive layer 302B exposed at the bottom of the via TV is used as the pad unit PD. The conductive layer 302B is, for example, provided in a rectangular shape in a planar view. The conductive layer 302B has a portion overlapping with the via VB. The via VB overlaps with, in the Z direction, a conductive layer 51A used as a wiring line for relaying connection between the conductive layer 302B and at least one contact C3. The conductive layer 51A is apart from the conductive layer 51 used as the source line SL. The conductive layer 302B is electrically connected to at least one contact C3 via a portion along the via VB and the conductive layer 51A.

The conductive layer 302A used as a shunt wiring line of the source line SL is, for example, provided in a rectangular shape in a planar view. The conductive layer 302A is included in the active area AA and the dummy area DAr, and is apart from the conductive layer 302B. The source line SL to which the conductive layer 302A is connected is electrically connected to at least one contact C3 in an area where the conductive layer 51 used as the source line SL extends up into the peripheral area PR.

### (13: Cross-Sectional Structure of the Vicinity of the Pad Unit PD)

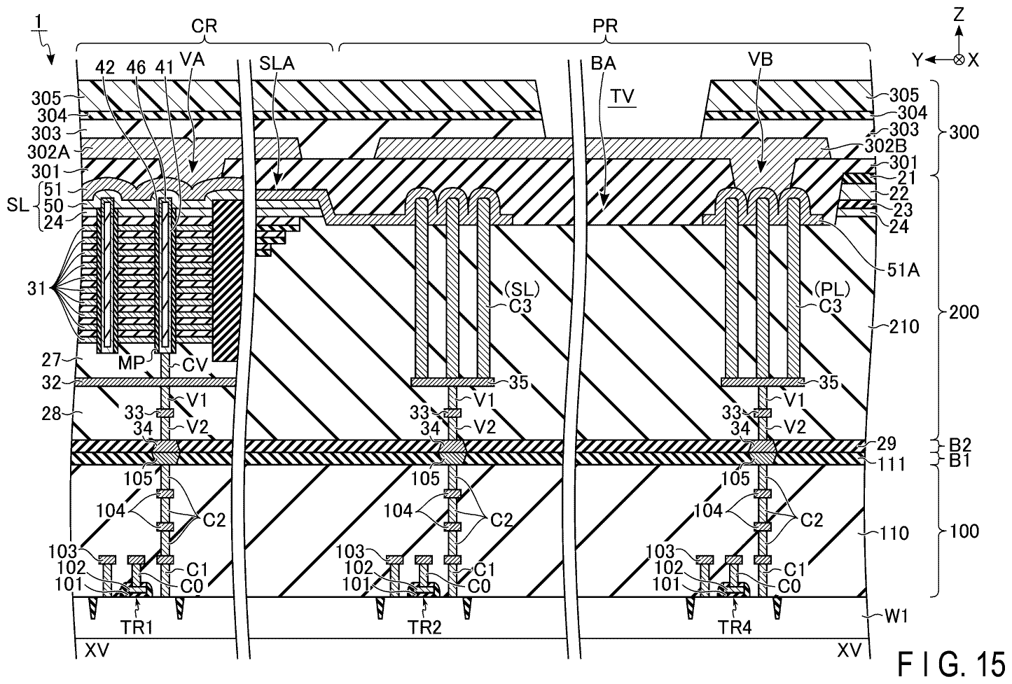

FIG. 15 is a cross-sectional view taken along line XV-XV of FIG. 14, showing an example of a cross-sectional structure of the vicinity of the pad unit PD in the memory device 1 according to the first embodiment. As shown in FIG. 15, the via TV penetrates the insulating layers 303, 304, and 305. At the bottom of the via TV, part of the conductive layer 302B used as the power supply line PL is exposed. In the first embodiment, a portion of the conductive layer 302B where the surface is exposed through the via TV does not have a portion overlapping with the conductive layer 51 used as the source line SL in the Z direction.

The conductive layer 302B has a portion provided along the via VB, and is connected to a plurality of contacts C3 via the via VB and the conductive layer 51A. Then, the conductive layer 302B is electrically connected to a transistor TR4 on the semiconductor substrate W1 via the contacts C3. The transistor TR4 is included in, for example, a power supply circuit of the memory device 1. That is, the conductive layer 302B corresponding to the pad unit PD is, via the memory layer 200, electrically connected to a power supply circuit included in the CMOS circuit provided in the CMOS layer 100. The conductive layer 302B has a portion facing, in the Z direction, the contacts C3 connected to the conductive layer 51 (the source line SL).

### <1-2> Manufacturing Method

Next, a method of manufacturing the memory device 1 according to the first embodiment is described.

### <1-2-1> Structure of the Memory Cell Array 10 Before Bonding

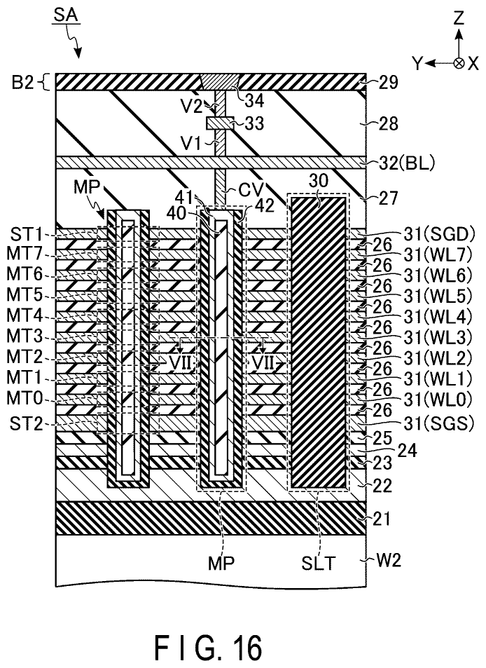

FIG. 16 is a cross-sectional view showing an example of a cross-sectional structure in the manufacturing process of the memory cell array 10 included in the memory device 1 according to the first embodiment. FIG. 16 shows an example of a structure of a circuit layer including the memory cell array 10 before bonding the semiconductor substrate W1 and the semiconductor substrate W2 and the bonding layer B2 above the structure, and shows coordinate axes with the semiconductor substrate W2 as a reference. As shown in FIG. 16, in the storage area SA, the circuit layer including the memory cell array 10 before bonding and the bonding layer B2 include, for example, an insulating layer 21, a semiconductor layer 22, a member 23, a semiconductor layer 24, insulating layers 25 to 29, an insulating member 30, conductive layers 31 to 34, and contacts CV, V1, and V2.

An insulating layer 21 is provided on the semiconductor substrate W2. A semiconductor layer 22, a member 23, and a semiconductor layer 24 are provided in this order on the insulating layer 21. Using the portion where the semiconductor layer 22, the member 23, and the semiconductor layer 24 are provided, a source line SL is formed after bonding the semiconductor substrates W1 and W2. Each of the semiconductor layer 22 and the member 23 is used as, for example, an etching stopper layer at the time of forming the memory pillar MP and the slit SLT. Each of the semiconductor layers 22 and 24 is, for example, polysilicon. The member 23 contains, for example, silicon oxide (SiO₂).

An insulating layer 25 is provided on the semiconductor layer 24. On the insulating layer 25, a conductive layer 31 and an insulating layer 26 are alternately provided in the Z direction. An insulating member 30 divides the member 23, the semiconductor layer 24, the insulating layer 25, and the alternately provided conductive layers 31 and insulating layers 26. The bottom of the insulating member 30 reaches the semiconductor layer 22. Each memory pillar MP is provided to extend along the Z direction, and penetrates the member 23, the semiconductor layer 24, the insulating layer 25, and the alternately provided conductive layers 31 and insulating layers 26. The bottom of each memory pillar MP reaches the semiconductor layer 22. The structure of the other parts of the memory cell array 10 before bonding processing is similar to the structure of the memory cell array 10 described using FIG. 6.

<1-2-2> Method of Forming the Source Line SL and the Wiring Layer 300 after Bonding

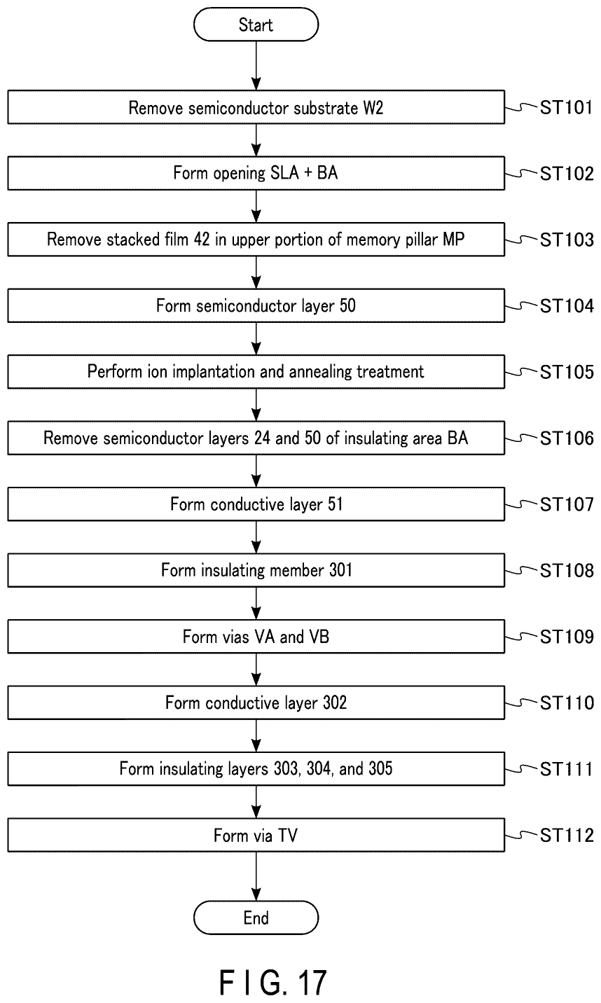

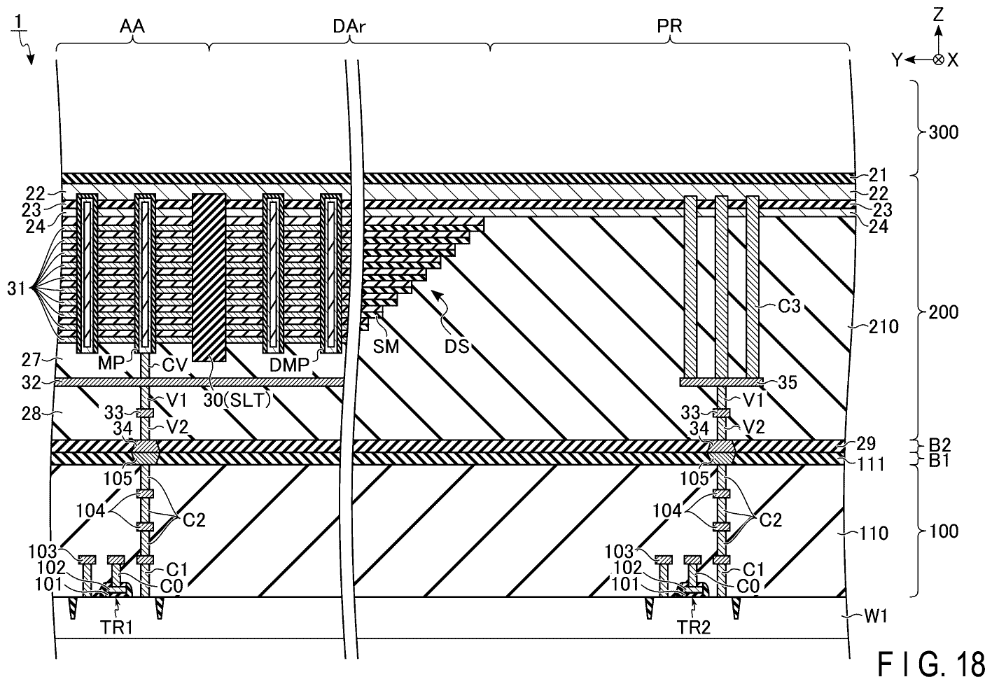

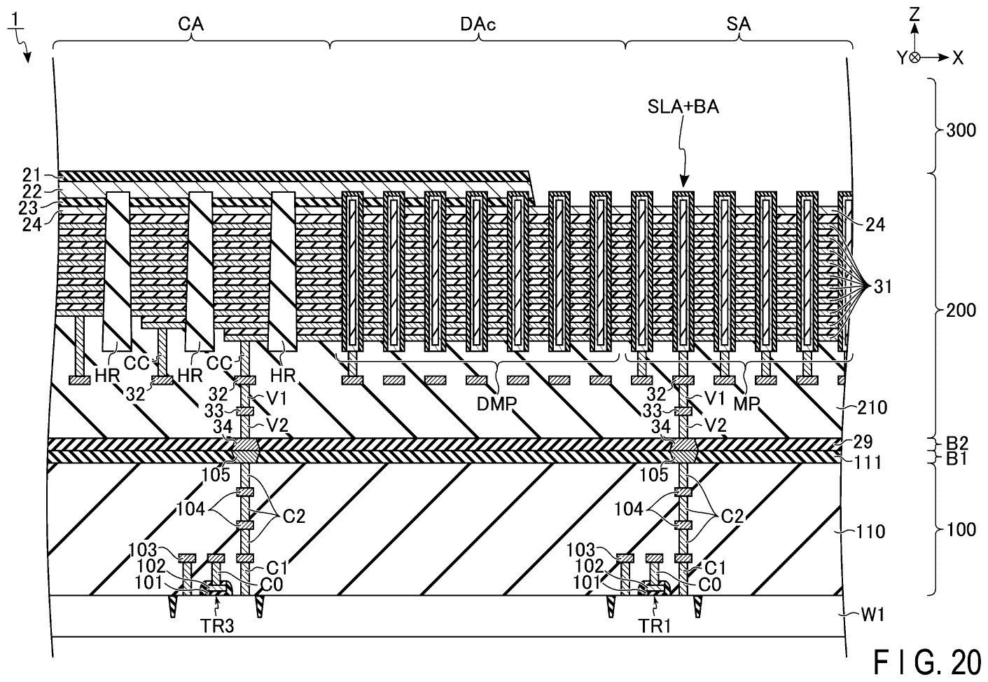

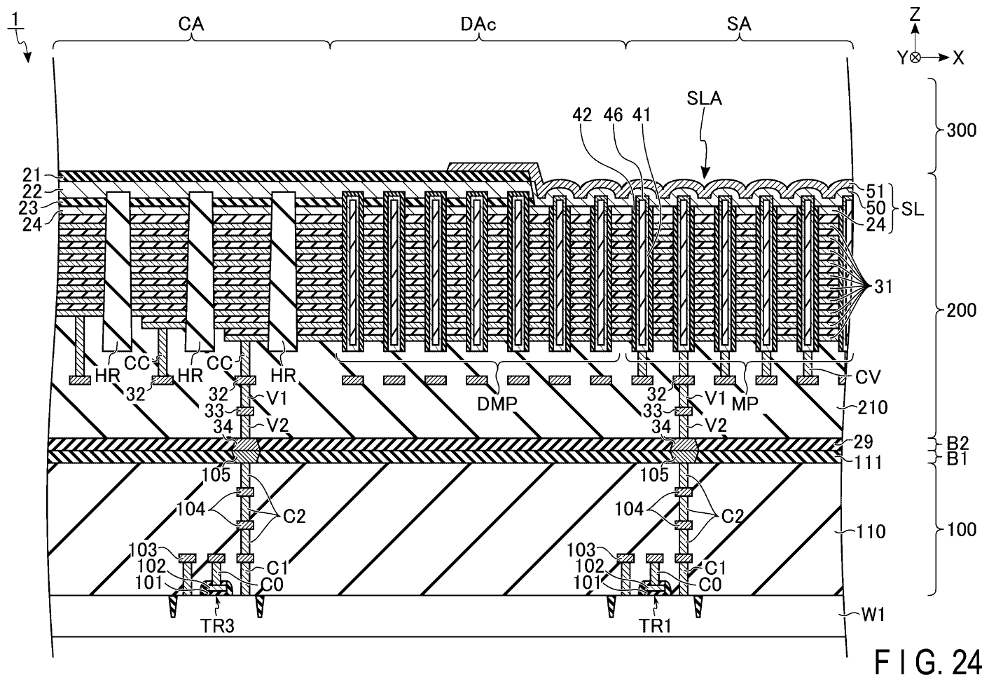

Hereinbelow, as a method of manufacturing the memory device 1 according to the first embodiment, a method of forming the source line SL and the wiring layer 300 after bonding the semiconductor substrate W1 and the semiconductor substrate W2 is described with reference to FIG. 17 as appropriate. FIG. 17 is a flowchart showing an example of a method of manufacturing the memory device 1 according to the first embodiment. Each of FIGS. 18 to 26 is a cross-sectional view showing an example of a cross-sectional structure in the manufacturing process of the memory device 1 according to the first embodiment. Each of FIGS. 18, 19, 21, 22, 23, 25, and 26 corresponds to a cross section along the BL direction, and shows a similar area to FIG. 8. Each of FIGS. 20 and 24 corresponds to a cross section along the WL direction, and shows a similar area to FIG. 9.

First, as shown in FIG. 18, the semiconductor substrate W2 is removed from the semiconductor substrates W1 and W2 after bonding (step ST101). For example, CMP (chemical mechanical polishing) processing is used to remove the semiconductor substrate W2. By the processing of step ST101, the surface of the insulating layer 21 is exposed. Part of the insulating layer 21 may be removed by this step. The insulating layer 21 may be formed after the semiconductor substrate W1 and the semiconductor substrate W2 are bonded together. In this case, in the processing of step ST101, for example, the insulating layer 21 is formed after the semiconductor substrate W2 is removed.

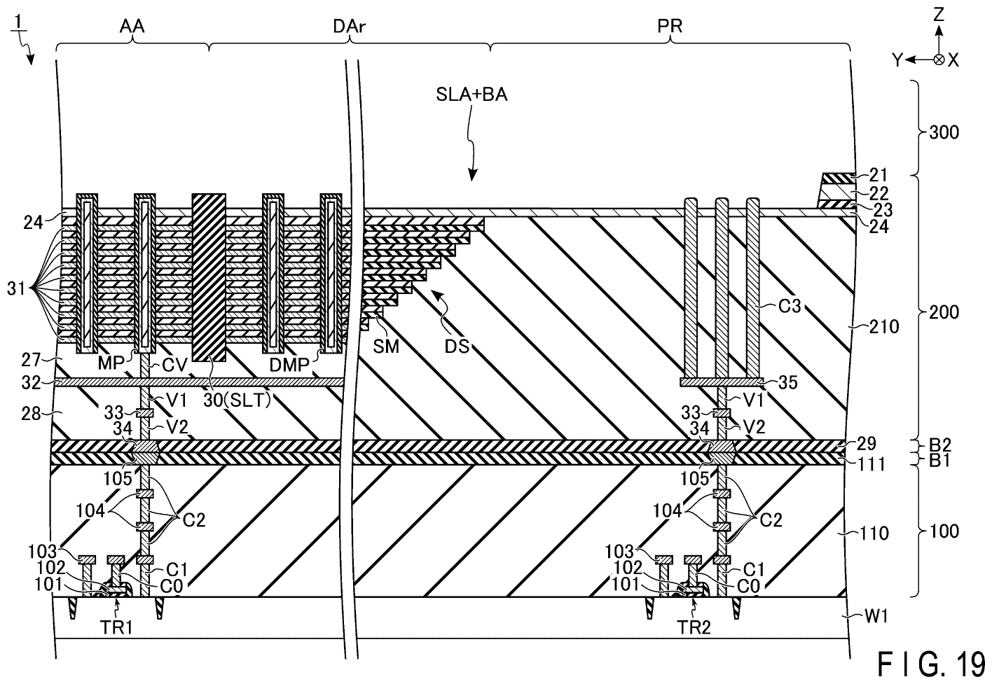

Next, as shown in FIGS. 19 and 20, an opening SLA+BA is formed (step ST102). Specifically, first, a mask in which the portion of a source line area SLA and an insulating area BA is opened in a planar view is formed. After that, each of the insulating layer 21, the semiconductor layer 22, and the member 23 is removed in the opening of the mask by anisotropic etching processing, and an opening SLA+BA is formed. That is, the opening SLA+BA corresponds to an area where the source line area SLA and the insulating area BA are combined. In the processing of step ST102, the semiconductor layer 24 can be used as an etching stopper layer. As shown in FIG. 19, an end portion of the opening SLA+BA in the BL direction is included in the peripheral area PR. As shown in FIG. 20, an end portion of the opening SLA+BA in the WL direction is included in the dummy area DAc. In the opening SLA+BA, upper portions of a plurality of memory pillars MP, upper portions of insulating members 30, upper portions of a plurality of dummy pillars DMP, and upper portions of a plurality of contacts C3 are exposed. The upper portion of each of the memory pillars MP, the insulating members 30, the dummy pillars DMP, and the contacts C3 protrudes upward from the semiconductor layer 24 in the opening SLA+BA.

Next, the stacked film 42 in an upper portion of the memory pillar MP is removed (step ST103). Specifically, for example, in the opening SLA+BA, the stacked film 42 provided above the semiconductor layer 24 is selectively removed by wet etching processing. Thereby, in the opening SLA+BA, the semiconductor layer 41 in an upper portion of each memory pillar MP and the semiconductor layer 41 in an upper portion of each dummy pillar DMP are exposed. In this step, an upper portion of the columnar member HR in the contact area CA is protected by the semiconductor layer 22.

Next, a semiconductor layer 50 is formed (step ST104). In the processing of step ST104, for example, CVD (chemical vapor deposition) processing is used to form the semiconductor layer 50. The semiconductor layer 50 at this point of time is, for example, amorphous silicon.

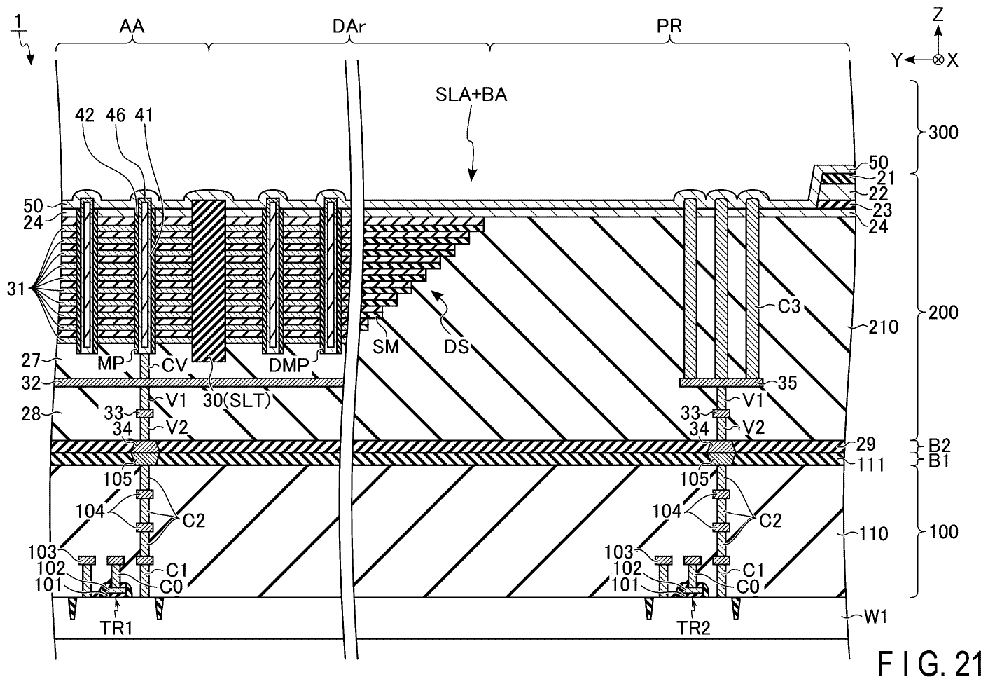

Next, ion implantation and annealing treatment are executed (step ST105). This step is performed on the opening SLA+BA. Specifically, first, an impurity is implanted into an upper portion of each memory pillar MP by ion implantation processing. After that, annealing treatment is executed, and thereby the implanted impurity is diffused to an upper portion of the semiconductor layer 41. Further, crystallization occurs in the semiconductor layer 50, and the semiconductor layer 50 is modified from amorphous silicon to polysilicon. In FIG. 21, the semiconductor layer 41 thus doped with an impurity is shown as a semiconductor layer 46. In this step, also the semiconductor layer 24 that was exposed at the opening SLA+BA can be doped with an impurity. The impurity doped in the semiconductor layer 41 by this step is, for example, at least one of phosphorus (P) and arsenic (As). Thus, the semiconductor layer 24 in the active area AA can contain an impurity, and can function as a conductor. On the other hand, in an area of the peripheral area PR where the semiconductor layer 22 remains, the semiconductor layer 24 does not contain such an impurity, and is not used as a conductor.

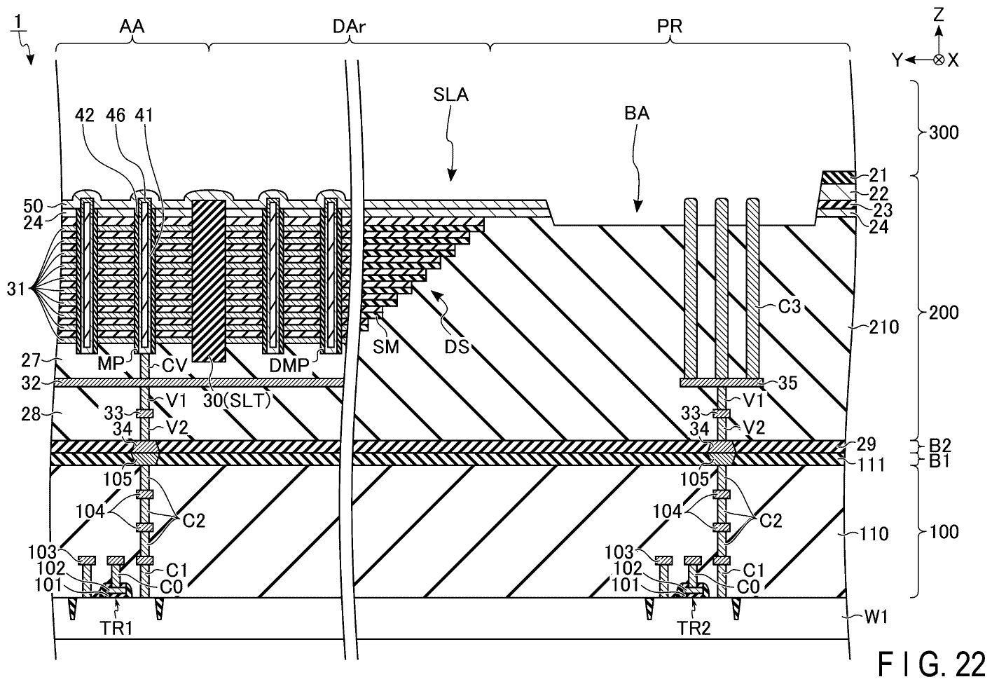

Next, as shown in FIG. 22, the semiconductor layers 24 and 50 of the insulating area BA are removed (step ST106). Thereby, in the insulating area BA, the surface of the insulating layer 210 and an upper portion of at least one contact C3 provided in the insulating area BA are exposed. In the processing of step ST106, also the semiconductor layer 50 provided on the insulating layer 21 and the semiconductor layer 50 provided on the side surfaces of the insulating layer 21, the semiconductor layer 22, and the member 23 can be removed. A portion of the opening SLA+BA not overlapping with the insulating area BA corresponds to the source line area SLA.

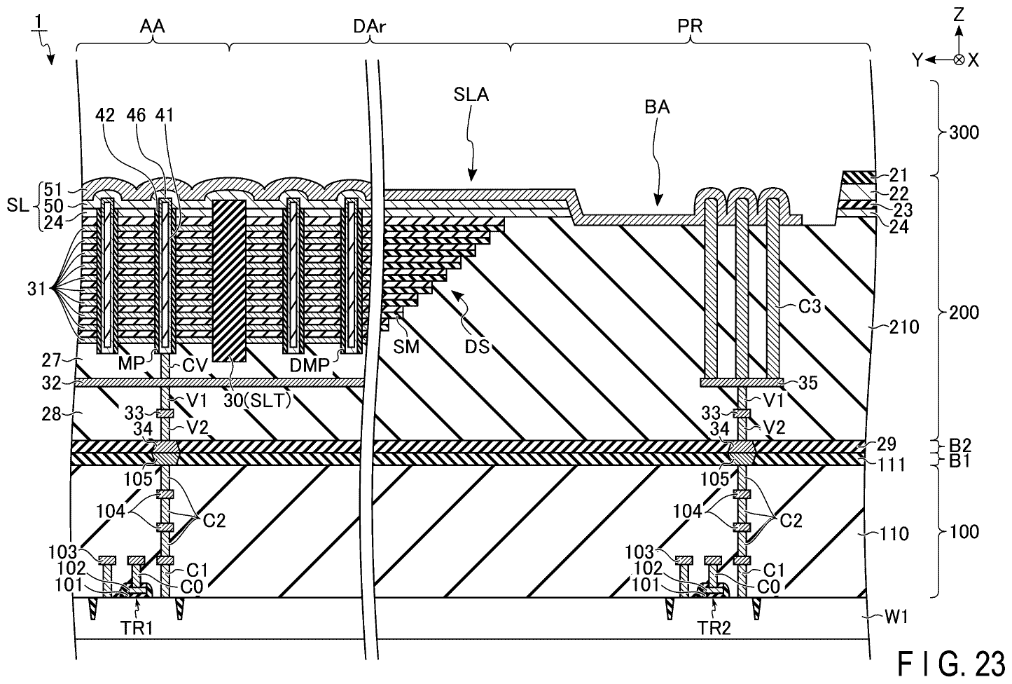

Next, as shown in FIGS. 23 and 24, a conductive layer 51 is formed (step ST107). Specifically, first, a conductive layer 51 is formed on the surfaces of the semiconductor layer 50, the insulating layer 210, and the insulating layer 21, etc. by CVD processing or the like. The conductive layer 51 has a portion covering an upper portion of the semiconductor layer 46 of each memory pillar MP, a portion covering an upper portion of the semiconductor layer 46 of each dummy pillar DMP, and a portion covering an upper portion of each contact C3. After that, a mask is formed, and the conductive layer 51 is processed by anisotropic etching processing. The conductive layer 51 processed in this step is provided to, for example, electrically connect the semiconductor layer 41 of each memory pillar MP and each contact C3. Thereby, a similar structure to the conductive layer 51 shown in FIGS. 8 and 9 is formed. As shown in FIG. 23, an end portion of the conductive layer 51 in the BL direction is included in the insulating area BA. As shown in FIG. 24, an end portion of the conductive layer 51 in the WL direction is included in the dummy area DAc.

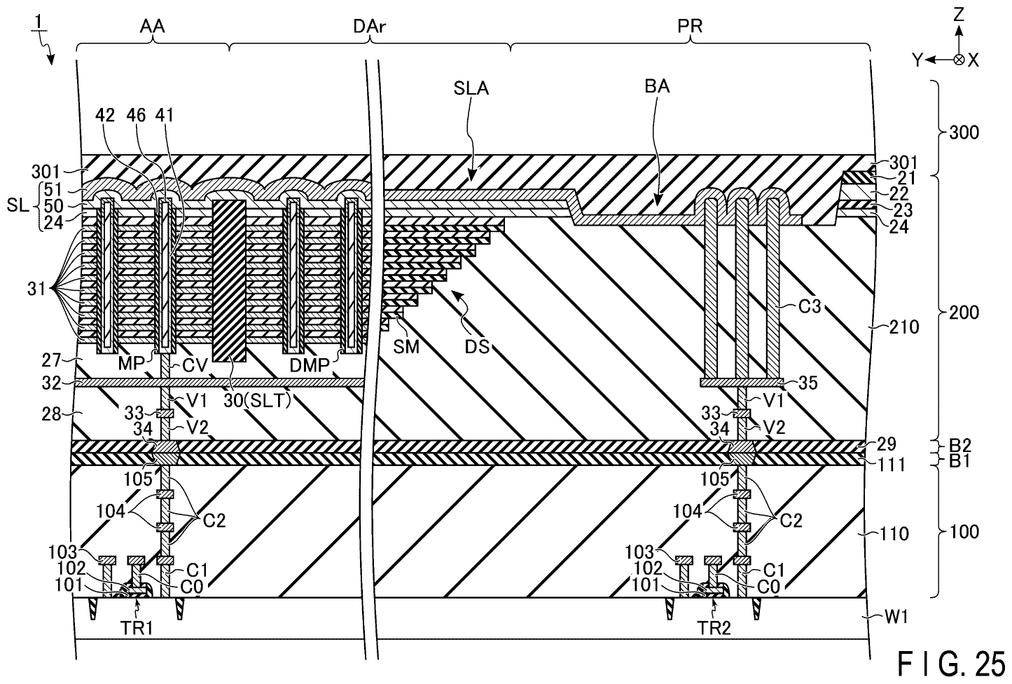

Next, as shown in FIG. 25, an insulating member 301 is formed (step ST108). Specifically, by the processing of step ST108, an insulating member 301 is embedded in the opening SLA+BA (the source line area SLA and the insulating area BA). After that, the surface of the insulating member 301 is planarized by CMP processing or the like.

Next, vias VA and VB are formed (step ST109). Specifically, first, a mask in which the portions of vias VA and VB are opened in a planar view is formed. After that, the insulating member 301 is removed in the openings of the mask by anisotropic etching processing, and vias VA and VB are formed. At the bottom of each of the vias VA and VB, the surface of the conductive layer 51 is exposed.

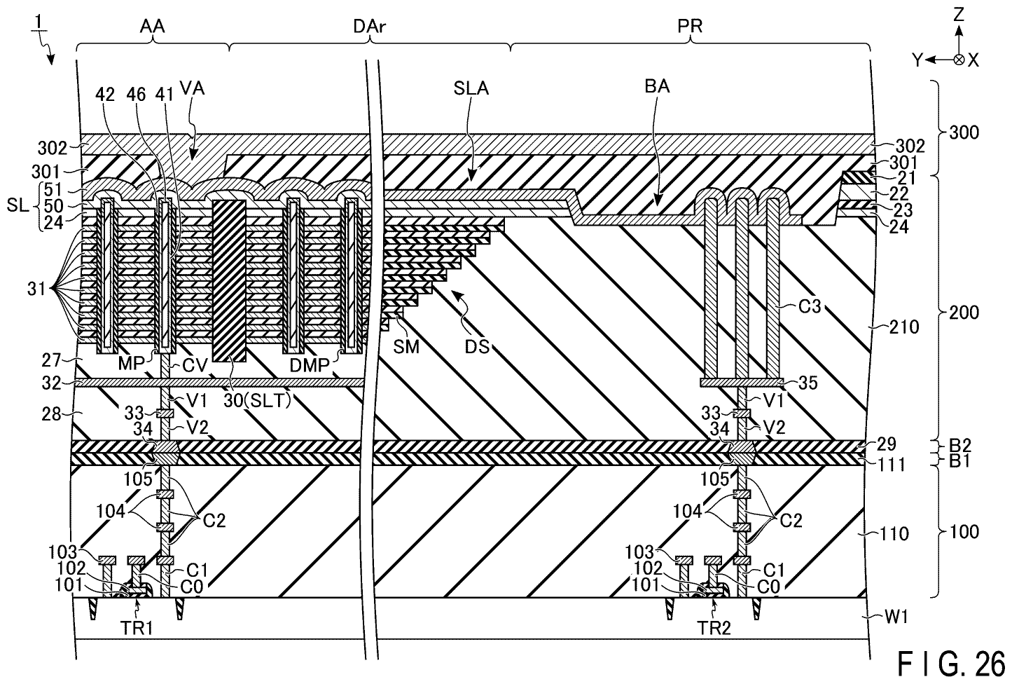

Next, as shown in FIG. 26, a conductive layer 302 is formed (step ST110). By the conductive layer 302 being formed, each of the via VA and the via VB (not illustrated) is filled. After that, the conductive layer 302 is processed into a desired configuration by photolithography processing and etching processing. The conductive layer 302 may be formed using a damascene method.

After that, insulating layers 303, 304, and 305 are formed (step ST111), and a via TV is formed (step ST112). Thereby, the structure of the memory device 1 shown in FIGS. 8 and 9 is completed.

### <1-3> Advantageous Effects of the First Embodiment

In the memory device 1 according to the first embodiment described hereinabove, the chip size can be reduced, and the manufacturing cost of the memory device 1 can be suppressed. Advantageous effects of the memory device 1 according to the first embodiment will now be described using a comparative example.

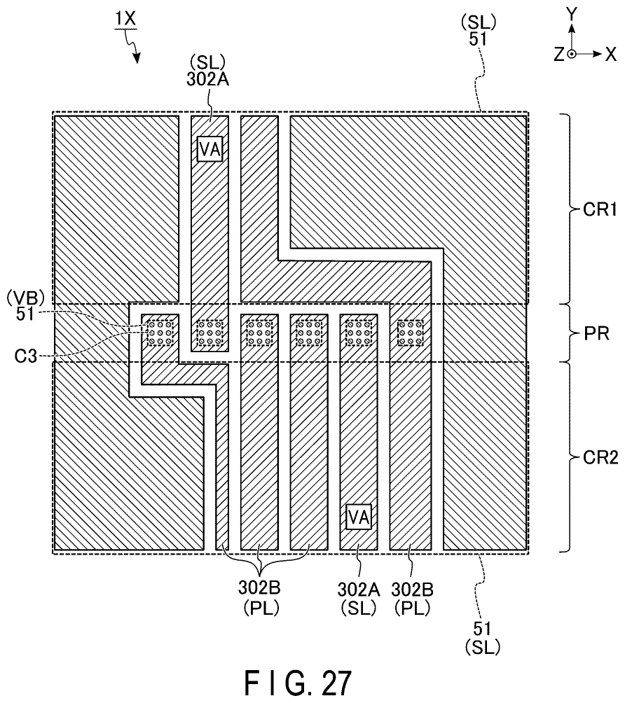

FIG. 27 is a plan view showing an example of a planar layout of a memory device 1X according to a comparative example to the first embodiment. FIG. 27 shows an example of arrangement of conductive layers 51, 302A, and 302B in two core areas CR1 and CR2 adjacent in the Y direction and a peripheral area PR therebetween. As shown in FIG. 27, a conductive layer 51 corresponding to a source line SL is placed in each core area CR. In the peripheral area PR, a plurality of conductive layers 51 are arranged apart from the conductive layer 51 of each core area CR. The conductive layer 51 of each core area CR is connected to the conductive layer 302A via a via VA. The conductive layer 302A is connected to the conductive layer 51 placed in the peripheral area PR via a via VB in the peripheral area PR. Similarly to the conductive layer 302A, the conductive layers 302B used as a power supply line PL can be connected to the conductive layer 51 in the peripheral area PR via a via VB. The conductive layer 302B may be placed to overlap with one of the core areas CR1 and CR2, or may be placed to overlap with both of the core areas CR1 and CR2.

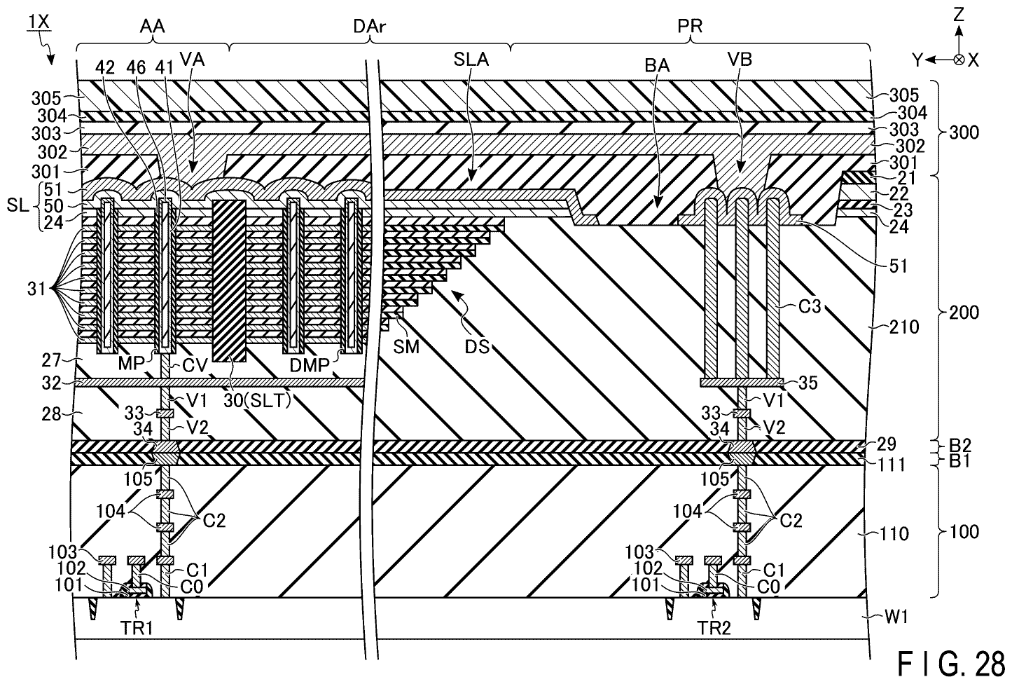

FIG. 28 is a cross-sectional view showing an example of a cross-sectional structure of the memory device 1X according to the comparative example to the first embodiment. As shown in FIG. 28, the source line SL in the comparative example to the first embodiment is connected to a contact C3 placed in the peripheral area PR via the conductive layer 51 in the active area AA, the conductive layer 302A, the vias VA and VB, and the conductive layer 51 in the peripheral area PR. That is, the connection path between the source line SL and the transistor TR2 passes through the conductive layer 302A. In the comparative example to the first embodiment, the source line area SLA and the insulating area BA are separately opened. Although illustration is omitted, the insulating area BA in the comparative example to the first embodiment can be provided in a portion that divides the semiconductor layer 22, the member 23, and the semiconductor layer 24 on a plane basis, a portion where the contact C3 is placed, and a portion where the via TV is placed. In this case, in the comparative example to the first embodiment, the semiconductor layer 22 may remain in most of the peripheral area PR.

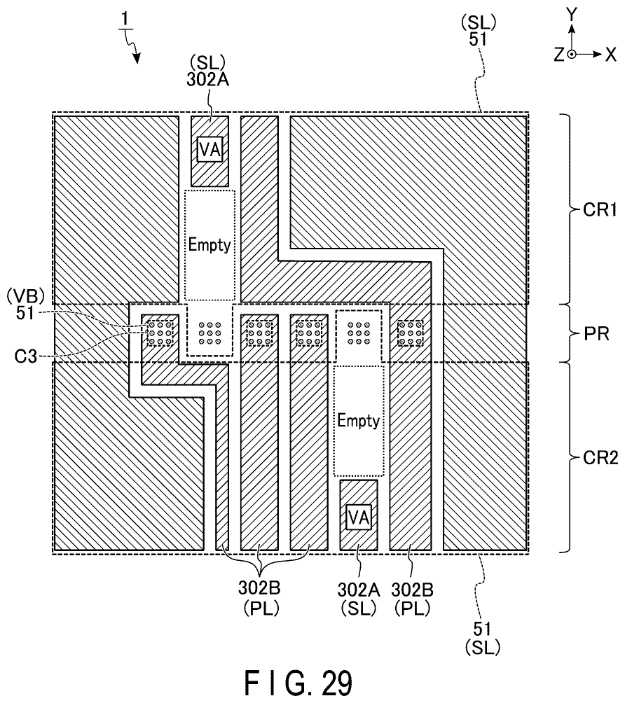

In contrast, the memory device 1 according to the first embodiment has a configuration in which the conductive layer 51 used as the source line SL is directly connected to the contact C3 without interposing the conductive layer 302A. FIG. 29 is a plan view showing an example of a planar layout of the memory device according to the first embodiment, and shows a similar area to FIG. 27. As shown in FIG. 29, in the first embodiment, the conductive layer 51 of each core area CR is connected to the contact C3 in the peripheral area PR without interposing the conductive layer 302A. Thereby, in the memory device 1 according to the first embodiment, of the conductive layers 302A in the comparative example to the first embodiment, portions used for connection between conductive layers 302A and contacts C3 in the peripheral area PR are omitted, and empty areas are formed.

Thereby, in the memory device 1 according to the first embodiment, the empty area generated by part of the conductive layer 302A being omitted can be used for other uses. That is, in the memory device 1 according to the first embodiment, design flexibility can be improved. Therefore, the memory device 1 according to the first embodiment can reduce the chip size with increase in design efficiency, and can suppress the manufacturing cost of the memory device 1.

In the memory device 1 according to the first embodiment, the semiconductor layer 22 in the contact area CA is remained. Thereby, in the step of removing the stacked film 42, an event where the oxide film in the columnar member HR is etched is avoided. As a result, in the memory device 1 according to the first embodiment, a risk that the distance between the source line SL and the select gate line SGS will be shortened and breakdown voltage failure will occur can be suppressed.

### <2> Second Embodiment

A memory device 1A according to a second embodiment has a configuration in which, in the memory device 1 according to the first embodiment, the shunt wiring line of the source line SL is omitted. Details of the memory device 1A according to the second embodiment will now be described focusing on differences from the first embodiment.

### <2-1> Configuration

A configuration of the memory device 1A according to the second embodiment will now be described.

### (1: Planar Layout of Conductive Layers 302)

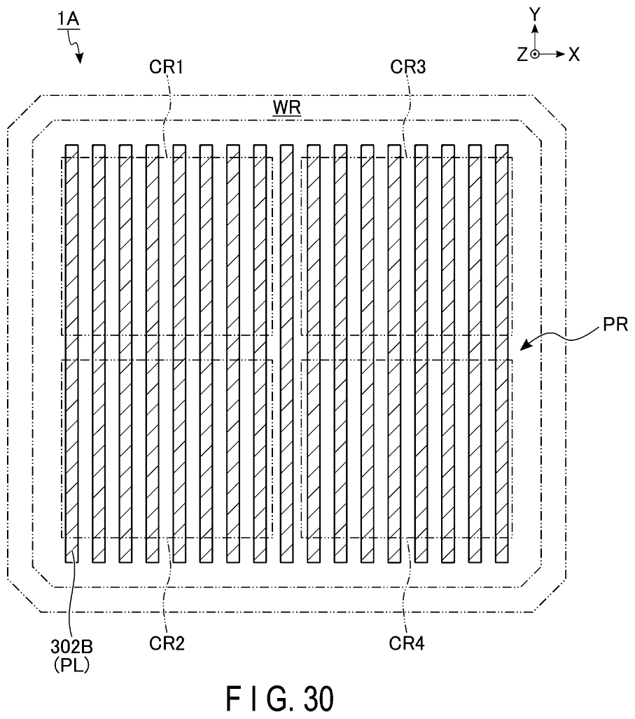

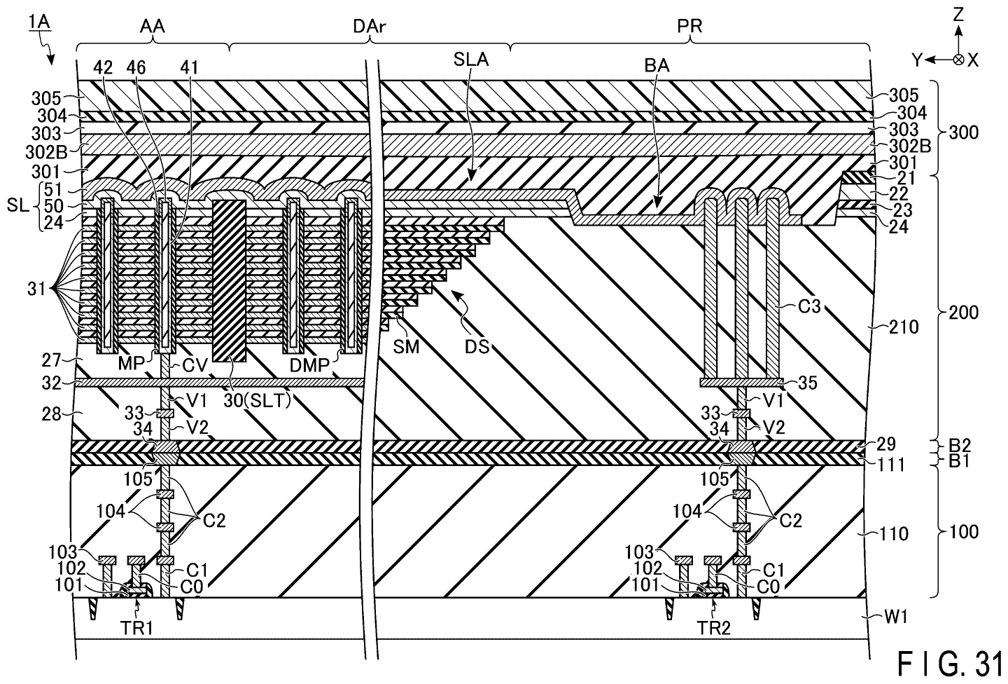

FIG. 30 is a plan view showing an example of a planar layout of conductive layers 302 in the memory device 1A according to the second embodiment. As shown in FIG. 30, the memory device 1A according to the second embodiment has a configuration in which, with respect to the memory device 1 according to the first embodiment, the conductive layer 302A used as a shunt wiring line of the source line SL is omitted. In the present example, conductive layers 302B are provided to extend from end portions of the core areas CR1 and CR3 on the outer peripheral side of the memory device 1A to end portions of the core areas CR2 and CR4 on the outer peripheral side of the memory device 1A. The arrangement of conductive layers 302B in the memory device 1A can be changed according to the layout of pad units PD (not illustrated) and the CMOS circuit, as appropriate.

### (2: Cross-Sectional Structure of the Memory Device 1A)

FIG. 31 is a cross-sectional view showing an example of a cross-sectional structure of the memory device 1A according to the second embodiment. As shown in FIG. 31, in the memory device 1A according to the second embodiment, the set of the conductive layer 302A and the via VA is omitted with respect to the memory device 1 according to the first embodiment described using FIG. 8. Then, a conductive layer 302B used as the power supply line PL is placed above the layer stack corresponding to the memory cell array 10. In the memory device 1A, the conductive layer 51 is preferably provided to have a lower resistance than in the first embodiment. For example, in a case where the conductive layer 51 of the second embodiment and the conductive layer 51 of the first embodiment have the same material composition, the conductive layer 51 of the second embodiment is provided to be thicker than the conductive layer 51 of the first embodiment. As the conductive layer 51 of the second embodiment, for example, a metal material containing aluminum (Al) as a main component is used. The configuration of the other parts of the memory device 1A according to the second embodiment is similar to that of the memory device 1 according to the first embodiment.

### <2-2> Advantageous Effects of the Second Embodiment

The memory device 1A according to the second embodiment can obtain a larger empty area associated with omission of the conductive layer 302A than the first embodiment. As a result, the memory device 1A according to the second embodiment can improve design flexibility, and can reduce the chip size. Therefore, the memory device 1A according to the second embodiment can suppress the manufacturing cost more than the first embodiment.

### <3> Third Embodiment

A memory device 1B according to a third embodiment has a configuration in which, in the memory device 1 according to the first embodiment, part of the conductive layer 51 and the via TV are arranged to overlap in the Z direction. Details of the memory device 1B according to the third embodiment will now be described focusing on differences from the first and second embodiments.

### <3-1> Configuration

A configuration of the memory device 1B according to the third embodiment will now be described.

### (1: Planar Layout of the Vicinity of the Pad Unit PD)

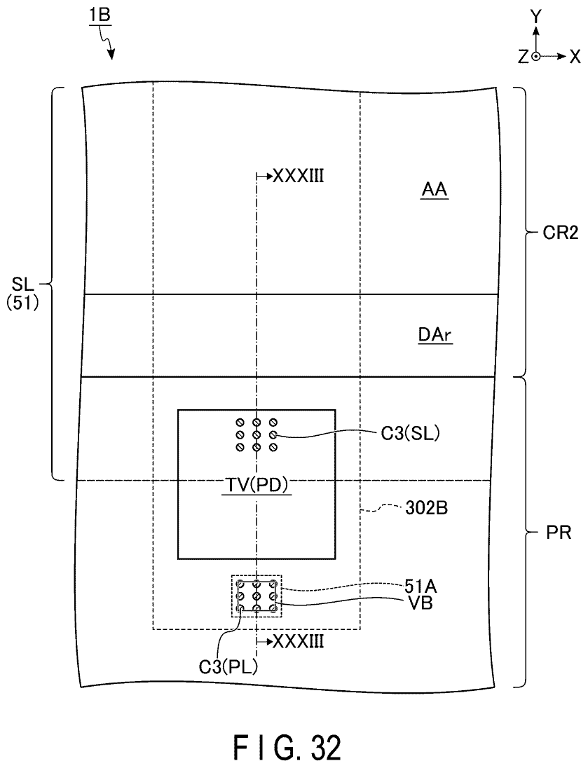

FIG. 32 is a plan view showing an example of a planar layout of the vicinity of the pad unit PD in the memory device 1B according to the third embodiment. FIG. 32 shows a pad unit PD used for connection to the input/output circuit 11, the logic controller 12, or the like in the memory device 1B, and part of each of the core area CR2 and the peripheral area PR in the vicinity thereof. As shown in FIG. 32, the memory device 1B according to the third embodiment is different from the memory device 1 according to the first embodiment in that the via TV overlaps with, in the Z direction, the conductive layer 51 used as part of the source line SL. Further, the via TV of the third embodiment overlaps with, in the Z direction, at least one contact C3 connected to the source line SL. In the present example, like in the second embodiment, the conductive layer 302A used as a shunt wiring line of the source line SL and the via VA may be omitted.

### (2: Cross-Sectional Structure of the Vicinity of the Pad Unit PD)

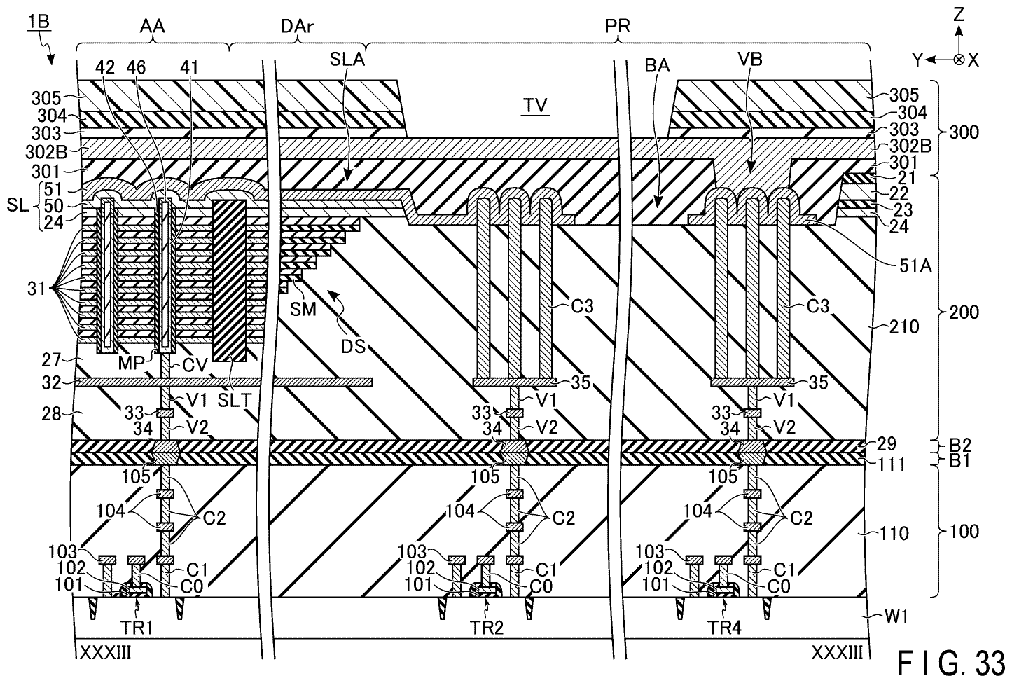

FIG. 33 is a cross-sectional view taken along line XXXIII-XXXIII of FIG. 32, showing an example of a cross-sectional structure of the vicinity of the pad unit PD in the memory device according to the third embodiment. As shown in FIG. 33, in the memory device 1B according to the third embodiment, a portion of the conductive layer 302B where the surface is exposed through the via TV has a portion overlapping with, in the Z direction, each of the conductive layer 51 used as the source line SL and the contact C3. Although the present example shows, as an example, a case where the conductive layer 302B has a portion extending in the active area AA, the configuration is not limited thereto. In the memory device 1B, it is sufficient that at least part of the conductive layer 51 used as the source line SL have a portion overlapping with the via TV in the Z direction. The configuration of the other parts of the memory device 1B according to the third embodiment is similar to that of the memory device 1 according to the first embodiment.

### <3-2> Advantageous Effects of the Third Embodiment

The memory device 1B according to the third embodiment can improve design flexibility for the via TV more than the first embodiment. As a result, the memory device 1B according to the third embodiment can reduce the chip size, and can suppress the manufacturing cost of the memory device 1B more than the first embodiment.

### <4> Fourth Embodiment

A memory device 1C according to a fourth embodiment has a configuration in which, in the memory device 1A according to the second embodiment, the semiconductor layer 46 of the memory pillar MP and a metal material used as part of the source line SL are directly connected to each other. Details of the memory device 1C according to the fourth embodiment will now be described focusing on differences from the first to third embodiments.

### <4-1> Configuration

A configuration of the memory device 1C according to the fourth embodiment will now be described.

### (1: Cross-Sectional Structure of the Memory Device 1C in the BL Direction)

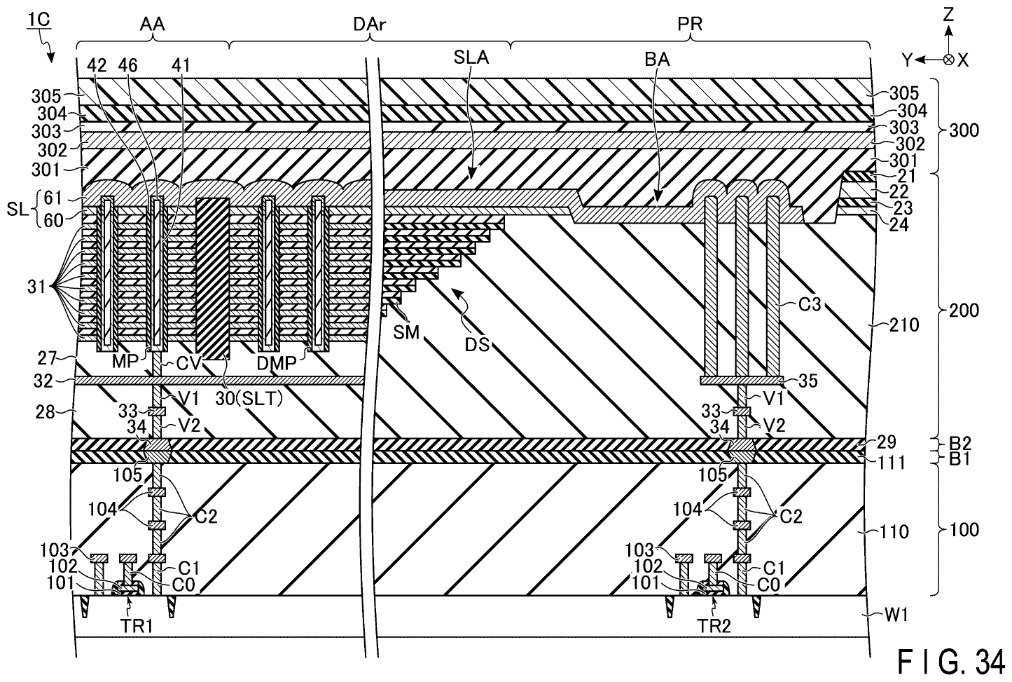

FIG. 34 is a cross-sectional view showing an example of a cross-sectional structure of the memory device 1C according to the fourth embodiment. As shown in FIG. 34, the memory device 1C has a configuration in which, with respect to the memory device 1 according to the first embodiment, the semiconductor layer 24 of the source line area SLA is replaced with a semiconductor layer 60, and the semiconductor layer 50 and the conductive layer 51 are replaced with a conductive layer 61.

The semiconductor layer 60 corresponds to the semiconductor layer 24 doped with an impurity. The conductive layer 61 contains a metal material. The conductive layer 61 contains, for example, any of titanium (Ti), titanium nitride (TiN), tungsten (W), and aluminum (Al). Similarly to the conductive layer 51 of the first embodiment, the conductive layer 61 has a portion provided to cover an upper portion of the semiconductor layer 46 of each memory pillar MP and a portion provided to cover an upper portion of the insulating member 30. The conductive layer 61 is in contact with the semiconductor layer 46 of each memory pillar MP, and is electrically connected to the semiconductor layer 46 of each memory pillar MP. That is, the semiconductor layer 46 of each memory pillar MP is electrically connected to the transistor TR2 via the conductive layer 61, at least one contact C3, the conductive layers 33 to 35 and 103 to 105, and the contacts V1, V2, C1, and C2.

### (2: Cross-Sectional Structure of the Memory Device 1C in the WL Direction)

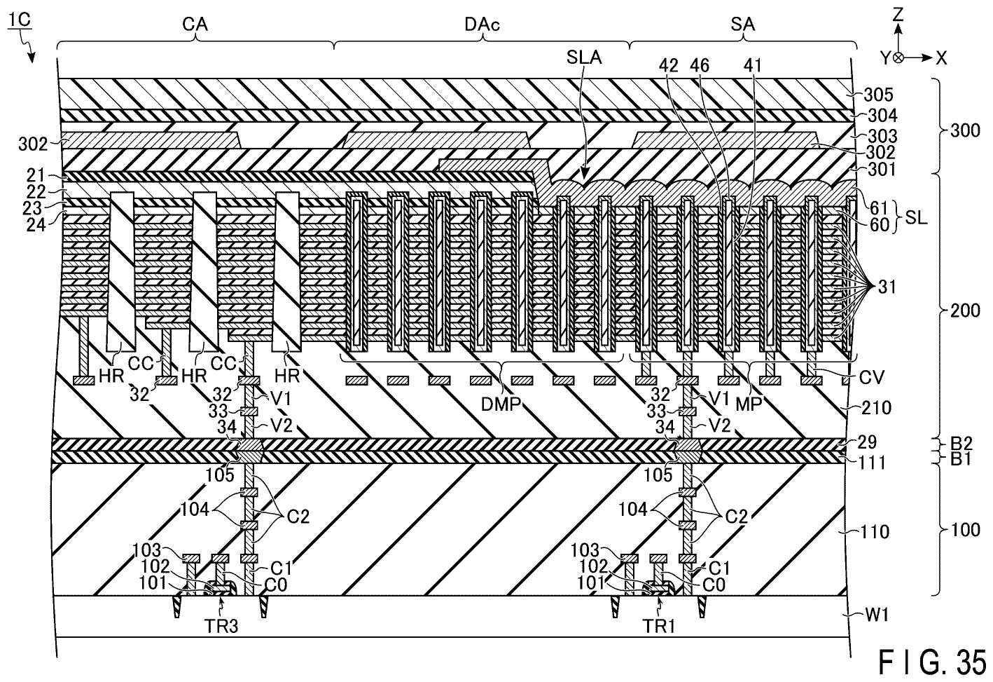

FIG. 35 is a cross-sectional view showing an example of a cross-sectional structure of the memory device 1C according to the fourth embodiment. FIG. 35 shows parts of the contact area CA, the dummy area DAc, and the storage area SA, and shows coordinate axes with the semiconductor substrate W1 as a reference. As shown in FIG. 35, the dummy area DAc of the fourth embodiment includes an end portion of the conductive layer 61. In the dummy area DAc, the end portion of the conductive layer 61 has a portion provided along the insulating layer 21. The conductive layer 61 has a portion provided to cover part of the insulating layer 21. In the portion provided to cover part of the insulating layer 21, the conductive layer 61 is apart from the dummy pillar DMP. The configuration of the other parts of the memory device 1C according to the fourth embodiment is similar to that of the memory device 1 according to the first embodiment.

### <4-2> Manufacturing Method

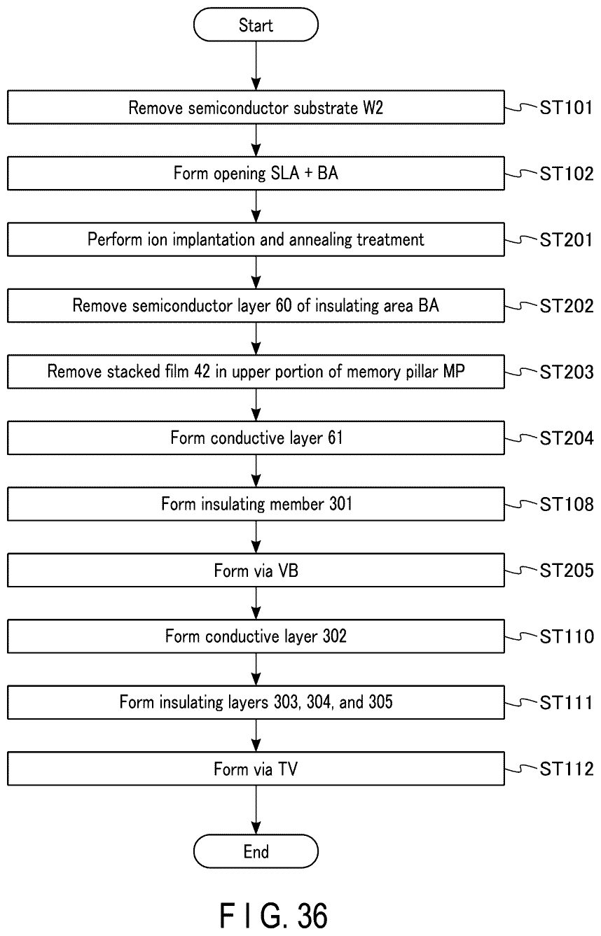

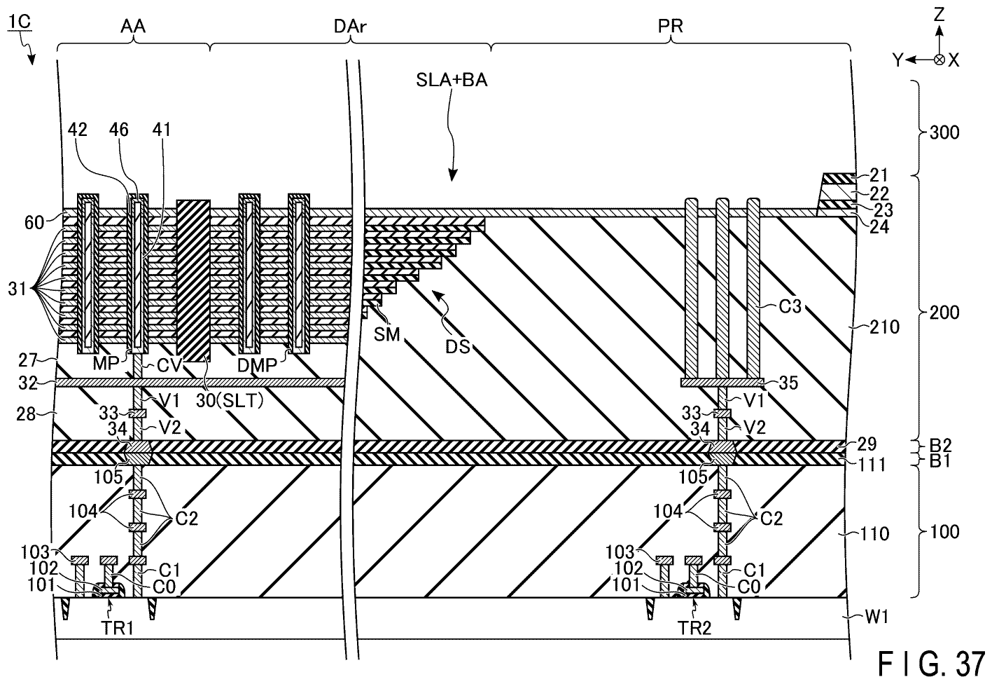

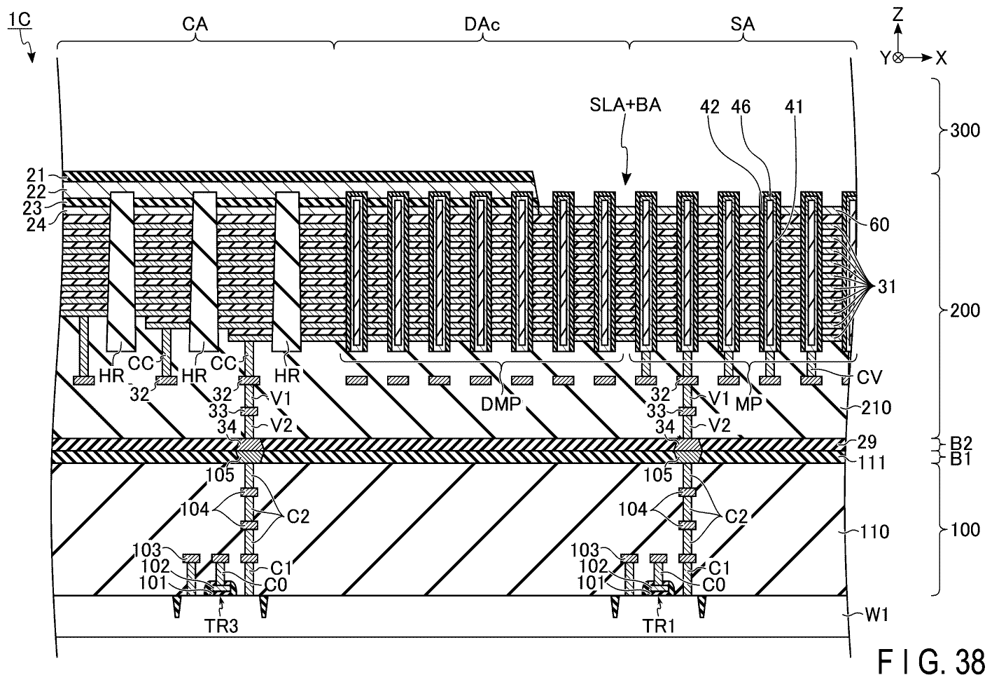

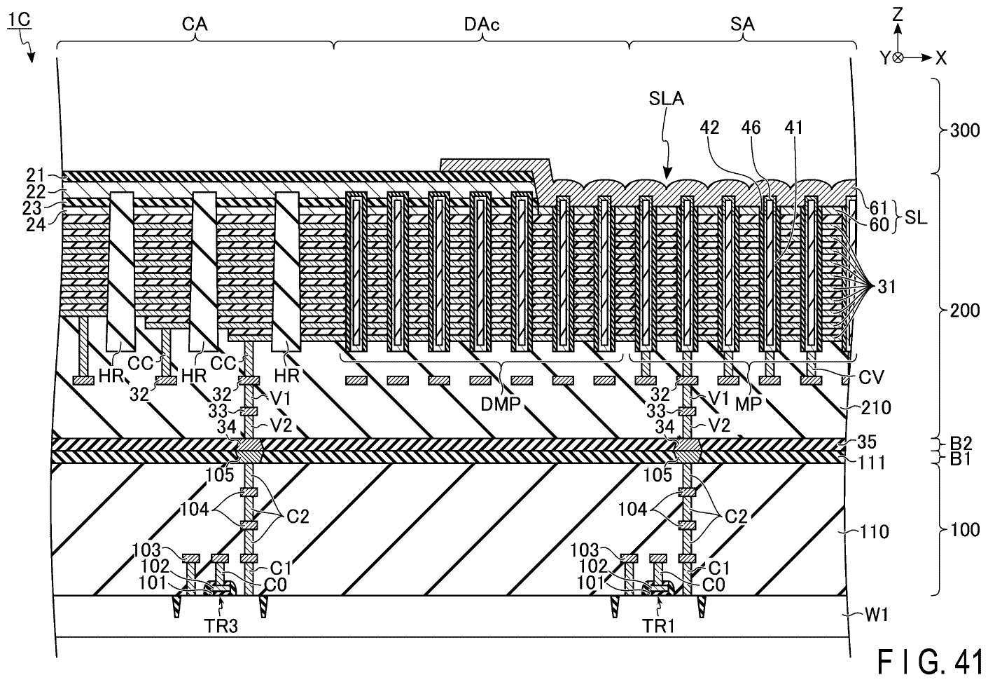

Next, as a method of manufacturing the memory device 1C according to the fourth embodiment, a method of forming the source line SL and the wiring layer 300 after bonding the semiconductor substrate W1 and the semiconductor substrate W2 is described with reference to FIG. 36 as appropriate. FIG. 36 is a flowchart showing an example of a method of manufacturing the memory device 1C according to the fourth embodiment. Each of FIGS. 37 to 43 is a cross-sectional view showing an example of a cross-sectional structure in the manufacturing process of the memory device 1C according to the fourth embodiment. Each of FIGS. 37, 39, 40, 42, and 43 corresponds to a cross section along the BL direction, and shows a similar area to FIG. 34. Each of FIGS. 38 and 41 corresponds to a cross section along the WL direction, and shows a similar area to FIG. 35.

First, like in the first embodiment, the semiconductor substrate W2 is removed from the semiconductor substrates W1 and W2 after bonding (step ST101), and an opening SLA+BA is formed (step ST102). At this point of time, the structure described using FIGS. 19 and 20 in the first embodiment is formed.

Next, ion implantation and annealing treatment are executed (step ST201). This step is performed on the opening SLA+BA. Specifically, first, an impurity is implanted into an upper portion of each memory pillar MP by ion implantation processing. After that, annealing treatment is executed, and thereby the implanted impurity is diffused to an upper portion of the semiconductor layer 41. In FIGS. 37 and 38, the semiconductor layer 41 thus doped with an impurity is shown as a semiconductor layer 46. In this step, also the semiconductor layer 24 that was exposed at the opening SLA+BA can be doped with an impurity. In FIGS. 37 and 38, the semiconductor layer 24 thus doped with an impurity is shown as a semiconductor layer 60. The impurity doped in the semiconductor layer 41 by this step is, for example, at least one of phosphorus (P) and arsenic (As).

Next, the semiconductor layer 60 of the insulating area BA is removed (step ST202). Thereby, in the insulating area BA, the surface of the insulating layer 210 and an upper portion of at least one contact C3 provided in the insulating area BA are exposed. A portion of the opening SLA+BA not overlapping with the insulating area BA corresponds to the source line area SLA.

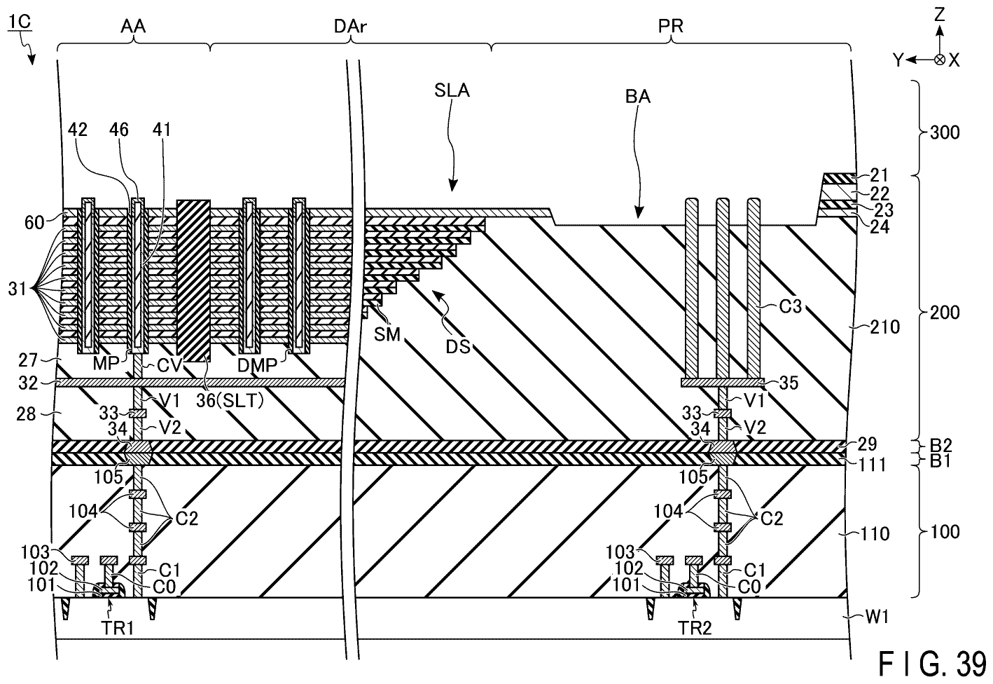

Next, as shown in FIG. 39, the stacked film 42 in an upper portion of the memory pillar MP is removed (step ST203). Specifically, for example, in the source line area SLA, the stacked film 42 provided above the semiconductor layer 60 is selectively removed by wet etching processing. Thereby, in the source line area SLA, the semiconductor layer 46 in an upper portion of each memory pillar MP and the semiconductor layer 46 in an upper portion of each dummy pillar DMP are exposed.

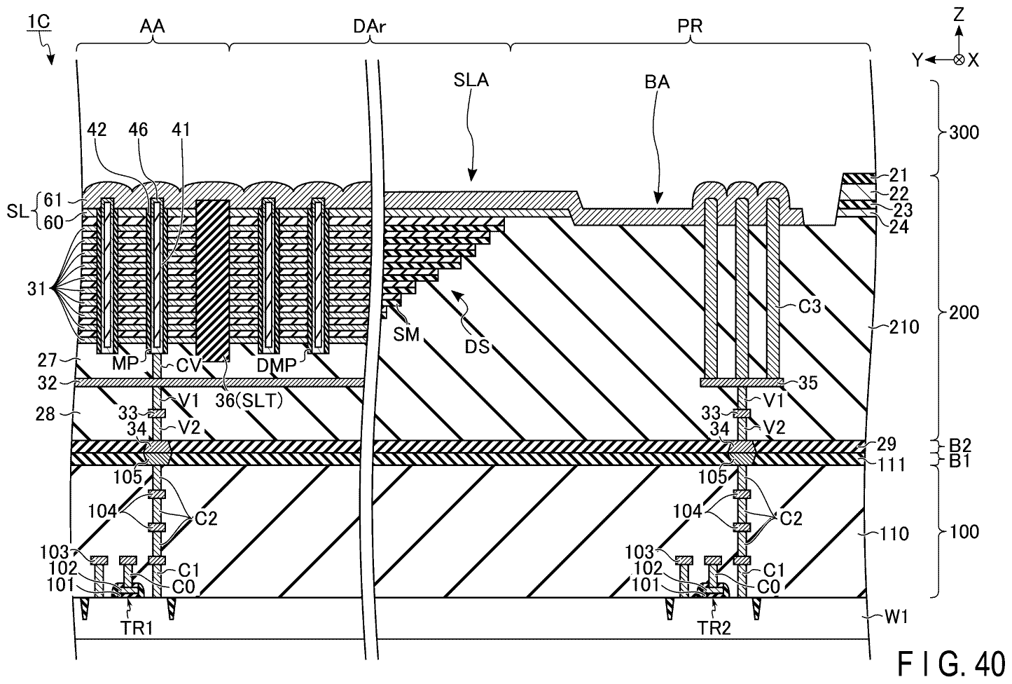

Next, as shown in FIGS. 40 and 41, a conductive layer 61 is formed (step ST204). Specifically, first, a conductive layer 61 is formed on the surfaces of the semiconductor layer 60, the insulating layer 210, and the insulating layer 21, etc. by CVD processing or the like. The conductive layer 61 has a portion covering an upper portion of the semiconductor layer 46 of each memory pillar MP, a portion covering an upper portion of the semiconductor layer 46 of each dummy pillar DMP, and a portion covering an upper portion of each contact C3. After that, a mask is formed, and the conductive layer 61 is processed by anisotropic etching processing. The conductive layer 61 processed in this step is provided to, for example, electrically connect the semiconductor layer 46 of each memory pillar MP and each contact C3. Thereby, a similar structure to the conductive layer 61 shown in FIGS. 34 and 35 is formed. As shown in FIG. 40, an end portion of the conductive layer 61 in the BL direction is included in the insulating area BA. As shown in FIG. 41, an end portion of the conductive layer 61 in the WL direction is included in the dummy area DAc.

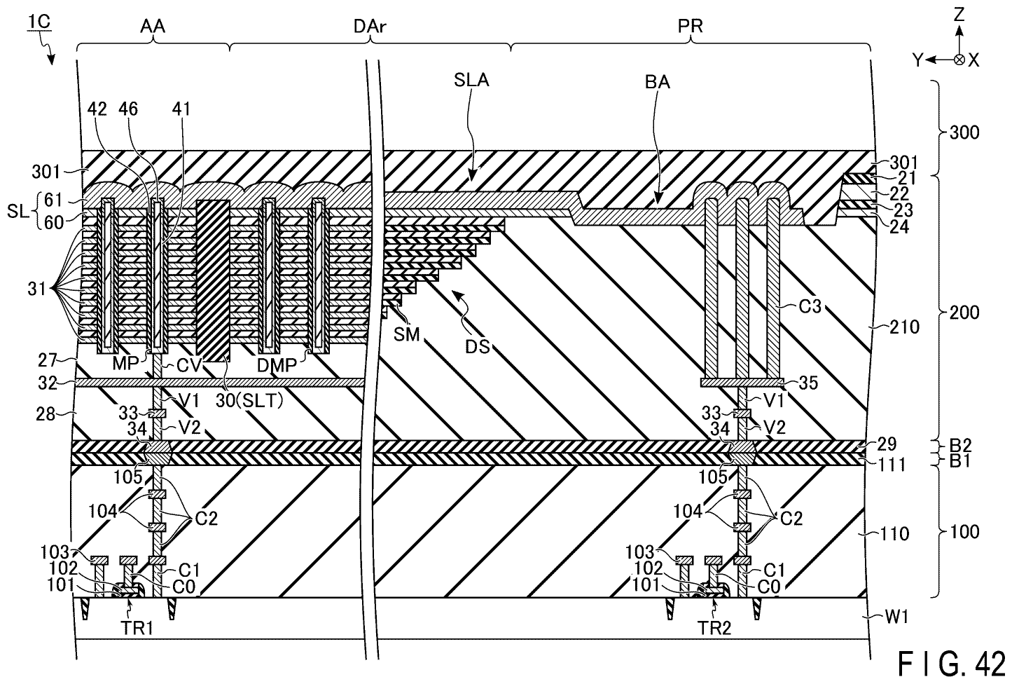

Next, as shown in FIG. 42, an insulating member 301 is formed in the insulating area BA (step ST108). By the processing of step ST108, an insulating member 301 is embedded in the opening SLA+BA (the source line area SLA and the insulating area BA). After that, the surface of the insulating member 301 is planarized by CMP processing or the like.

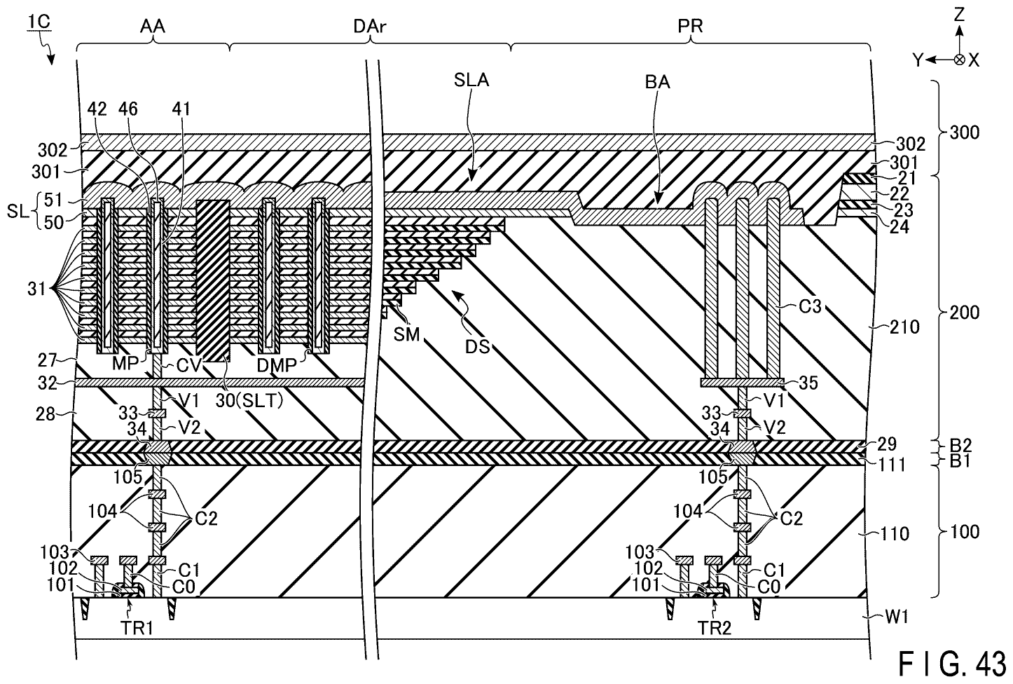

Next, a via VB is formed (step ST205). The via VB in the fourth embodiment is, for example, provided in the vicinity of the pad unit PD, and is thus not shown in FIG. 34 or 43. Then, as shown in FIG. 43, a conductive layer 302 is formed like in the first embodiment (step ST110). By the conductive layer 302 being formed, the via VB is filled. After that, insulating layers 303, 304, and 305 are formed (step ST111), and a via TV is formed (step ST112). Thereby, the structure of the memory device 1C shown in FIGS. 34 and 35 is completed.

### <4-3> Advantageous Effects of the Fourth Embodiment

The memory device 1C according to the fourth embodiment has a configuration in which the semiconductor layer 46 obtained by an upper portion of each memory pillar MP being doped with an impurity and the conductive layer 61 used as the source line SL are directly connected to each other. Thereby, the memory device 1C according to the fourth embodiment can suppress the manufacturing cost of the memory device 1C. Further, in the memory device 1C according to the fourth embodiment, like in the second embodiment, the shunt wiring line (the conductive layer 302A) of the source line SL can be omitted, and design flexibility can be improved. Therefore, the memory device 1C according to the fourth embodiment can reduce the chip size more than the first embodiment.

### <5> Fifth Embodiment

A memory device 1D according to a fifth embodiment relates to another way of use of the conductive layer 51 described in the memory device 1 according to the first embodiment. Details of the memory device 1D according to the fifth embodiment will now be described focusing on differences from the first to fourth embodiments.

### <5-1> Configuration

A configuration of the memory device 1D according to the fifth embodiment will now be described.

### (1: Cross-Sectional Structure of the Memory Device 1D)

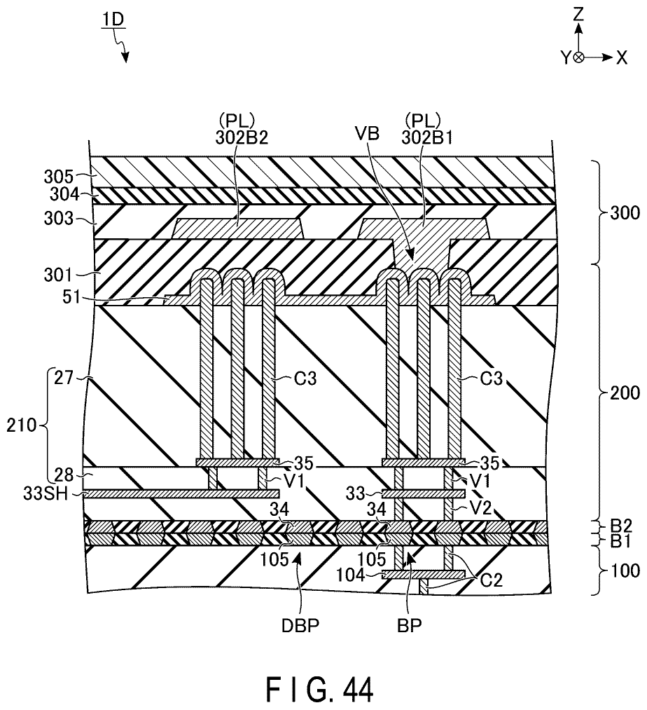

FIG. 44 is a cross-sectional view showing an example of a cross-sectional structure of the memory device 1D according to the fifth embodiment. FIG. 44 extracts and shows part of the peripheral area PR of the memory device 1D according to the fifth embodiment, and shows coordinate axes with the semiconductor substrate W1 (not illustrated) as a reference. As shown in FIG. 44, two conductive layers 302B1 and 302B2 are arranged in the X direction. The conductive layers 302B1 and 302B2 are used as power supply lines PL of different potentials. For example, the ground voltage VSS is applied to the conductive layer 302B1. The conductive layer 302B1 has a portion along the via VB, and is electrically connected to the conductive layer 51 below. The conductive layer 302B2 and the conductive layer 51 are apart from each other with the insulating member 301 therebetween. The conductive layer 51 shown in the drawing has a portion provided to extend in the X direction, and overlaps with each of the conductive layers 302B1 and 302B2 in the Z direction.

In the present example, the memory layer 200 includes a conductive layer 33SH. The conductive layer 33SH is a wiring line provided in the same layer as the conductive layer 33. The conductive layer 33SH is used as a shield wiring line. The conductive layer 33SH can, for example, suppress propagation of noise generated in the CMOS circuit on the semiconductor substrate W1 to the bit line BL.

The conductive layer 51 shown in the drawing is electrically connected to a circuit in the CMOS layer 100 via at least one contact C3 provided to overlap with the conductive layer 302B1 in the Z direction, conductive layers 33 to 35 and 105, and contacts V1 and V2. Further, the conductive layer 51 shown in the drawing is electrically connected to the conductive layer 33SH via at least one contact C3 provided to overlap with the conductive layer 302B2 in the Z direction, a conductive layer 35, and a contact V1.

Further, in FIG. 44, a plurality of bonding pads BP and DBP arranged in the X direction are shown. The bonding pads BP and DBP include bonding pads BP used to connect circuits of the memory layer 200 and the CMOS layer 100, and bonding pads DBP corresponding to a dummy pattern. In the memory device 1D according to the fifth embodiment, the bonding pad DBP and the conductive layer 33SH are apart from each other with an insulating layer 28 therebetween.

### (2: Planar Layout of Conductive Layers 33 and 33SH)

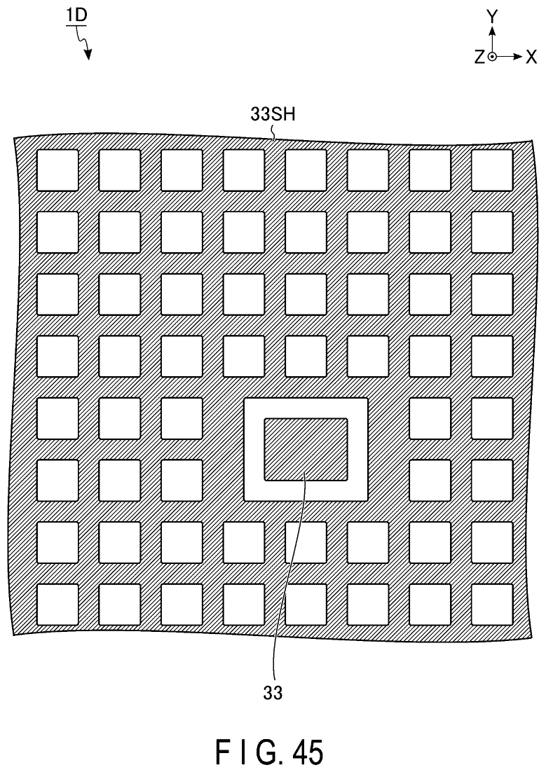

FIG. 45 is a plan view showing an example of a planar layout of conductive layers in the memory device 1D according to the fifth embodiment. As shown in FIG. 45, the conductive layer 33SH has a portion provided in a mesh shape. The periphery of the conductive layer 33 is surrounded by the conductive layer 33SH. The conductive layer 33SH and the conductive layer 33 are apart from each other in a planar view. The conductive layer 33SH may surround a plurality of conductive layers 33. The conductive layer 33SH is placed mainly in the peripheral area PR. The conductive layer 33SH may have other shapes as long as it functions as a shield wiring line. For example, the conductive layer 33SH may be formed in a plate shape.

### <5-2> Manufacturing Method

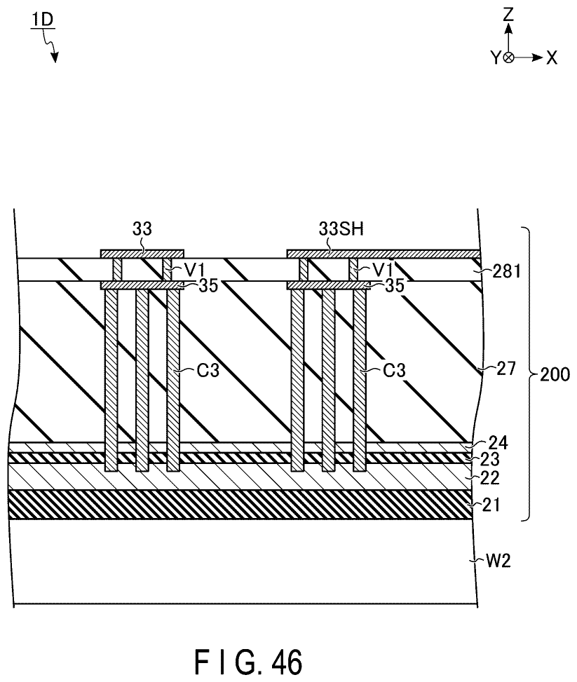

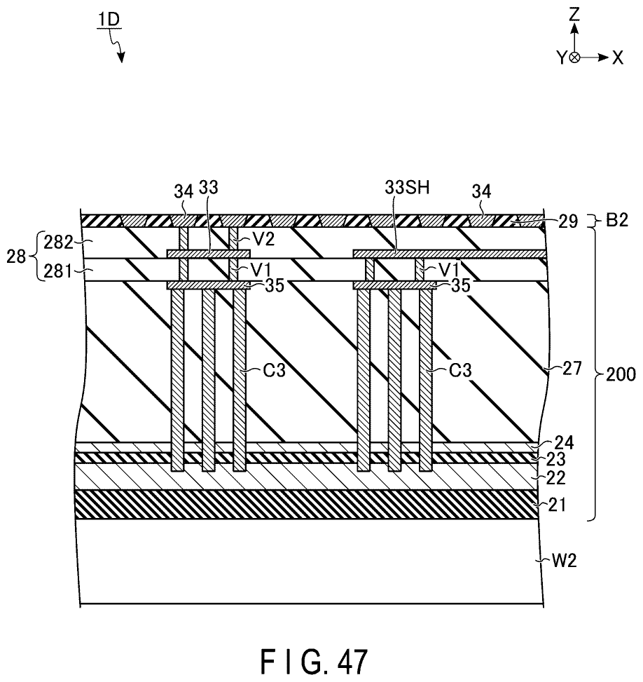

Next, as a method of manufacturing the memory device 1D according to the fifth embodiment, the steps from the formation of the conductive layers 33 and 33SH to the formation of the conductive layer 302 are described with reference to FIG. 17 as appropriate. Some of the steps for manufacturing the memory device 1D according to the fifth embodiment can be performed by a flow similar to the flowchart described using FIG. 17 in the first embodiment. Each of FIGS. 46 to 51 is a cross-sectional view showing an example of a cross-sectional structure in the manufacturing process of the memory device 1D according to the fifth embodiment. Each of FIGS. 46 to 51 shows a similar area to FIG. 44; however, unlike FIG. 44, each of FIGS. 46 and 47 shows coordinate axes with the semiconductor substrate W2 before bonding as a reference.

First, as shown in FIG. 46, an insulating layer 281 is formed on an insulating layer 27, and conductive layers 33 and 33SH are formed on the insulating layer 281 in such a way as to be connected to conductive layers 35 via contacts V1 in the insulating layer 281. Then, an insulating layer 282 is provided to cover the conductive layers 33 and 33SH and contacts V2 formed on the conductive layer 33. The set of insulating layers 281 and 282 corresponds to the insulating layer 28 shown in FIG. 44. Above the semiconductor substrate W2 before bonding, the conductive layers 33 and 33SH and the contacts V1 and V2 are formed simultaneously with the structure in the insulating layer 28 on the bit line BL (illustration omitted). Then, an insulating layer 29 is formed on the insulating layer 282, and conductive layers 34 are formed by, for example, a damascene method. Thereby, the structure shown in FIG. 47 is formed on the semiconductor substrate W2.

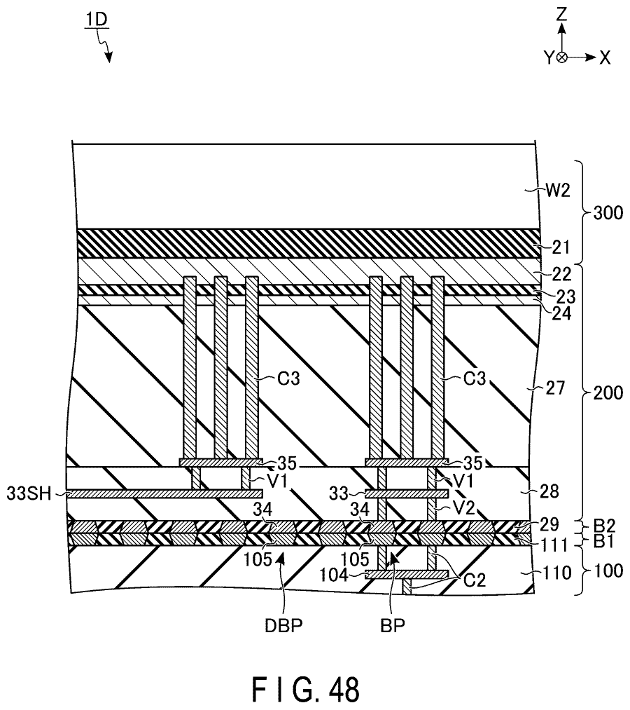

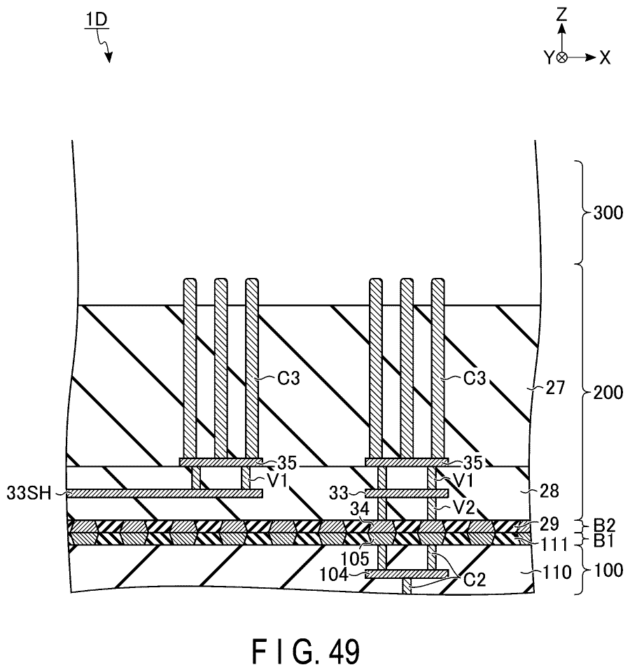

Next, as shown in FIG. 48, the semiconductor substrate W1 and the semiconductor substrate W2 are bonded together. Specifically, the bonding layer B1 formed using the semiconductor substrate W1 and the bonding layer B2 formed using the semiconductor substrate W2 are bonded together. Thereby, the conductive layers 34 and 105 arranged to face each other are bonded together. During bonding processing, the conductive layer 33SH and the bonding pad DBP corresponding to a dummy pattern are electrically insulated from each other. After that, for example, the processing of steps ST101 to ST106 described in the first embodiment is executed. Thereby, as shown in FIG. 49, an upper portion of each contact C3 is exposed. The upper portion of each contact C3 protrudes upward from the insulating layer 27.

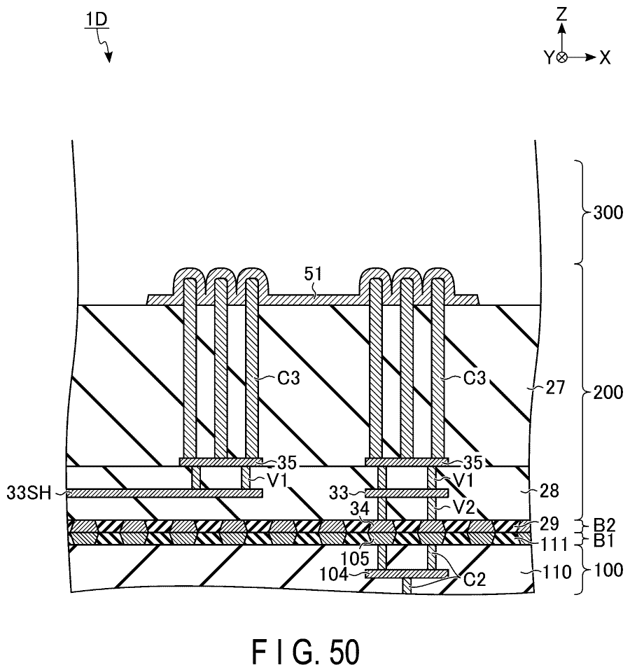

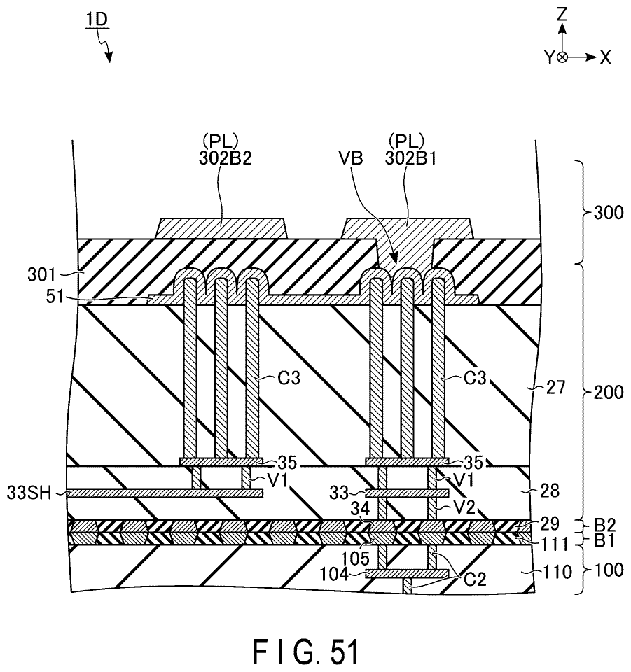

Next, the processing of step ST107 described in the first embodiment is executed, and thereby a conductive layer 51 is formed as shown in FIG. 50. The conductive layer 51 shown in the drawing connects the contact C3 provided above the conductive layer 33SH and the contact C3 provided above the conductive layer 33. After that, for example, the processing of steps ST108 to ST110 described in the first embodiment is executed, and thereby an insulating member 301 and conductive layers 302B1 and 302B2 are formed as shown in FIG. 51. The method of manufacturing the other parts of the memory device 1D according to the fifth embodiment is, for example, similar to that of the first embodiment.

### <5-3> Advantageous Effects of the Fifth Embodiment

In the memory device 1D according to the fifth embodiment described hereinabove, the yield can be improved, and the manufacturing cost of the memory device 1D can be suppressed. Advantageous effects of the memory device 1D according to the fifth embodiment will now be described using a comparative example.

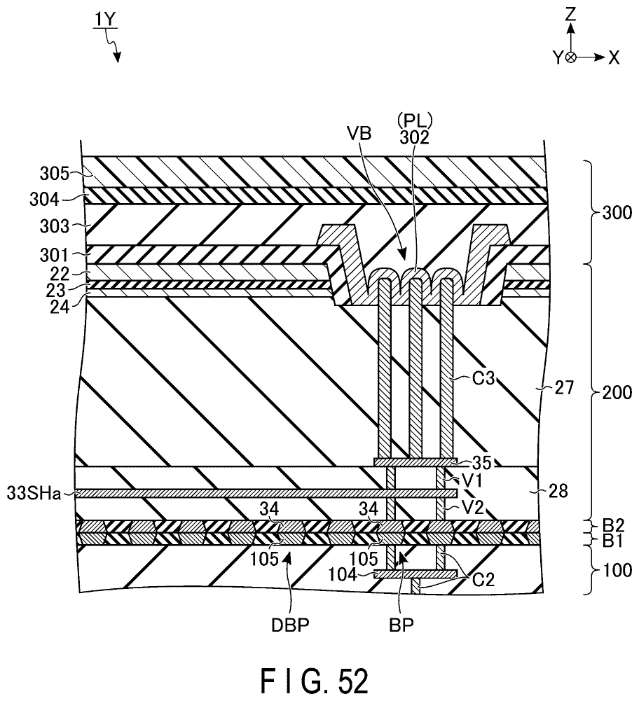

FIG. 52 is a cross-sectional view showing an example of a cross-sectional structure of a memory device 1Y according to a comparative example to the fifth embodiment. As shown in FIG. 52, in the comparative example to the fifth embodiment, a conductive layer 33SHa used as a shield wiring line is electrically connected to a contact C3 immediately below a via VB. In the comparative example to the fifth embodiment, in order to use the conductive layer 33SHa as a shield wiring line, the conductive layer 33SHa is connected to a conductive layer 302 used as a power supply line PL to which the ground voltage VSS is applied. Further, the conductive layer 33SHa is connected to bonding pads BP via contacts V2.

Then, in the manufacturing process of the memory device 1Y, bonding pads BP are connected to a conductive layer 33SHa in a floating state. In a case where bonding pads BP are thus connected to a long-distance wiring line in a floating state, Cu corrosion may occur during CMP and bonding pretreatment, and open failure may occur. Thus, there is a certain restriction to the wiring length of the conductive layer 33SHa. Further, the contact C3 is placed immediately below the conductive layer 302 at the same node. Thus, there is a certain restriction to the arrangement of contacts C3.

In contrast, in the memory device 1D according to the fifth embodiment, the conductive layer 33SH, which is a long-distance wiring line, and the conductive layer 302B1 are connected to each other by using the conductive layer 51 described in the first embodiment. In the memory device 1D according to the fifth embodiment, the conductive layer 33SH is connected to the conductive layer 302B1 and the contact C3 immediately below it in a back surface wiring processing after bonding processing; thus, even if the conductive layer 33SH is a long-distance wiring line, the occurrence of corrosion at the time of connection to the bonding pad BP can be suppressed. Therefore, the memory device 1D according to the fifth embodiment can suppress the occurrence of defects in the bonding pad BP, and can improve the yield.

Further, a contact C3 to be connected to the conductive layer 302B1 can be placed immediately below the conductive layer 302B2 of a different potential. As a result, the memory device 1D according to the fifth embodiment can improve design flexibility, and can reduce the chip size. Therefore, the memory device 1D according to the fifth embodiment can suppress the manufacturing cost.

### <6> Sixth Embodiment

In a memory device 1E according to a sixth embodiment, each core area CR has two storage areas SA1 and SA2 arranged to sandwich a contact area CA. Then, the semiconductor layer 50 and the conductive layer 51 are continuously provided between the storage areas SA1 and SA2. Details of the memory device 1E according to the sixth embodiment will now be described focusing on differences from the first to fifth embodiments.

### <6-1> Configuration

A configuration of the memory device 1E according to the sixth embodiment will now be described.

### (1: Planar Layout of the Core Area CR)

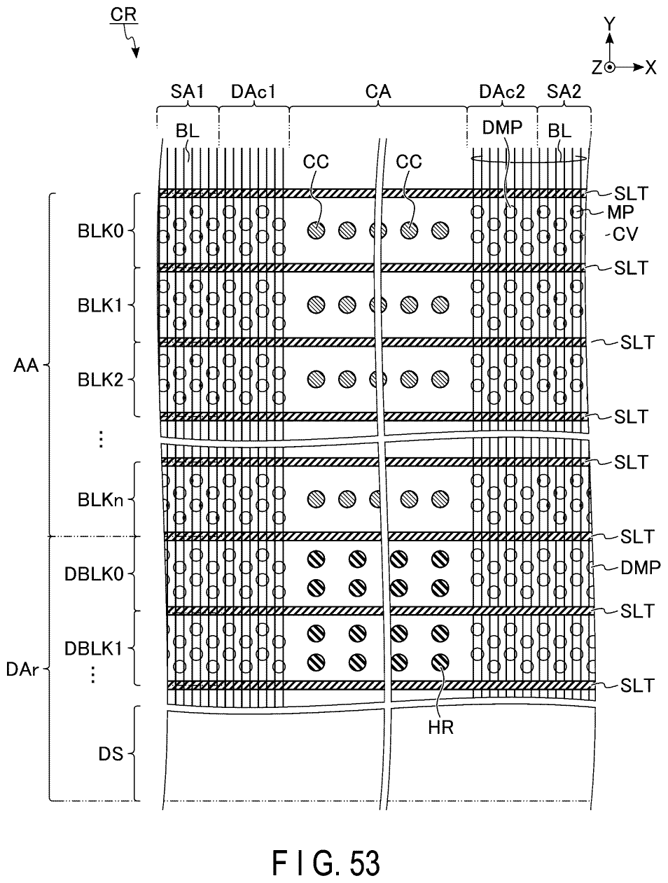

FIG. 53 is a plan view showing an example of a planar layout in a core area CR of a memory cell array 10 included in the memory device 1E according to the sixth embodiment. As shown in FIG. 53, the core area CR in the sixth embodiment includes, for example, storage areas SA1 and SA2, dummy areas DAc1 and DAc2, and a contact area CA arranged in the X direction, and an active area AA and a dummy area DAr arranged in the Y direction.

The planar layout of each of the storage areas SA1 and SA2 is, for example, similar to that of the storage area SA in the first embodiment. The planar layout of each of the dummy areas DAc1 and DAc2 is, for example, similar to that of the dummy area DAc in the first embodiment. The planar layout of the contact area CA in the sixth embodiment is, for example, similar to that of the contact area CA in the first embodiment. The contact area CA in the sixth embodiment is placed between the storage areas SA1 and SA2 in the X direction. The dummy area DAc1 is placed between the storage area SA1 and the contact area CA in the X direction. The dummy area DAc2 is placed between the storage area SA2 and the contact area CA in the X direction.

Each slit SLT in the sixth embodiment has a portion provided to cross the storage areas SA1 and SA2, the dummy areas DAc1 and DAc2, and the contact area CA along the X direction. The word lines WL provided in the same layer in the same blocks BLK are electrically connected to each other between the storage areas SA1 and SA2 via the contact area CA. The select gate lines SGD provided in the same layer in the same blocks BLK and associated with the same string units can be electrically connected to each other between the storage areas SA1 and SA2 via, for example, a wiring layer, etc. provided to overlap with the stacked wiring lines included in the memory cell array 10. The select gate lines SGS provided in the same layer in the same blocks BLK are electrically connected to each other between the storage areas SA1 and SA2 via the contact area CA.

An area where the dummy block DBLK and the contact area CA overlap includes a plurality of columnar members HR. The columnar members HR are, for example, arranged in a lattice configuration. Although illustration is omitted, a plurality of columnar members HR are arranged also in an area where each block BLK and the contact area CA overlap. Note that also in the memory device 1 according to the first embodiment, a plurality of columnar members HR may be arranged in an area where the dummy block DBLK and the contact area CA overlap.

### (2: Cross-Sectional Structure of the Memory Device 1E)

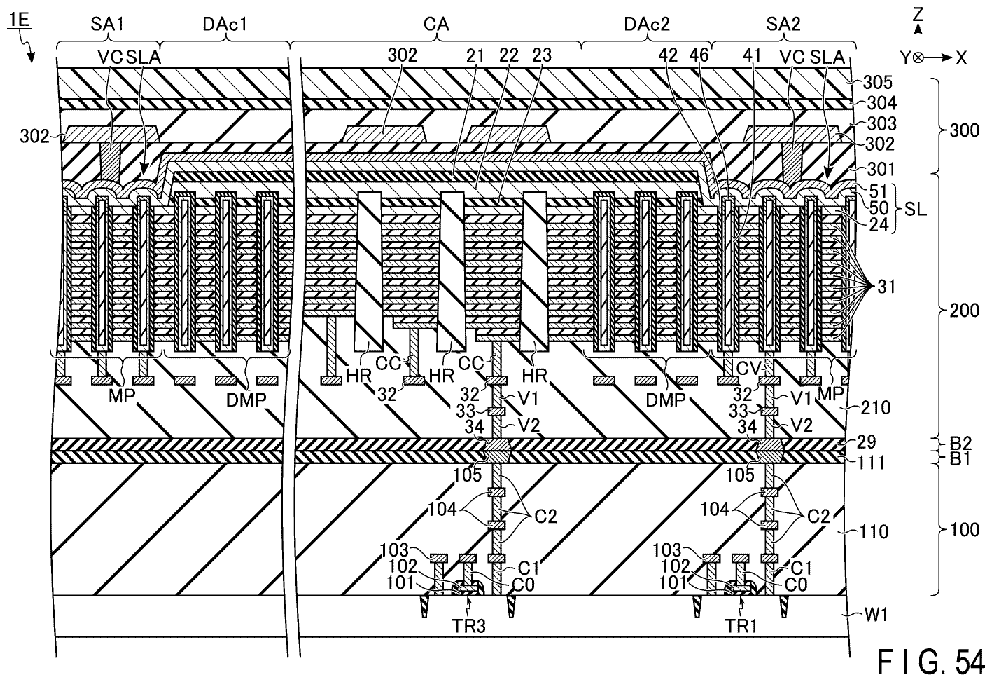

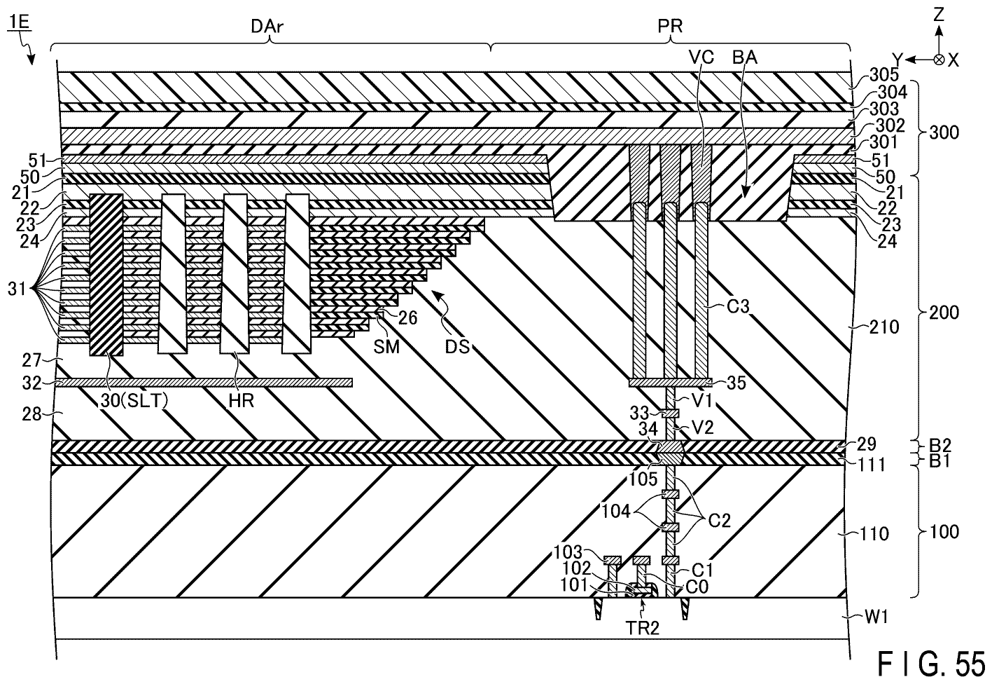

FIGS. 54 and 55 are cross-sectional views showing examples of cross-sectional structures of the memory device 1E according to the sixth embodiment. FIG. 54 shows an area including the storage areas SA1 and SA2 and the contact area CA and extending along the X direction (the WL direction). FIG. 55 shows an area including the dummy area DAr and the peripheral area PR and extending along the Y direction (the BL direction) in the contact area CA.

The structure in each of the storage areas SA1 and SA2 of the sixth embodiment is different from that of the storage area SA described in the first embodiment in a connection portion between the conductive layer 302 and the source line SL. Specifically, as shown in FIG. 54, in each storage area SA, a via contact VC is provided on the conductive layer 51. The via contact VC penetrates the insulating member 301. On each via contact VC, an associated conductive layer 302 is provided. Thereby, the conductive layer 302 and the conductive layer 51 are electrically connected to each other via the via contact VC.

Further, in the sixth embodiment, in the contact area CA, the semiconductor layer 50 and the conductive layer 51 are provided between the insulating layer 21 and the insulating member 301. Specifically, in the contact area CA, the semiconductor layer 50, the conductive layer 51, and the insulating member 301 are sequentially stacked on the insulating layer 21. Then, the semiconductor layer 50 in the storage area SA1 and the semiconductor layer 50 in the storage area SA2 are continuously provided via the semiconductor layer 50 on the insulating layer 21 in the contact area CA. Similarly, the conductive layer 51 in the storage area SA1 and the conductive layer 51 in the storage area SA2 are continuously provided via the conductive layer 51 above the insulating layer 21 in the contact area CA. Portions of the semiconductor layer 50 and the conductive layer 51 provided along an end portion of the source line area SLA (the side surfaces of the insulating layer 21, the semiconductor layer 22, and the member 23) are included in, for example, the dummy area DAc1 or DAc2.

The structure in each of the dummy area DAr and the peripheral area PR of the sixth embodiment is different from that of the dummy area DAr and the peripheral area PR described in the first embodiment in the stacked structure on the semiconductor layer 24 in the contact area CA and the structure of the insulating area BA. Specifically, as shown in FIG. 55, the dummy area DAr of the sixth embodiment has, in an area overlapping with the contact area CA and the dummy areas DAc1 and DAc2, a stacked structure of the semiconductor layer 24, the member 23, the semiconductor layer 22, the insulating layer 21, the semiconductor layer 50, the conductive layer 51, and the insulating member 301. In the insulating area BA of the sixth embodiment, at least one via contact VC is provided. The via contact VC is provided to penetrate the insulating member 301 in the insulating area BA, and electrically connects the associated contact C3 and the conductive layer 302. The configuration of the other parts of the memory device 1E according to the sixth embodiment is similar to that of the first embodiment.

### <6-2> Manufacturing Method

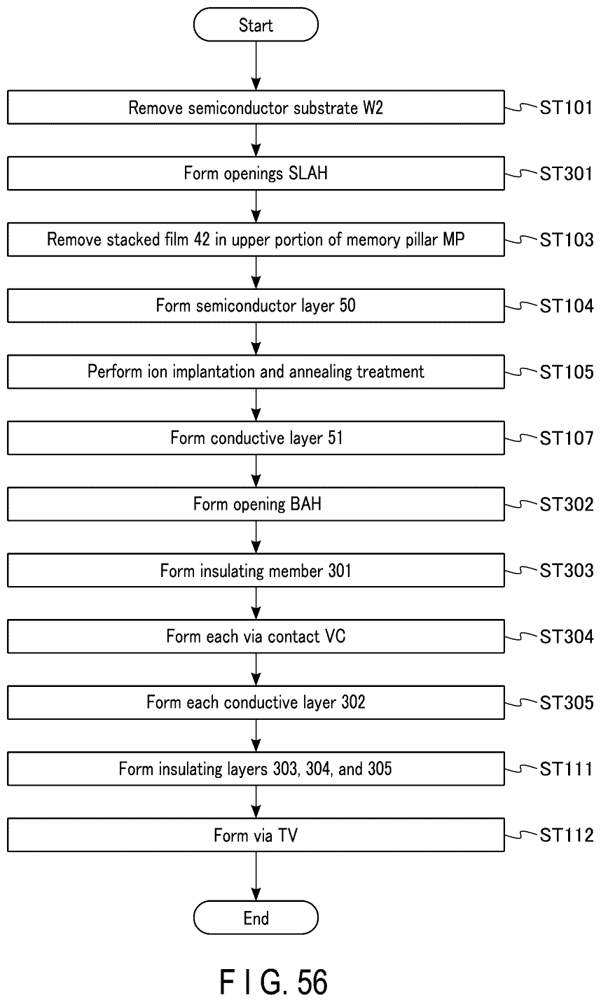

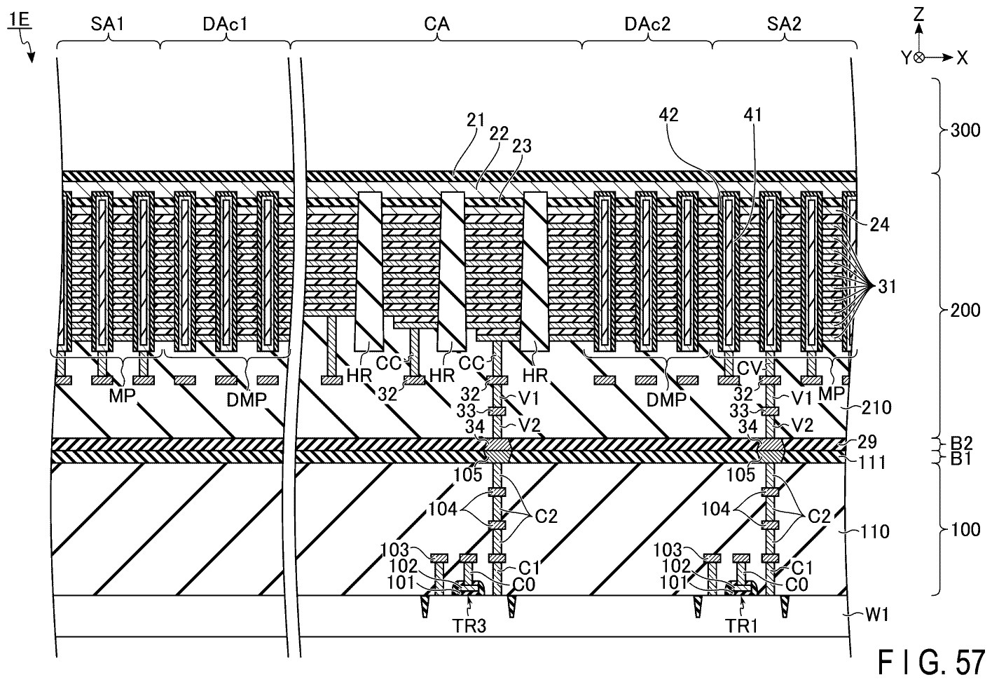

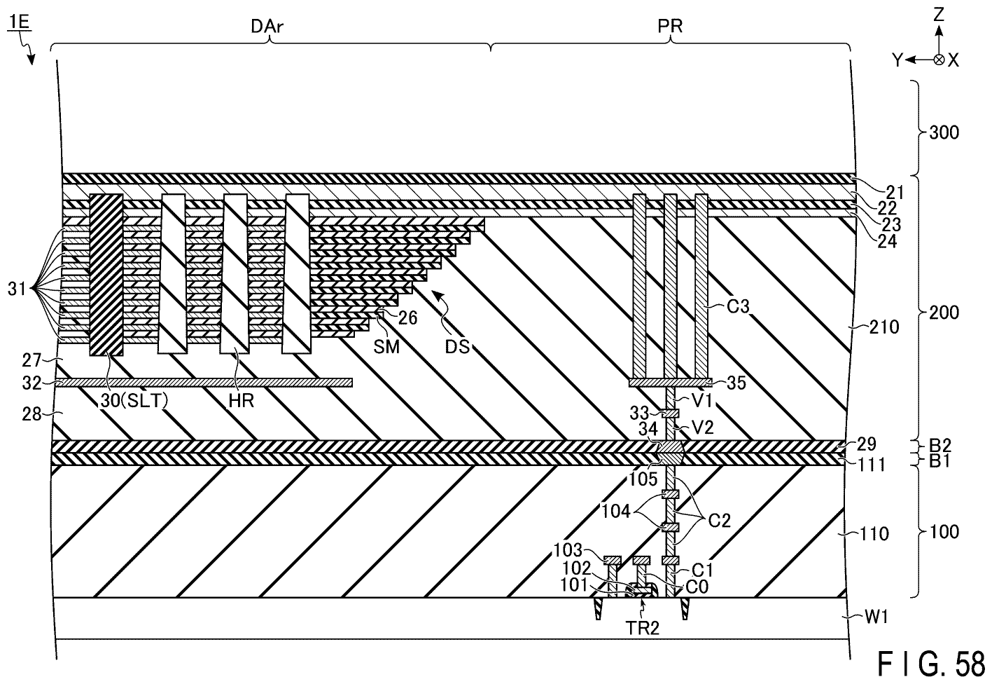

Next, as a method of manufacturing the memory device 1E according to the sixth embodiment, a method of forming the source line SL and the wiring layer 300 after bonding the semiconductor substrate W1 and the semiconductor substrate W2 is described with reference to FIG. 56 as appropriate. FIG. 56 is a flowchart showing an example of a method of manufacturing the memory device 1E according to the sixth embodiment. Each of FIGS. 57 to 68 is a cross-sectional view showing an example of a cross-sectional structure in the manufacturing process of the memory device 1E according to the sixth embodiment. Each of FIGS. 57, 59, 60, 61, 63, 65, and 67 corresponds to a cross section along the X direction (the WL direction), and shows a similar area to FIG. 54. Each of FIGS. 58, 62, 64, 66, and 68 corresponds to a cross section along the Y direction (the BL direction), and shows a similar area to FIG. 55.

First, like in the first embodiment, the semiconductor substrate W2 is removed from the semiconductor substrates W1 and W2 after bonding (step ST101). Thereby, as shown in FIGS. 57 and 58, the surface of the insulating layer 21 is exposed.

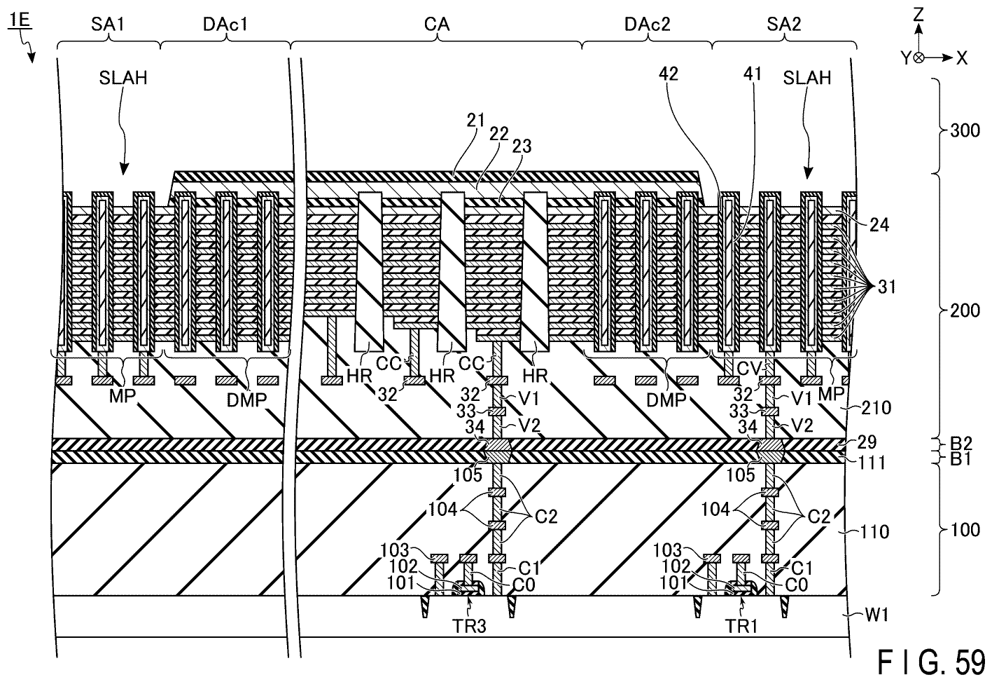

Next, as shown in FIG. 59, openings SLAH are formed (step ST301). Specifically, first, a mask in which the portions of source line areas SLA are opened in a planar view is formed. After that, each of the insulating layer 21, the semiconductor layer 22, and the member 23 is removed in the openings of the mask by anisotropic etching processing, and openings SLAH are formed. That is, the opening SLAH corresponds to the source line area SLA. In the processing of step ST301, the semiconductor layer 24 can be used as an etching stopper layer.

Next, like in the first embodiment, the stacked film 42 in an upper portion of the memory pillar MP is removed (step ST103). In the processing of step ST103, for example, in the opening SLAH, the stacked film 42 provided above the semiconductor layer 24 is selectively removed by wet etching processing. Thereby, in the opening SLAH, the semiconductor layer 41 in an upper portion of each memory pillar MP is exposed. In this step, an upper portion of the columnar member HR in the contact area CA is protected by the semiconductor layer 22 and the insulating layer 21.

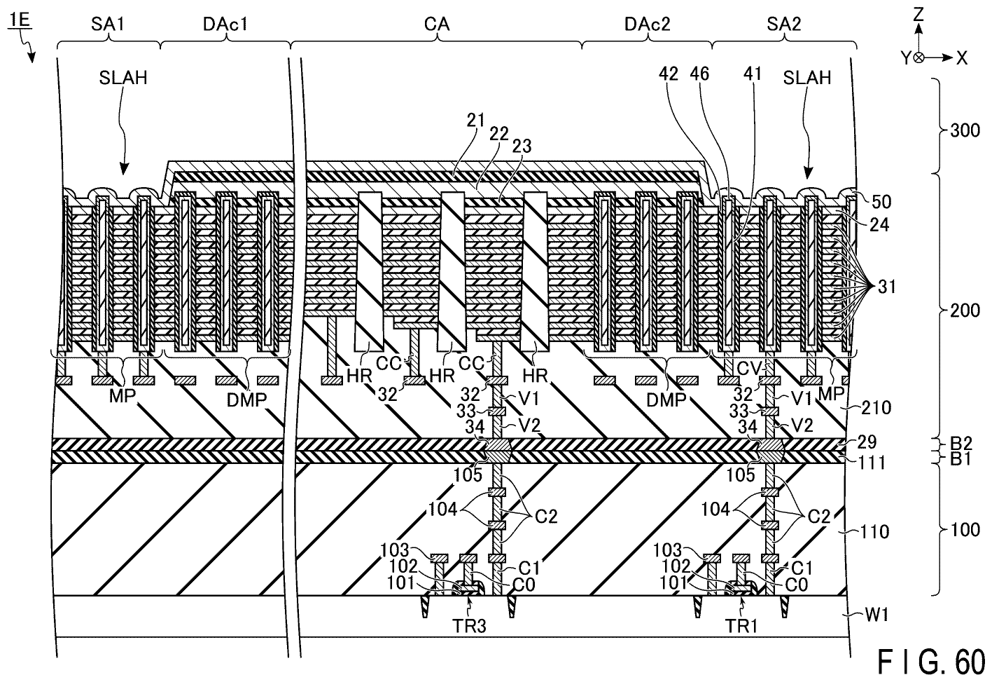

Next, as shown in FIG. 60, like in the first embodiment, a semiconductor layer 50 is formed (step ST104), and ion implantation and annealing treatment are executed (step ST105). The semiconductor layer 50 is continuously provided between the storage areas SA1 and SA2 via the contact area CA and the dummy areas DAc1 and DAc2. The semiconductor layer 50 has a portion provided along the semiconductor layer 41 in an upper portion of the memory pillar MP in each of the storage areas SA1 and SA2, and has a portion provided on the insulating layer 21 in the contact area CA. In the ion implantation processing, an impurity is implanted into an upper portion of each memory pillar MP. After that, annealing treatment is executed, and thereby the implanted impurity is diffused to an upper portion of the semiconductor layer 41. In FIG. 60, the semiconductor layer 41 thus doped with an impurity is shown as a semiconductor layer 46. The impurity doped in the semiconductor layer 41 by this step is, for example, at least one of phosphorus (P) and arsenic (As).

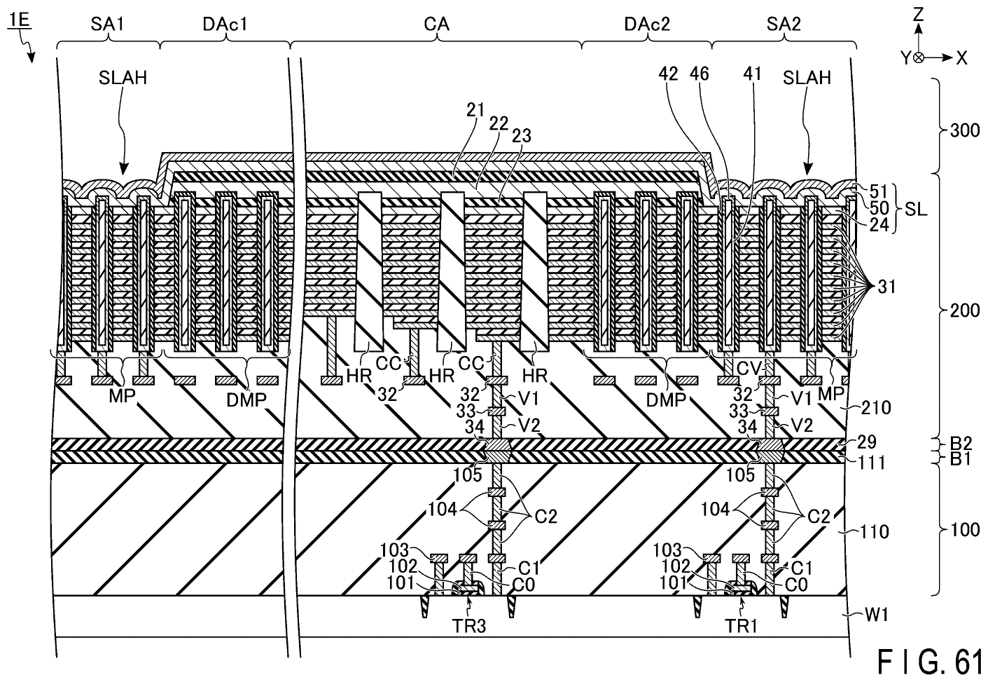

Next, as shown in FIG. 61, a conductive layer 51 is formed like in the first embodiment (step ST107). Specifically, the conductive layer 51 is formed on the semiconductor layer 50, and is continuously provided between the storage areas SA1 and SA2 via the contact area CA and the dummy areas DAc1 and DAc2. The semiconductor layers 24 and 50 and the conductive layer 51 function as part of the source line SL.

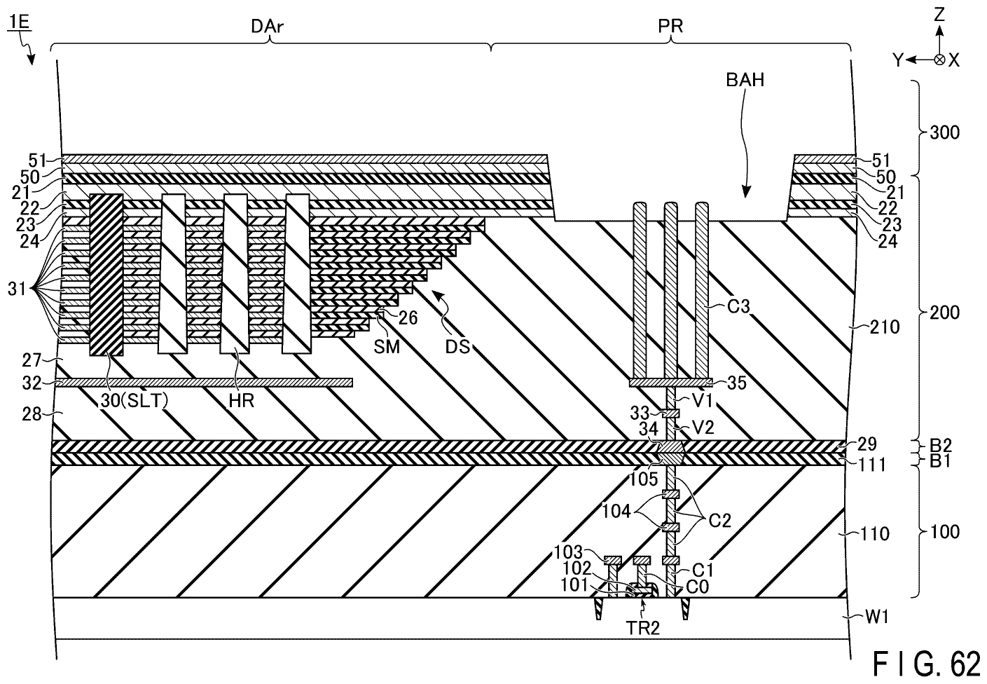

Next, as shown in FIG. 62, an opening BAH is formed (step ST302). Specifically, first, a mask in which the portion of an insulating area BA is opened in a planar view is formed. After that, each of the insulating layer 21, the semiconductor layers 22, 24, and 50, the member 23, and the conductive layer 51 is removed in the opening of the mask by anisotropic etching processing, and an opening BAH is formed. That is, the opening BAH corresponds to the insulating area BA. By the processing of step ST302, the surface of the insulating layer 210 and an upper portion of at least one contact C3 are exposed at the bottom of the opening BAH.

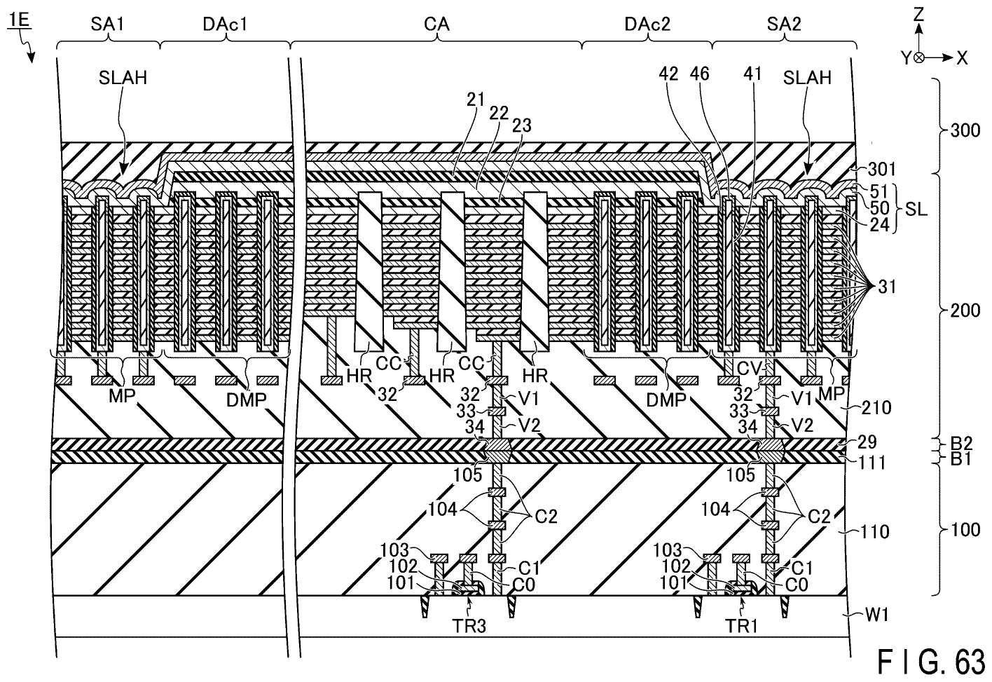

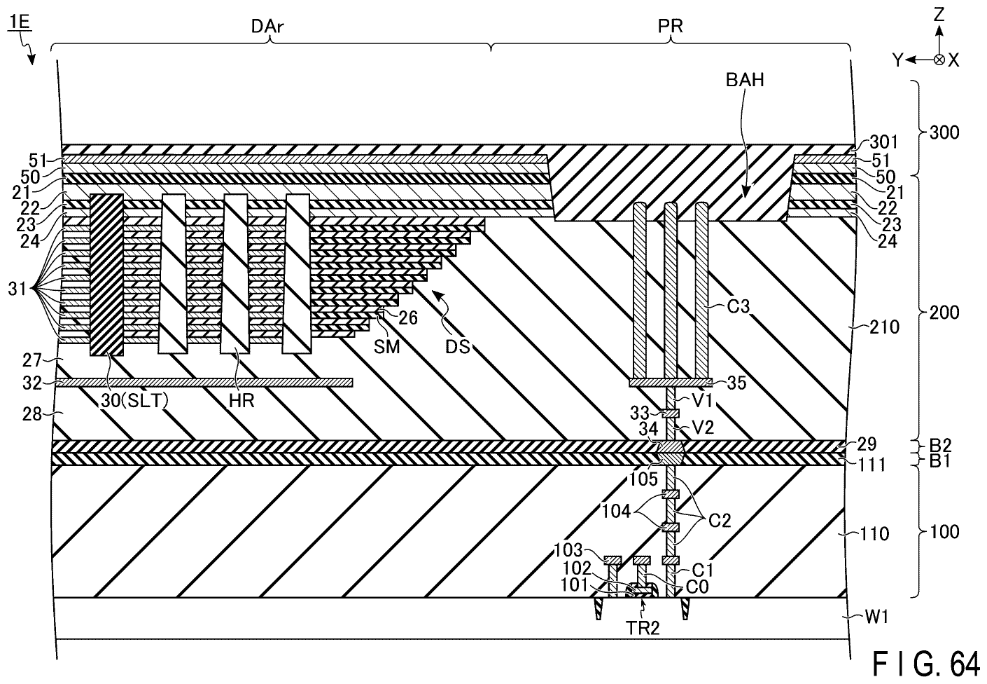

Next, as shown in FIGS. 63 and 64, an insulating member 301 is formed (step ST303). Specifically, first, an insulating member 301 is formed to be embedded in the openings SLAH and BAH (the source line areas SLA and the insulating area BA). After that, the surface of the insulating member 301 is planarized by CMP processing or the like. The planarized insulating member 301 covers the upper surface of the conductive layer 51.

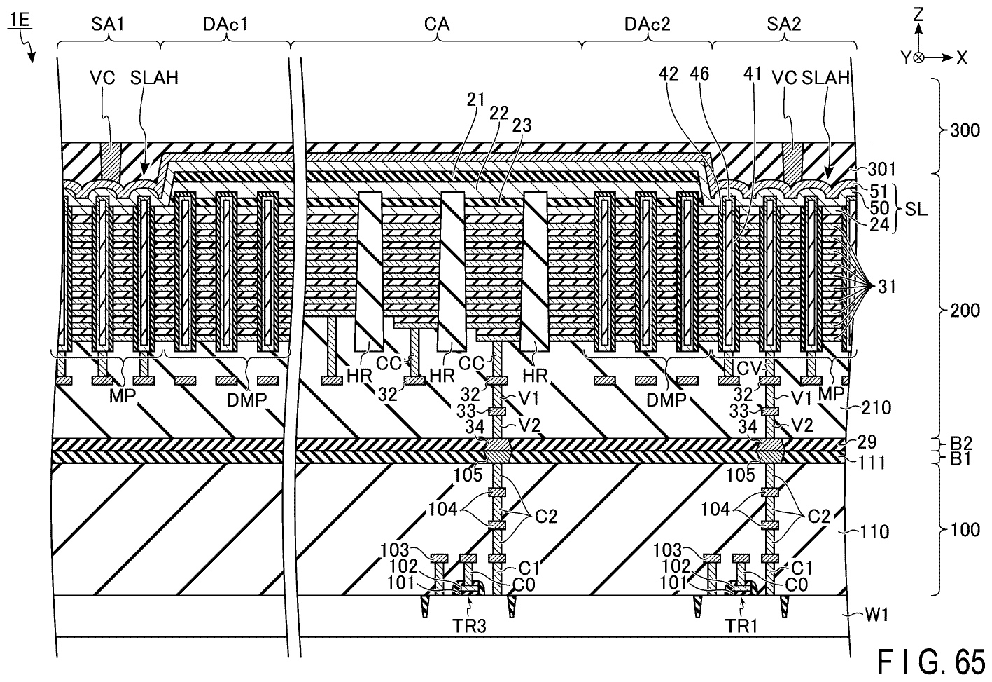

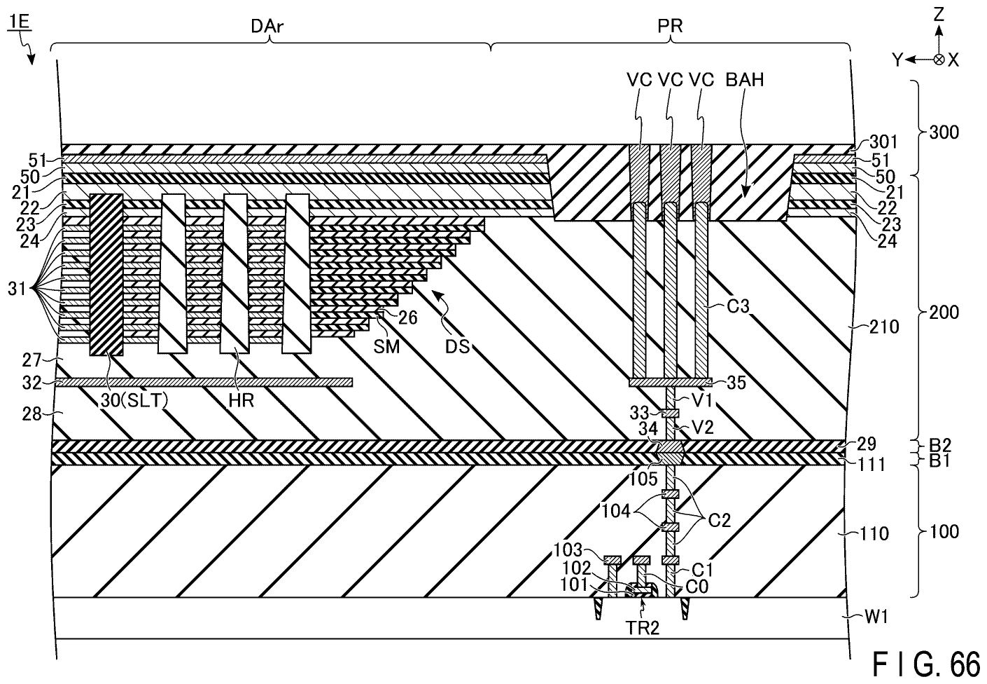

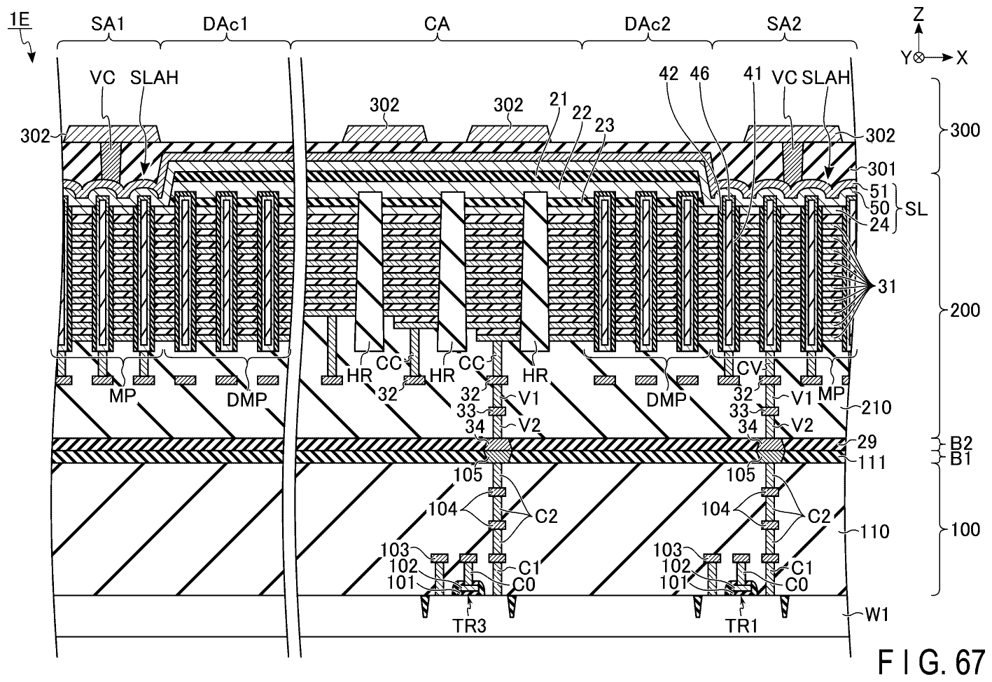

Next, as shown in FIGS. 65 and 66, via contacts VC are formed (step ST304). Specifically, a mask in which the portions of via contacts VC are opened in a planar view is formed. After that, the insulating member 301 is removed in the openings of the mask by anisotropic etching processing, and a conductor is formed such that the portions where the insulating member 301 has been removed are filled. After that, the conductor formed on the upper surface of the insulating member 301 is removed, and thereby the structure of each via contact VC is formed. By the processing of step ST304, a bottom portion of each of the via contacts VC provided in the storage areas SA1 and SA2 is connected to the conductive layer 51. A bottom portion of each of the via contacts VC provided in the peripheral area PR is connected to the associated contact C3.

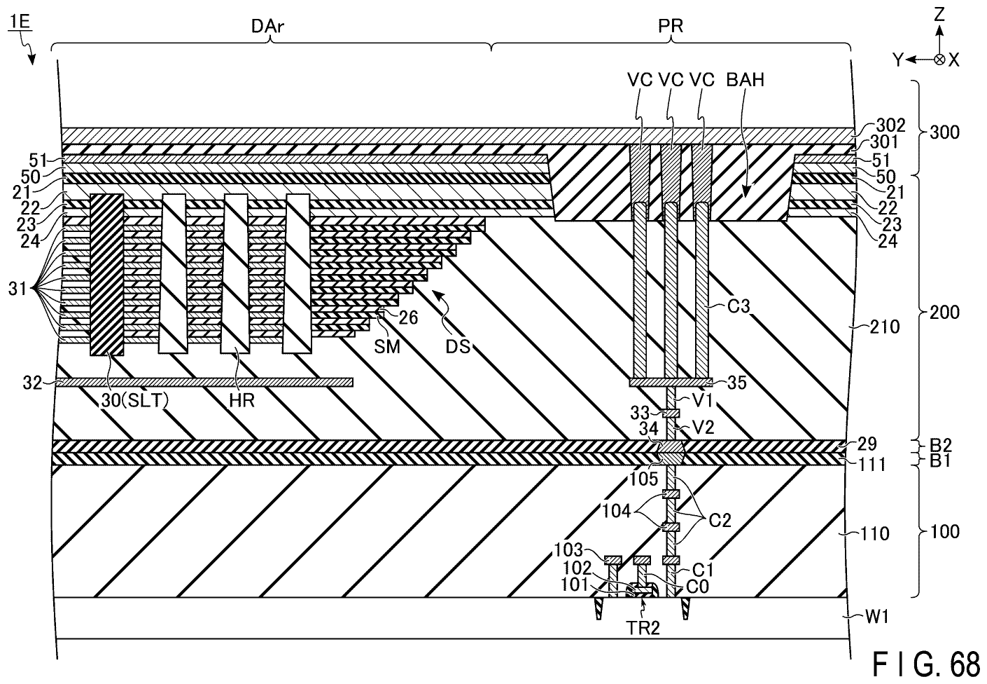

Next, as shown in FIGS. 67 and 68, conductive layers 302 are formed on the insulating member 301 (step ST305). In the processing of step ST305, a conductive layer 302 is processed into a desired configuration by photolithography processing and etching processing. The conductive layers 302 provided in the storage areas SA1 and SA2 are electrically connected to the conductive layer 51 via the via contacts VC. The conductive layer 302 provided in the peripheral area PR is electrically connected to the contact C3 via the via contact VC. After that, like in the first embodiment, insulating layers 303, 304, and 305 are formed (step ST111), and a via TV is formed (step ST112). Thereby, the structure of the memory device 1E shown in FIGS. 54 and 55 is completed.

### <6-3> Advantageous Effects of the Sixth Embodiment

As described hereinabove, in a case where two storage areas SA1 and SA2 are arranged to sandwich a contact area CA, a source line SL may be connected between the two storage areas SA1 and SA2. As a result, the memory device 1E according to the sixth embodiment can reduce the difference in characteristics of the source line SL between the two storage areas SA1 and SA2 without adding a wiring layer. Then, the memory device 1E according to the sixth embodiment can improve the performance of the memory cell transistor MT.

### <7> Seventh Embodiment

In a memory device 1F according to a seventh embodiment, a conductive layer 51 is continuously provided between storage areas SA1 and SA2, and the conductive layer 51 in a contact area CA is placed not to be included in the vicinity of the peripheral area PR. Details of the memory device 1F according to the seventh embodiment will now be described focusing on differences from the first to sixth embodiments.

### <7-1> Configuration

A configuration of the memory device 1F according to the seventh embodiment will now be described.

### (1: Planar Layout of the Core Area CR)

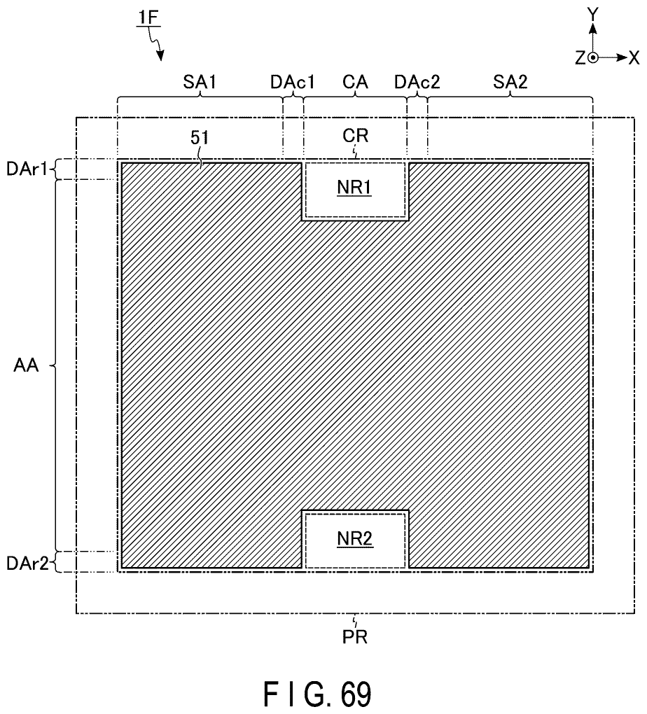

FIG. 69 is a plan view showing an example of a planar layout of a memory cell array 10 included in the memory device 1F according to the seventh embodiment. FIG. 69 shows one core area CR and a peripheral area PR in the vicinity thereof, and shows placement of a conductive layer 51. As shown in FIG. 69, the core area CR of the seventh embodiment has two neighboring areas NR1 and NR2. The neighboring areas NR1 and NR2 are included at least in a contact area CA, and have portions overlapping with dummy areas DAr1 and DAr2, respectively. Each of the neighboring areas NR1 and NR2 is adjacent to the peripheral area PR. The conductive layer 51 of the seventh embodiment is placed in, for example, an area of the core area CR excluding the neighboring areas NR1 and NR2. That is, the conductive layer 51 of the seventh embodiment is, at least in the contact area CA, provided not to be placed in the vicinity of the peripheral area PR (for example, an area between two adjacent core areas CR).

Although FIG. 69 shows, as an example, a case where a conductive layer 51 is provided on the entire surfaces of the storage areas SA1 and SA2 and the dummy areas DAc1 and DAc2, the configuration is not limited thereto. Each of the neighboring areas NR1 and NR2 may overlap with each of the storage areas SA1 and SA2 and the dummy areas DAc1 and DAc2. In this case, an end portion in the Y direction of the conductive layer 51 is preferably located in the dummy area DAr1 or DAr2. Each of the neighboring areas NR1 and NR2 may not overlap with the active area AA. In this case, the neighboring areas NR1 and NR2 are included in the dummy areas DAr1 and DAr2, respectively.

### (2: Cross-Sectional Structure of the Memory Device 1F)

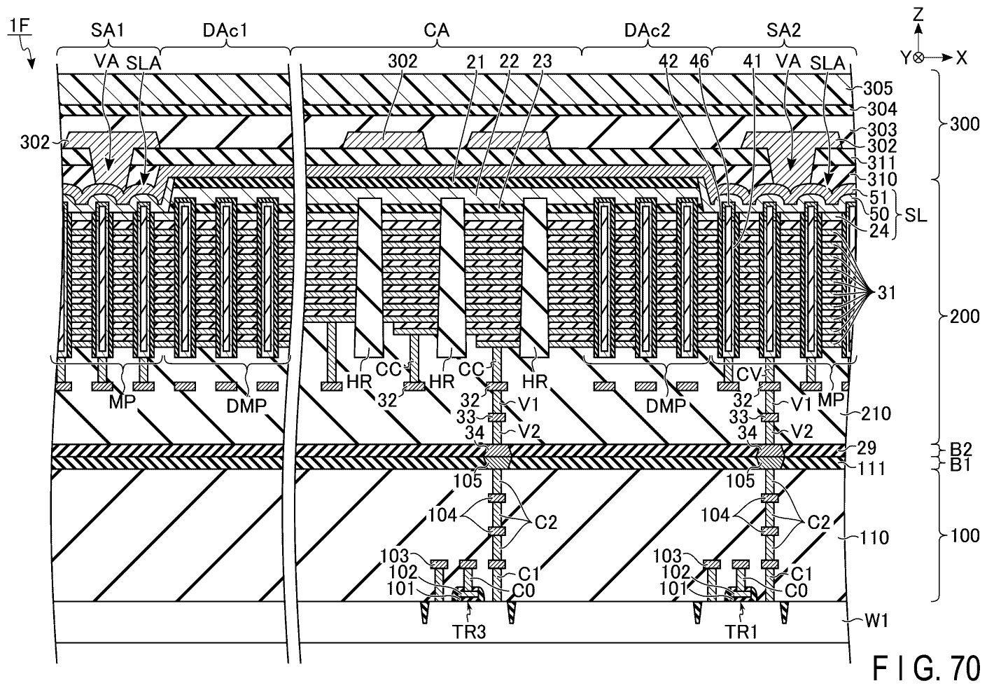

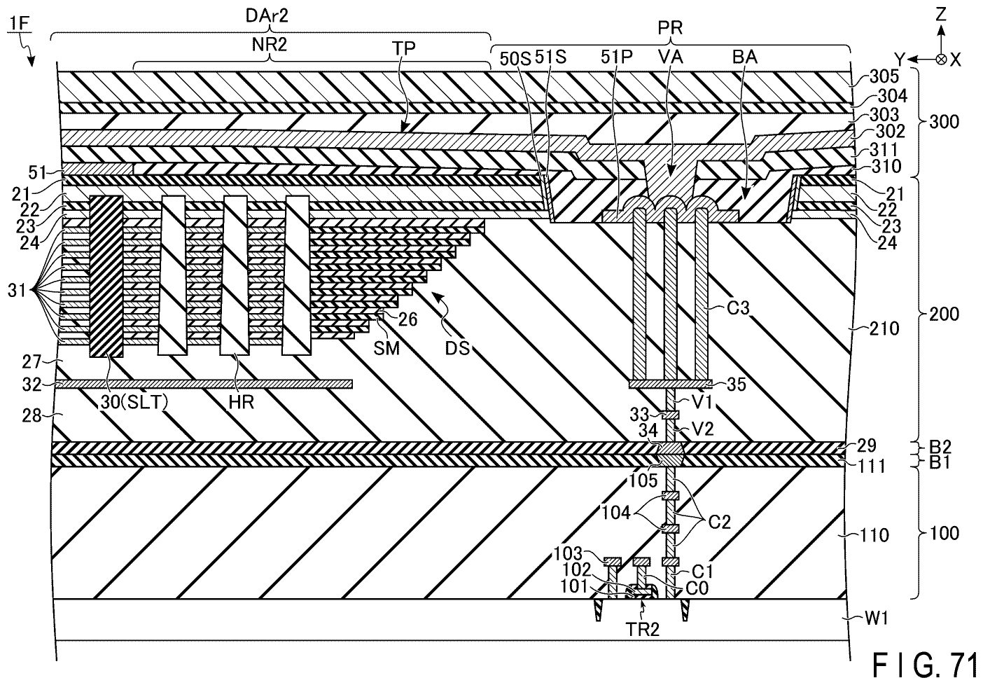

FIGS. 70 and 71 are cross-sectional views showing examples of cross-sectional structures of the memory device 1F according to the seventh embodiment. FIG. 70 shows an area including the storage areas SA1 and SA2 and the contact area CA and extending along the X direction (the WL direction). FIG. 71 shows an area including the dummy area DAr and the peripheral area PR and extending along the Y direction (the BL direction) in the contact area CA.

The structure in each of the storage areas SA1 and SA2 of the seventh embodiment is different from that of the storage area SA described in the first embodiment in that the insulating member 301 in the source line area SLA is replaced with insulating members 310 and 311 and the conductive layer 51 is continuously provided between the storage areas SA1 and SA2. Specifically, as shown in FIG. 70, in the source line area SLA of each storage area SA, insulating members 310 and 311 are sequentially stacked on the conductive layer 51. Then, conductive layers 302 are provided on the insulating member 311. The conductive layer 302 in each storage area SA is connected to the conductive layer 51 via a via VA penetrating the insulating members 311 and 310.

In the seventh embodiment, in the contact area CA, the conductive layer 51 and the insulating member 311 are provided between the insulating layer 21 and the insulating layer 303. Specifically, in the contact area CA, the conductive layer 51 and the insulating member 311 are sequentially stacked on the insulating layer 21. Then, the conductive layer 51 in the storage area SA1 and the conductive layer 51 in the storage area SA2 are continuously provided via the conductive layer 51 on the insulating layer 21 in the contact area CA. Further, the insulating member 311 in the storage area SA1 and the insulating member 311 in the storage area SA2 are continuously provided via the insulating member 311 on the conductive layer 51 in the contact area CA. A portion of the conductive layer 51 provided along an end portion of the source line area SLA (the side surfaces of the insulating layer 21, the semiconductor layer 22, and the member 23) is included in, for example, the dummy area DAc1 or DAc2. The upper surfaces of the insulating members 310 in the storage areas SA1 and SA2 are aligned with the upper surface of the conductive layer 51 in the contact area CA.

The structure in each of the dummy area DAr and the peripheral area PR of the seventh embodiment is different from that of the dummy area DAr and the peripheral area PR described in the first embodiment in the structure of the insulating area BA and the structure on the insulating layer 21 in the contact area CA. Specifically, as shown in FIG. 71, the insulating area BA of the seventh embodiment includes a conductive layer 51P, and is filled with the insulating member 310. The conductive layer 51P is formed in the same step as the conductive layer 51, and corresponds to a portion separated from the conductive layer 51. The conductive layer 51P has a portion provided on the insulating layer 210 and a portion provided along an upper portion of at least one contact C3, and is electrically connected to the at least one contact C3. An upper portion of the conductive layer 51P has a portion covered with the insulating member 310. In the peripheral area PR, the conductive layer 302 is connected to the conductive layer 51P via a via VA penetrating the insulating members 310 and 311.

The dummy area DAr2 of the seventh embodiment has, in an area overlapping with the contact area CA and the dummy areas DAc1 and DAc2, a stacked structure of the semiconductor layer 24, the member 23, the semiconductor layer 22, and the insulating layer 21. In the present example, the dummy area DAr2 has the conductive layer 51 on the insulating layer 21 on the active area AA side, and has the insulating member 310 on the insulating layer 21 in the neighboring area NR2. The insulating member 310 in the neighboring area NR2 has a tapered portion TP, and is provided continuously with the insulating member 310 in the insulating area BA. Thus, the insulating member 310 has a level difference in the insulating area BA. In an end portion of the neighboring area NR2 on the opposite side to the peripheral area PR, the upper surface of the conductive layer 51 and the upper surface of the insulating member 310 are aligned. In the dummy area DAr2, the insulating member 311 and the conductive layer 302 are sequentially provided on the conductive layer 51 and the insulating member 310. Each of the insulating member 311 and the conductive layer 302 has a portion provided along the insulating member 310 and a portion provided along the conductive layer 51. The height of the upper surface of a portion of the conductive layer 302 overlapping with at least one contact C3 or the conductive layer 51P in the Z direction is lower than the height of the upper surface of a portion of the conductive layer 302 overlapping with the conductive layer 51 via the insulating member 311 in the Z direction. The configuration of the other parts of the memory device 1F according to the seventh embodiment is similar to that of the first embodiment.

### <7-2> Manufacturing Method

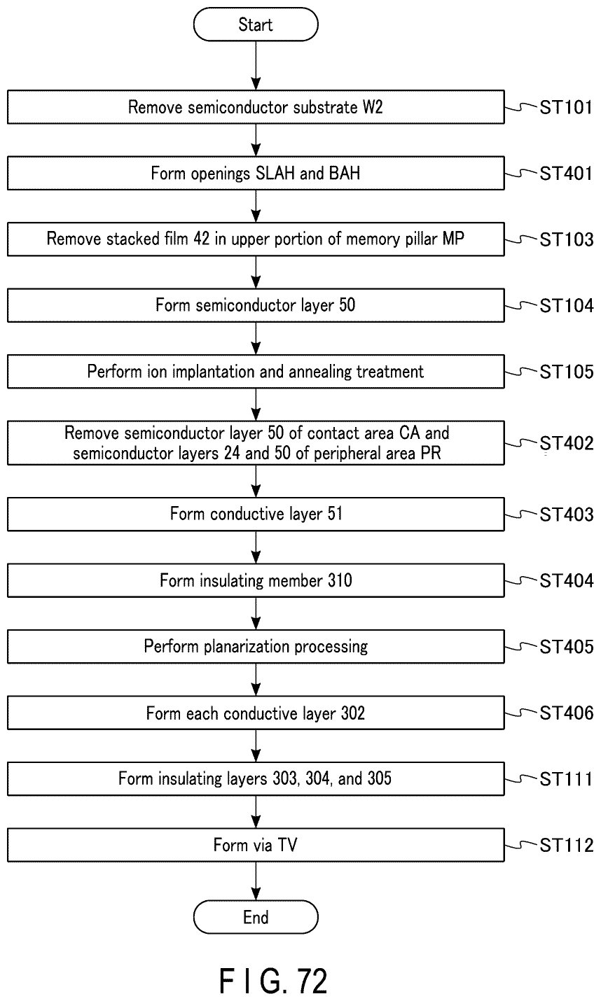

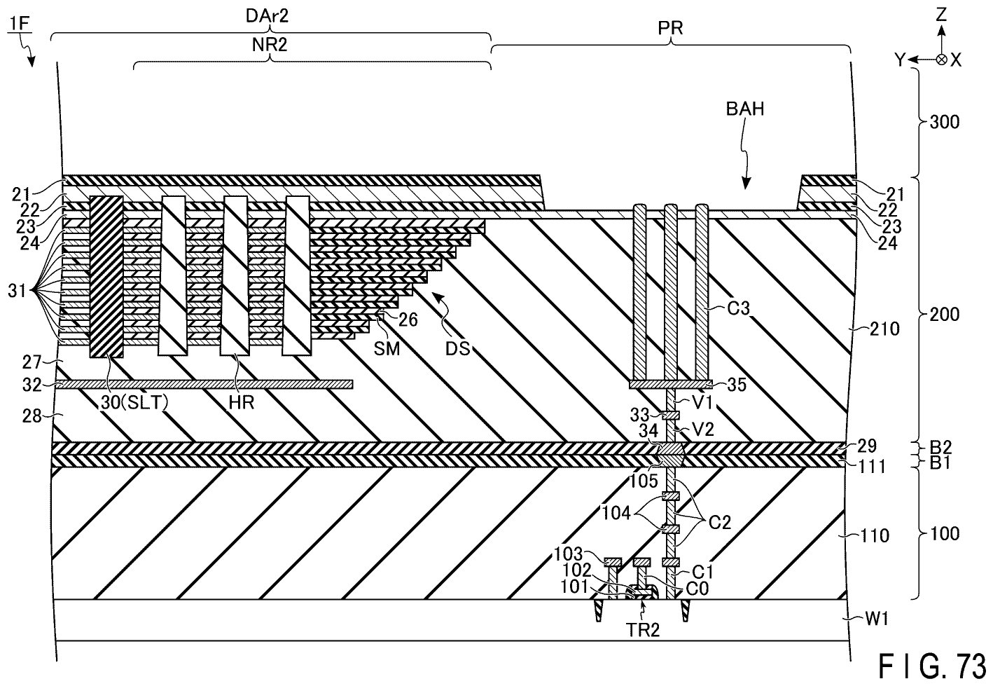

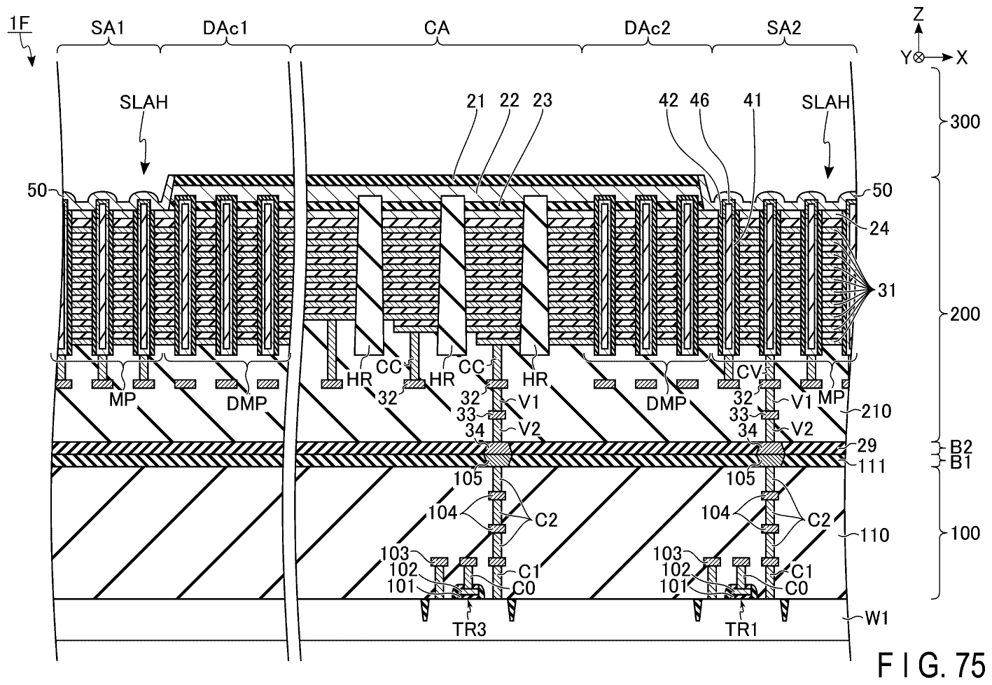

Next, as a method of manufacturing the memory device 1F according to the seventh embodiment, a method of forming the source line SL and the wiring layer 300 after bonding the semiconductor substrate W1 and the semiconductor substrate W2 is described with reference to FIG. 72 as appropriate. FIG. 72 is a flowchart showing an example of a method of manufacturing the memory device 1F according to the seventh embodiment. Each of FIGS. 73 to 84 is a cross-sectional view showing an example of a cross-sectional structure in the manufacturing process of the memory device 1F according to the seventh embodiment. Each of FIGS. 75, 77, 79, 81, and 83 corresponds to a cross section along the X direction (the WL direction), and shows a similar area to FIG. 70. Each of FIGS. 73, 74, 76, 78, 80, 82, and 84 corresponds to a cross section along the Y direction (the BL direction), and shows a similar area to FIG. 71.

First, like in the first embodiment, the semiconductor substrate W2 is removed from the semiconductor substrates W1 and W2 after bonding (step ST101). Then, openings SLAH and BAH are formed (step ST401). In step ST401, the opening SLAH is formed similarly to the opening SLAH described using FIG. 59 in the sixth embodiment. As shown in FIG. 73, the opening BAH is formed in a portion corresponding to the insulating area BA. At the bottom of the opening BAH, the semiconductor layer 24 and an upper portion of at least one contact C3 are exposed.

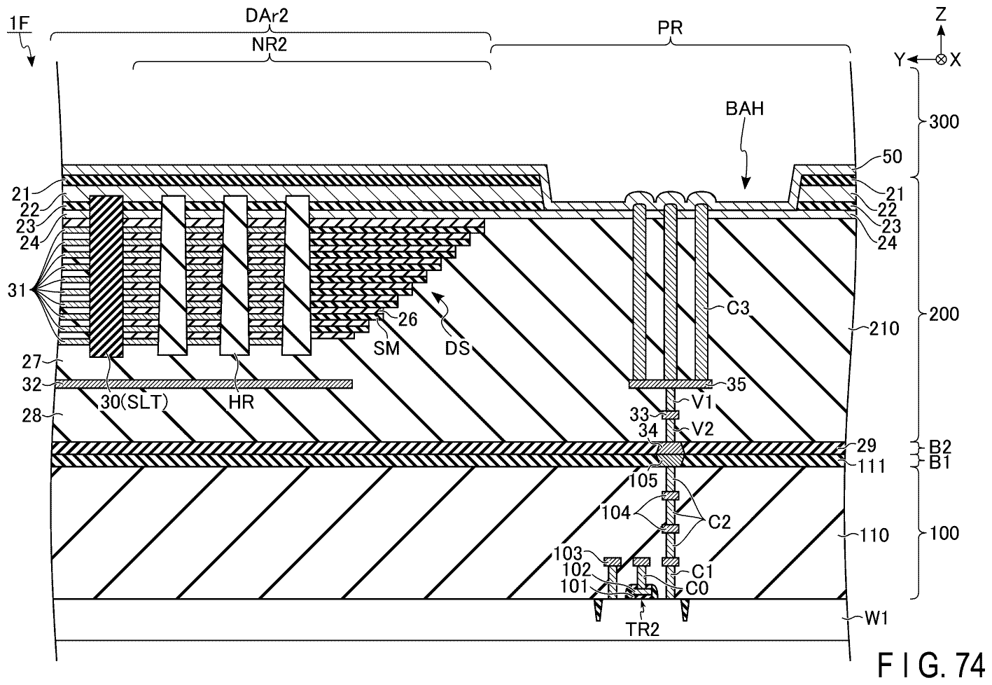

Next, like in the sixth embodiment, the stacked film 42 in an upper portion of the memory pillar MP is removed (step ST103), a semiconductor layer 50 is formed (step ST104), and ion implantation and annealing treatment are executed (step ST105). Thereby, the structures shown in FIGS. 60 and 74 are formed.

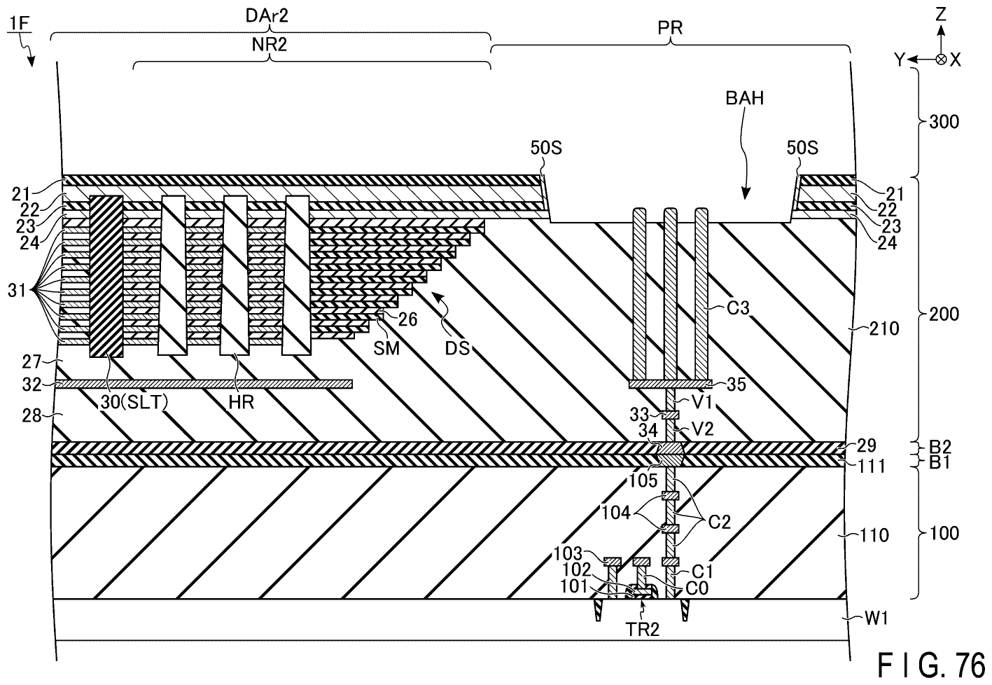

Next, as shown in FIGS. 75 and 76, the semiconductor layer 50 of the contact area CA and the semiconductor layers 24 and 50 of the peripheral area PR are removed (step ST402). Specifically, first, a mask that covers the storage areas SA1 and SA2 in a planar view is formed. After that, in the opening of the mask, the semiconductor layer 50, or the semiconductor layers 50 and 24 are removed by anisotropic etching processing. Thereby, the semiconductor layer 50 of the storage area SA1 and the semiconductor layer 50 of the storage area SA2 are separated, and the insulating layer 210 is exposed at the bottom of the opening BAH. The semiconductor layer 50 provided on the side surface of the opening BAH may remain. In FIG. 76, the semiconductor layer 50 remaining on the side surface of the opening BAH is shown as a semiconductor layer 50S.

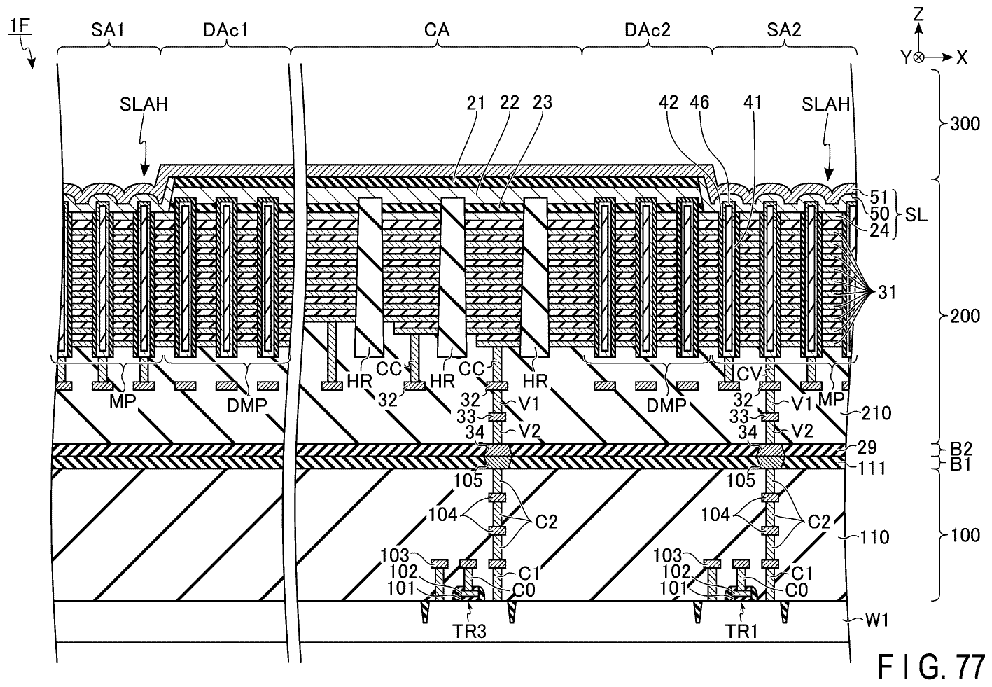

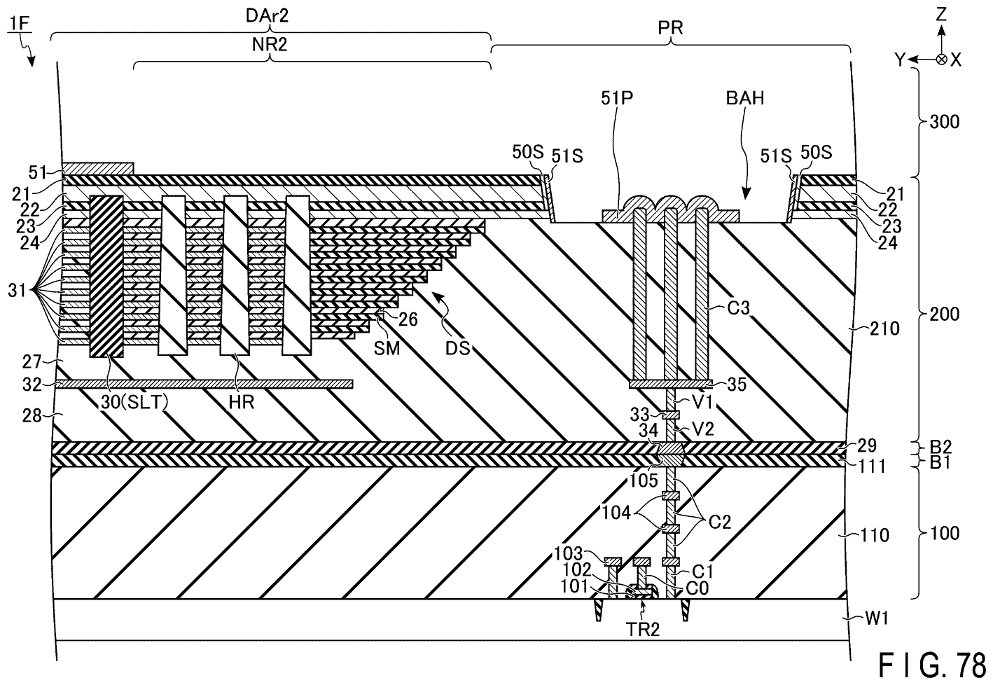

Next, as shown in FIGS. 77 and 78, a conductive layer 51 is formed (step ST403). Specifically, first, a conductive layer 51 is formed by, for example, CVD processing or the like. Then, a mask that covers, in a planar view, a portion corresponding to the conductive layer 51 shown in FIG. 69 and an upper portion of at least one contact C3 is formed. After that, the conductive layer 51 is removed in the opening of the mask by anisotropic etching processing. Thereby, the conductive layer 51 in the core area CR is processed into the shape shown in FIG. 69, and the conductive layer 51 in the peripheral area PR is processed into the shape of the conductive layer 51P. The conductive layer 51 provided on the side surface of the opening BAH may remain. In FIG. 78, the conductive layer 51 remaining on the side surface of the opening BAH is shown as a conductive layer 51S.

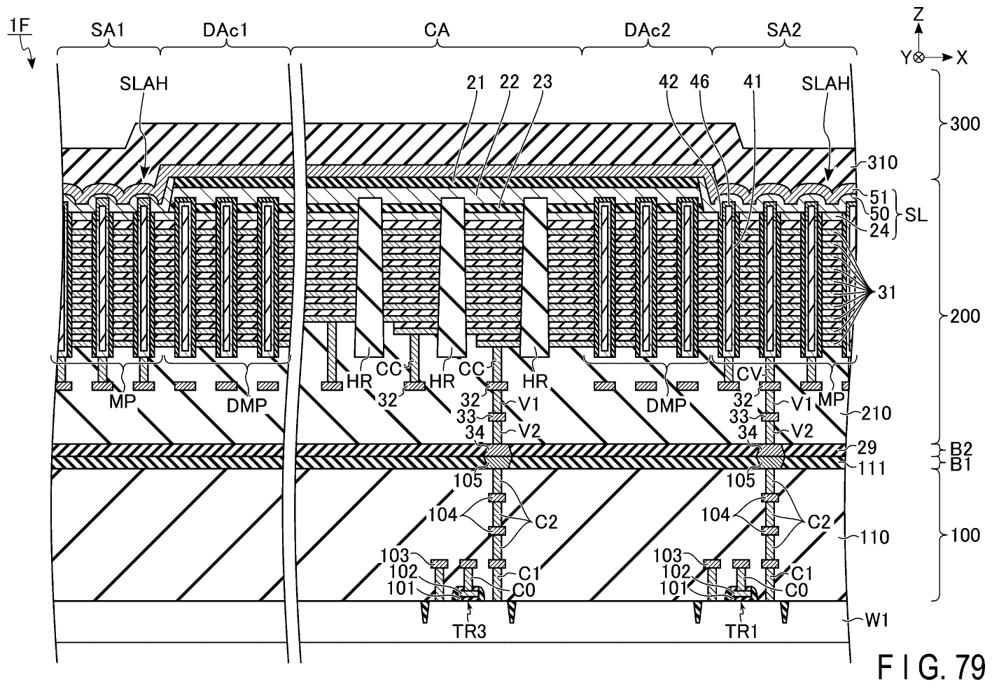

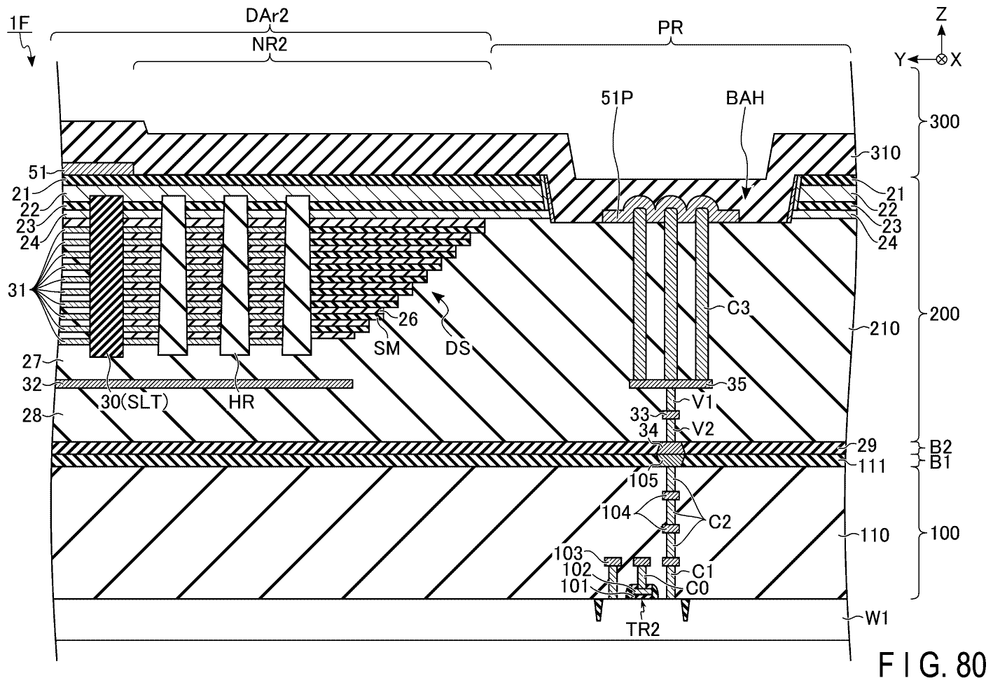

Next, as shown in FIGS. 79 and 80, an insulating member 310 is formed (step ST404). By the processing of step ST404, the insulating member 310 is embedded in the openings SLAH and BAH (the source line areas SLA and the insulating area BA).

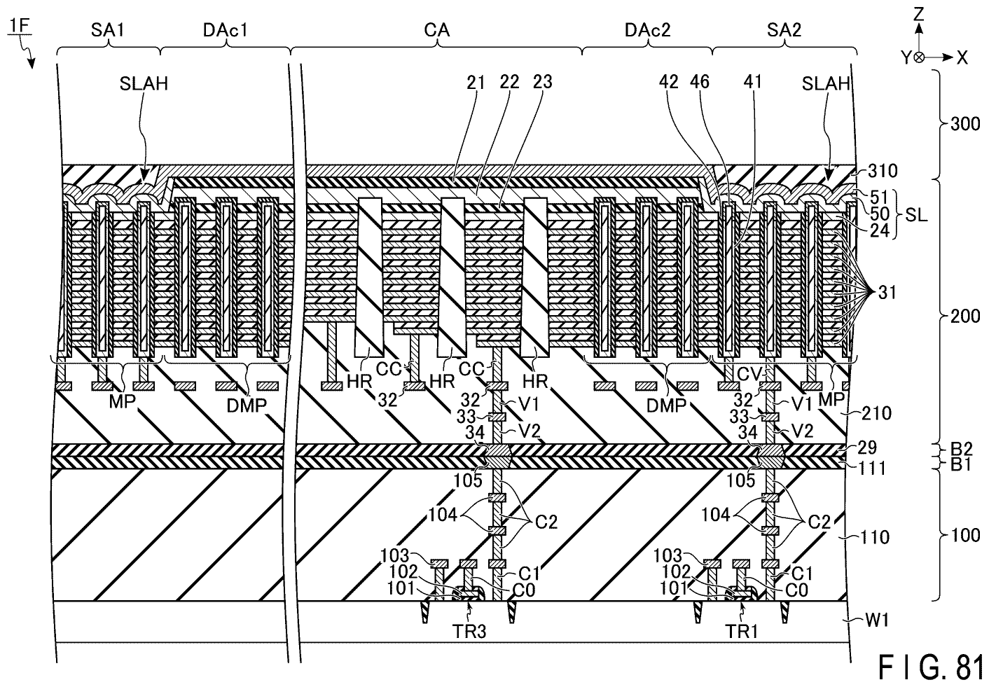

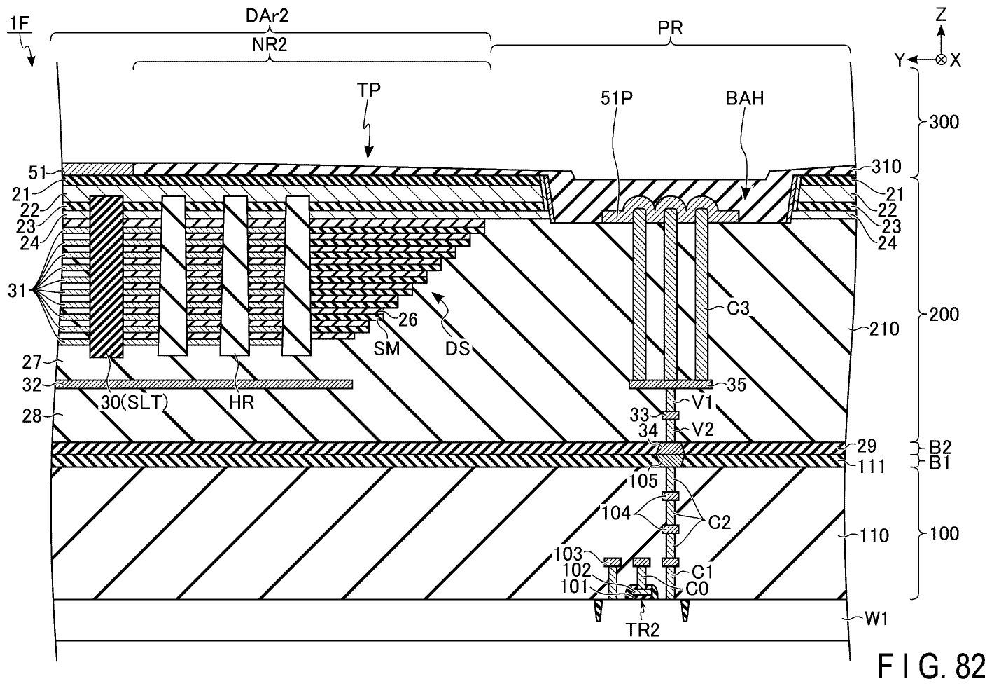

After that, planarization processing such as CMP processing is executed (step ST405). In the processing of step ST405, planarizing processing is executed such that the conductive layer 51 provided on the insulating layer 21 is exposed. Then, as shown in FIG. 81, at least the upper surface of the conductive layer 51 in the contact area CA is exposed, and the upper surfaces of the insulating members 310 in the storage areas SA1 and SA2 and the upper surface of the conductive layer 51 in the contact area CA are aligned. Then, as shown in FIG. 82, a tapered portion TP of the insulating member 310 is formed from the dummy area DAr toward the peripheral area PR. Specifically, the tapered portion TP of the insulating member 310 is formed between a portion of the peripheral area PR provided in the insulating area BA and an end portion of the conductive layer 51 in the dummy area DAr.

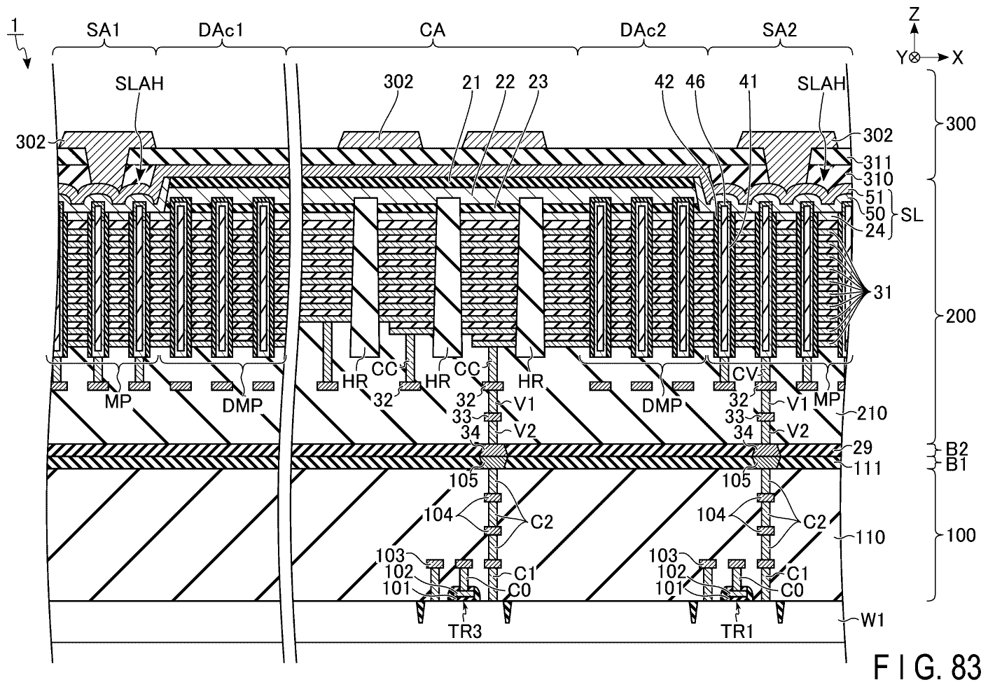

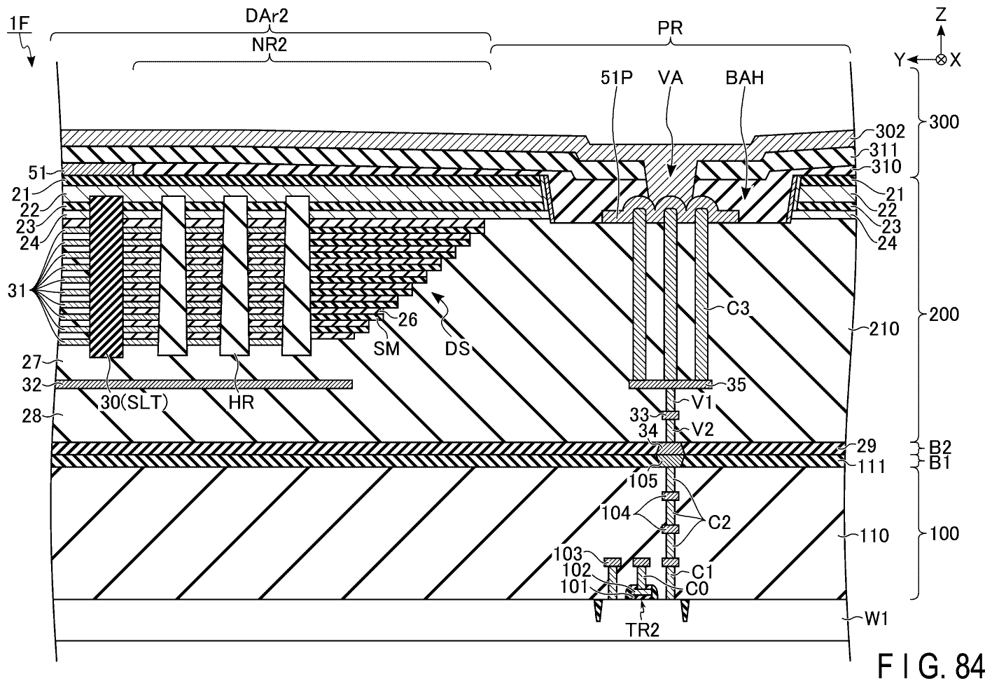

Next, as shown in FIGS. 83 and 84, conductive layers 302 are formed (step ST406). Specifically, first, an insulating member 311 is formed on the insulating member 310. Then, a mask in which the portions of vias VA are opened in a planar view is formed. After that, the insulating member 310 and the insulating member 311 are removed in the openings of the mask by anisotropic etching processing, and vias VA are formed. Then, a conductive layer 302 is formed such that the portions where the insulating member 310 and the insulating member 311 have been removed are filled. After that, the conductive layer 302 is processed into a desired configuration by photolithography processing and etching processing. The conductive layers 302 provided in the storage areas SA1 and SA2 are electrically connected to the conductive layer 51 via the vias VA. The conductive layer 302 provided in the peripheral area PR is electrically connected to at least one contact C3 via the via VA and the conductive layer 51P. After that, like in the first embodiment, insulating layers 303, 304, and 305 are formed (step ST111), and a via TV is formed (step ST112). Thereby, the structure of the memory device 1F shown in FIGS. 70 and 71 is completed.

### <7-3> Advantageous Effects of the Seventh Embodiment

Similarly to the sixth embodiment, the memory device 1F according to the seventh embodiment can reduce the difference in characteristics of the source line SL between the two storage areas SA1 and SA2 without adding a wiring layer. Then, the memory device 1F according to the seventh embodiment can improve the performance of the memory cell transistor MT.

Further, in the memory device 1F according to the seventh embodiment, the source line SL is connected between the two storage areas SA1 and SA2, and the conductive layer 51 is not placed in the neighboring area NR1 or NR2. Thereby, the height of the via VA for connecting the conductive layer 302 and the conductive layer 51P is reduced, and the difficulty of embedding a conductor in the via VA can be reduced. As a result, the memory device 1F according to the seventh embodiment can suppress the occurrence of failures related to connection between the conductive layer 302 and the conductive layer 51P.

### <7-4> Modification Example of the Seventh Embodiment

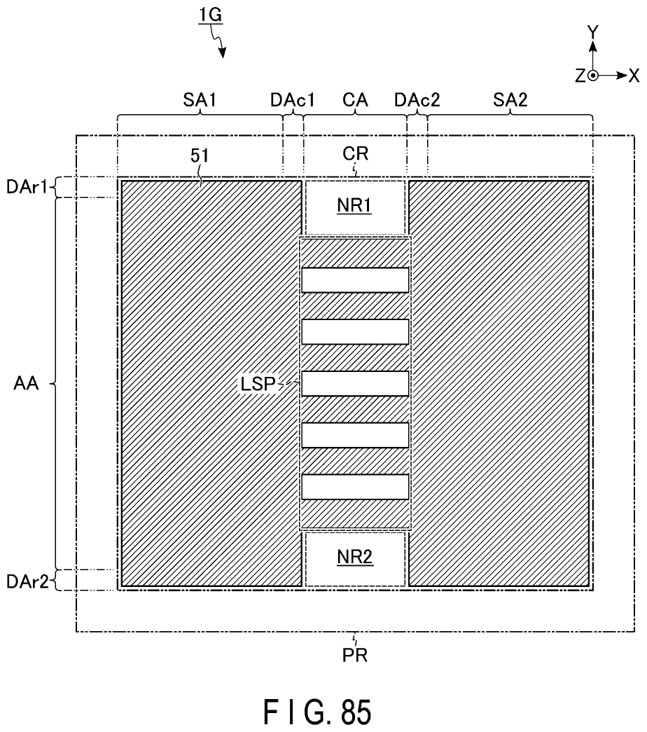

FIG. 85 is a plan view showing an example of a planar layout of a memory cell array 10 included in a memory device 1G according to a modification example of the seventh embodiment. FIG. 85 shows one core area CR and a peripheral area PR in the vicinity thereof, and shows placement of a conductive layer 51. As shown in FIG. 85, the conductive layer 51 of the memory device 1G has a line-and-space portion LSP. The line-and-space portion LSP is, for example, placed between the neighboring areas NR1 and NR2 in the contact area CA. The line-and-space portion LSP has a configuration in which a portion (line portion) of the conductive layer 51 extending in the X direction and a space portion are alternately arranged in the Y direction. In the modification example of the seventh embodiment, the conductive layer 51 in the storage area SA1 and the conductive layer 51 in the storage area SA2 are continuously provided via the line-and-space portion LSP.

A method of manufacturing the memory device 1G according to the modification example of the seventh embodiment is similar to the method of manufacturing the memory device 1F described using FIG. 72 in the seventh embodiment. Then, the processing of step ST405 in the method of manufacturing the memory device 1G is executed such that the conductive layer 51 of the line-and-space portion LSP is exposed. In the memory device 1G, the area of the conductive layer 51 provided in the contact area CA is smaller than that of the memory device 1F. Thus, in the modification example of the seventh embodiment, the time for planarization processing of step ST405 can be made shorter than in the seventh embodiment.

On the other hand, in the memory device 1F according to the seventh embodiment, since the area of the conductive layer 51 provided in the contact area CA is larger, the resistance value of the source line SL can be made lower than in the modification example of the seventh embodiment, and the characteristics of the memory cell transistor MT can be improved. Thus, by the seventh embodiment and the modification example of the seventh embodiment, the balance between the manufacturing cost and the performance of the memory cell transistor MT can be adjusted according to the placement of the conductive layer 51.

### <8> Modification Examples and the Like

The memory device 1 described hereinabove can be variously modified.

The aspect described in the above embodiments can be combined as appropriate. For example, the second embodiment may be combined with the third embodiment. The fourth embodiment may be combined with the second and third embodiments. The fifth embodiment may be combined with the second to fourth embodiments. Each of the sixth embodiment and the seventh embodiment may be combined with the first to fifth embodiments. Further, the structure of the sixth or seventh embodiment may be applied to the structure of the memory device 1X according to the comparative example to the first embodiment shown in FIGS. 27 and 28. In a case where the structure of the sixth or seventh embodiment is applied to the memory device 1X, the source lines SL provided in the storage areas SA on both sides in the X direction in the core area CR can be electrically connected to each other without interfering with wiring lines for power supply extending in the Y direction (conductive layers 302B (PL)).

In the above embodiment, each of the circuit configuration, the planar layout, and the cross-sectional structure of the memory device 1 can be changed as appropriate. Other contacts may be inserted between the memory pillar MP and the conductive layer 32. Other contacts may be inserted between the contact C3 and the conductive layer 35. A conductive layer may be inserted into the coupled portion between contacts. The numbers of wiring layers and contacts included in the memory device 1 can be changed according to circuit design as appropriate. The memory pillar MP or each contact may have a tapered shape, an inverse tapered shape, or a bowing shape. The XY cross-sectional structure of the memory pillar MP may be a circular shape or an elliptical shape. Each wiring line in the stacked wiring lines included in the memory cell array 10 may include a metal oxide film around a conductor such as tungsten. The conductive layer alternately stacked with the insulating layer in the stacked wiring lines may be regarded as a configuration including such a metal oxide film.

In the present specification, “connection” refers to being electrically connected, and does not exclude, for example, being connected via another element. “Electrically connected” may be connection via an insulator as long as operations similar to those in a case of being electrically connected can be performed. The “semiconductor substrate” may be referred to simply as a “substrate”. The “semiconductor layer” may be referred to as a “conductive layer”. The “area” may be regarded as a configuration included by a substrate. For example, in a case where it is provided that a semiconductor substrate W1 includes a storage area SA and a contact area CA, the storage area SA and the contact area CA are associated with different areas above the semiconductor substrate W1. The “height” corresponds to, for example, the spacing in the Z direction between a configuration of a measurement object and the semiconductor substrate W1. As a reference of “height”, a configuration other than the semiconductor substrate W1 may be used. The “planar view” corresponds to, for example, viewing the surface of the semiconductor substrate W1 from the vertical direction of the semiconductor substrate W1. The “via” may be referred to as an opening.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory device having a bonding surface, the memory device comprising:
a substrate having a first area and a second area arranged in a first direction;
a first circuit layer provided between the substrate and the bonding surface and including a CMOS circuit; and
a second circuit layer provided above the bonding surface, wherein
the second circuit layer includes, in the first area, a memory cell array including a layer stack and a plurality of first pillars, the layer stack including a plurality of first insulating layers and a plurality of first conductive layers alternately stacked in a second direction crossing the first direction, the first pillars penetrating the layer stack in the second direction and being electrically connected to a source line above the layer stack, and includes, in the second area, at least one first contact having a portion provided at a same height as the layer stack and being electrically connected to the CMOS circuit, and
the source line includes a second conductive layer, the second conductive layer having, in the first area, a portion provided to cover an upper portion of each of the first pillars included in the memory cell array and having, in the second area, a portion provided to cover an upper portion of the at least one first contact, the second conductive layer electrically connects the first pillars and the at least one first contact, and a surface of the second conductive layer is provided in a non-planar shape above at least one of a set of the first pillars and a set of the at least one first contact.

2. The memory device according to claim 1, wherein
the layer stack further includes a first semiconductor layer provided between an uppermost first conductive layer and the second conductive layer and functioning as part of the source line, and the second conductive layer has, in the second area, a portion provided along a side surface of the first semiconductor layer.

3. The memory device according to claim 1, wherein
each of the first pillars includes a second semiconductor layer extending in the second direction, the source line further includes a third semiconductor layer provided between the layer stack and the second conductive layer and having a portion along an upper portion of each of the first pillars, and the third semiconductor layer is in contact with the second semiconductor layer of each of the first pillars.

4. The memory device according to claim 3, wherein
the second conductive layer has, in the second area, a portion provided along a side surface of the third semiconductor layer.

5. The memory device according to claim 3, wherein
the second conductive layer is in contact with the at least one first contact.

6. The memory device according to claim 1, further comprising:
a wiring layer provided above the second circuit layer, wherein
the wiring layer includes a third conductive layer electrically connected to the CMOS circuit via the second circuit layer and having a portion overlapping with the at least one first contact in the second direction.

7. The memory device according to claim 6, wherein
the second conductive layer is not electrically connected to a conductive layer provided at a height of the third conductive layer.

8. The memory device according to claim 6, wherein
the third conductive layer has a pad unit, at least a part of the pad unit overlapping with the at least one first contact in the second direction.

9. The memory device according to claim 1, wherein
each of the first pillars includes a second semiconductor layer extending in the second direction, and the second conductive layer is in contact with the second semiconductor layer of each of the first pillars.

10. The memory device according to claim 9, wherein
an impurity concentration of the second semiconductor layer is higher in a portion in contact with the second conductive layer than in a portion facing one of the first conductive layers in the first direction.

11. The memory device according to claim 1, wherein
the first area includes a third area and a fourth area arranged in a third direction crossing each of the first direction and the second direction,
the second circuit layer includes the first pillars in the third area, and
the second circuit layer further includes, in the fourth area, a plurality of columnar members, a second contact, and a fourth semiconductor layer, the columnar members penetrating the layer stack in the second direction and each having a portion provided at a same height as the second conductive layer above the layer stack, the second contact being connected to corresponding one of the first conductive layers and being electrically connected to the CMOS circuit, the fourth semiconductor layer being provided to cover the portion of each of the columnar members.

12. The memory device according to claim 11, wherein
the second circuit layer further includes a second insulating layer provided on the fourth semiconductor layer, and the second conductive layer has a portion provided above the second insulating layer.

13. The memory device according to claim 1, wherein
the second conductive layer contains tungsten (W) or aluminum (Al).

14. A memory device having a bonding surface, the memory device comprising:
a substrate having a first area and a second area arranged in a first direction;
a first circuit layer provided between the substrate and the bonding surface and including a CMOS circuit; and
a second circuit layer provided above the bonding surface, wherein
the second circuit layer includes, in the first area, a memory cell array including a layer stack and a plurality of first pillars, the layer stack including a plurality of first insulating layers and a plurality of first conductive layers alternately stacked in a second direction crossing the first direction, the first pillars penetrating the layer stack in the second direction and being electrically connected to a source line above the layer stack, and includes, in the second area, at least one first contact having a portion provided at a same height as the layer stack and being electrically connected to the CMOS circuit,
the first area includes a third area and a fourth area arranged in a third direction crossing each of the first direction and the second direction,
the second circuit layer includes the first pillars in the third area, the source line includes, in the third area, a second conductive layer having at least a portion provided to cover an upper portion of each of the first pillars, and the first pillars and the at least one first contact are electrically connected to each other via at least the second conductive layer,
the second circuit layer further includes, in the fourth area, a plurality of columnar members, a second contact, and a semiconductor layer, the columnar members penetrating the layer stack in the second direction and each having a portion provided at a same height as the second conductive layer above the layer stack, the second contact being connected to corresponding one of the first conductive layers and being electrically connected to the CMOS circuit, the semiconductor layer being provided to cover the portion of each of the columnar members,
the third area is provided to be divided into a fifth area and a sixth area arranged to sandwich the fourth area in the third direction, and
a portion of the second conductive layer provided in the fifth area and a portion of the second conductive layer provided in the sixth area are continuously provided via a portion of the second conductive layer provided above the semiconductor layer in the fourth area.

15. The memory device according to claim 14, further comprising:
a wiring layer provided above the second circuit layer, wherein
the second circuit layer further includes, in the second area, at least one third contact having a portion provided at the same height as the layer stack and being electrically connected to the CMOS circuit,
the wiring layer includes a third conductive layer being electrically connected to the CMOS circuit via the at least one third contact and having a first portion and a second portion, the first portion overlapping with the at least one third contact in the second direction, the second portion overlapping with the second conductive layer in the second direction while being apart from the second conductive layer in the fourth area, and
a height of an upper surface of the second portion of the third conductive layer is higher than a height of an upper surface of the first portion of the third conductive layer.

16. A memory device having a bonding surface, the memory device comprising:
a substrate having a first area and a second area arranged in a first direction;
a first circuit layer provided between the substrate and the bonding surface and including a CMOS circuit; and
a second circuit layer provided above the bonding surface, wherein
the second circuit layer includes, in the first area, a layer stack including a plurality of first insulating layers and a plurality of first conductive layers alternately stacked in a second direction crossing the first direction, a plurality of first pillars penetrating the layer stack in the second direction and being electrically connected to a source line above the layer stack, a bit line being provided below the layer stack and being electrically connected to one of the first pillars, and a second conductive layer provided between the bit line and the bonding surface, and includes, in the second area, a third conductive layer, a fourth conductive layer, a fifth conductive layer, a first contact, and a second contact, the third and fourth conductive layers being provided at a same height as the second conductive layer and being arranged apart from each other, the fifth conductive layer being provided at a same height as the source line, the first and second contacts each having a portion provided at a same height as the layer stack,
the third conductive layer is electrically connected to the fifth conductive layer via the first contact,
the fourth conductive layer is electrically connected to the fifth conductive layer via the second contact, and
the fifth conductive layer is electrically connected to the CMOS circuit via the second contact and the fourth conductive layer and is not electrically connected to the CMOS circuit via the first contact and the third conductive layer.

17. The memory device according to claim 16, wherein
the third conductive layer is provided in a mesh shape.

18. The memory device according to claim 16, wherein
the second circuit layer further includes, in the second area, at least one third contact having a portion provided at the same height as the layer stack and being electrically connected to the CMOS circuit, and
the source line includes a sixth conductive layer having a portion provided to cover an upper portion of each of the first pillars in the first area and a portion provided to cover an upper portion of the at least one third contact in the second area, the sixth conductive layer electrically connects the first pillars and the at least one third contact, and a surface of the sixth conductive layer is provided in a non-planar shape above at least one of a set of the first pillars and a set of the at least one third contact.

19. The memory device according to claim 16, further comprising:
a seventh conductive layer provided on the fifth conductive layer above the second contact; and
an eighth conductive layer provided above the first contact, at a same height as the seventh conductive layer, and apart from the seventh conductive layer, wherein
the seventh conductive layer and the eighth conductive layer are used as power supply lines of different potentials.

20. The memory device according to claim 16, wherein
the fifth conductive layer contains tungsten (W) or aluminum (Al).
